(19) United States
(12) Patent Application Publication
(10) Pub. No.: US 2010/0055312 A1
(43) Pub. Date: Mar. 4, 2010

(54) FILM DEPOSITION APPARATUS, SUBSTRATE PROCESSING APPARATUS, FILM DEPOSITION METHOD, AND COMPUTER-READABLE STORAGE MEDIUM

(75) Inventors: HITOSHI KATO, Oshu-Shi (JP); Manabu Honma, Oshu-Shi (JP); Tomoki Haneishi, Oshu-Shi (JP); Katsuyoshi Aikawa, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/552,315

(22) Filed: Sep. 2, 2009

(30) Foreign Application Priority Data
Sep. 4, 2008 (JP) 2008-227031
Jun. 2, 2009 (JP) 2009-133153

(51) Int. Cl. C23C 16/455; B05C 11/00

(52) U.S. Cl. 427/255.26; 118/668

(57) ABSTRACT

In a film deposition apparatus which deposits a thin film on a substrate by supplying first and second reactive gases in a vacuum chamber, there are provided a turntable, a first reactive gas supplying portion and a second reactive gas supplying portion which are arranged to extend from circumferential positions of the turntable to a center of rotation of the turntable, a first separation gas supplying portion arranged between the first and second reactive gas supplying portions, a first space having a first height and including the first separation gas supplying portion, a second space having a second height and including the second reactive gas supplying portion, a third space having a height lower than the first height and the second height and including the first separation gas supplying portion, a position detecting unit detecting a rotation position of the turntable, and a detection part arranged at a circumferential portion of the turntable and detected by the position detecting unit.

### CROSS-REFERENCE TO RELATED APPLICATION

This application is based upon and claims the benefit of priority from Japanese patent application No. 2008-227031, filed on Sep. 4, 2008, and Japanese patent application No. 2009-133153, filed on Jun. 2, 2009, the entire contents of which are incorporated herein by reference in their entirety.

### BACKGROUND OF THE INVENTION

1. Field of the Invention

This invention relates to a film deposition apparatus, a substrate processing apparatus, a film deposition method, and a computer-readable storage medium for depositing a film on a substrate by alternately supplying two or more source gases to the substrate.

2. Description of the Related Art

As a film deposition technique in a semiconductor fabrication process, there has been known a so-called Atomic Layer Deposition (ALD) or Molecular Layer Deposition (MLD). In such a film deposition technique, a first reactive gas is adsorbed on a surface of a semiconductor wafer (referred to as a wafer hereinafter) under vacuum and then a second reactive gas is adsorbed on the surface of the wafer in order to form one or more atomic or molecular layers through reaction of the first and the second reactive gases on the surface of the wafer; and such an alternating adsorption of the gases is repeated plural times, thereby depositing a film on the wafer. This technique is advantageous in that the film thickness can be controlled at higher accuracy by the number of times alternately supplying the gases, and in that the deposited film can have excellent uniformity over the wafer. Therefore, this deposition method is thought to be promising as a film deposition technique that can address further miniaturization of semiconductor devices.

Such a film deposition method may be preferably used, for example, for depositing a dielectric material to be used as a gate insulator. When silicon dioxide (SiO₂) is deposited as the gate insulator, a bis (tertiary-butylamino) silane (BTBAS) gas or the like is used as a first reactive gas (source gas) and ozone gas or the like is used as a second gas (oxidation gas).

In order to carry out such a deposition method, use of a single-wafer deposition apparatus having a vacuum chamber and a shower head at a top center portion of the vacuum chamber has been under consideration. In such a deposition apparatus, the reactive gases are introduced into the chamber from the top center portion, and un-reacted gases and by-products are evacuated from a bottom portion of the chamber. When such a deposition chamber is used, it takes a long time for a purge gas to purge the reactive gases, resulting in an extremely long process time because the number of cycles may reach several hundred. Therefore, a deposition method and apparatus that enable high throughput is desired.

Under these circumstances, film deposition apparatuses having a vacuum chamber and a rotation table that holds plural wafers along a rotation direction have been proposed.

Patent Document 1 listed below discloses a deposition apparatus whose process chamber is shaped into a flattened cylinder. The process chamber is divided into two half circle areas. Each area has an evacuation port provided to surround the area at the top portion of the corresponding area. In addition, the process chamber has a gas inlet port that introduces separation gas between the two areas along a diameter of the process chamber. With these compositions, while different reactive gases are supplied into the corresponding areas and evacuated from above by the corresponding evacuation ports, a rotation table is rotated so that the wafers placed on the rotation table can alternately pass through the two areas. A separation area to which the separation gas is supplied has a lower ceiling than the areas to which the reactive gases are supplied.

However, because the reactive gases and the separation gas are supplied downward and then evacuated upward from the evacuation ports provided at the upper portion of the chamber, particles in the chamber may be blown upward by the upward flow of the gases and fall on the wafers, leading to contamination of the wafers.

Patent Document 2 listed below discloses a process chamber having a wafer support member (rotation table) that holds plural wafers and that is horizontally rotatable, first and second gas ejection nozzles that are located at equal angular intervals along the rotation direction of the wafer support member and oppose the wafer support member, and purge nozzles that are located between the first and the second gas ejection nozzles. The gas ejection nozzles extend in a radial direction of the wafer support member. A top surface of the wafers is higher than a top surface of the wafer supporting member, and the distance between the ejection nozzles and the wafers on the wafer support member is about 0.1 mm or more. A vacuum evacuation apparatus is connected to a portion between the outer edge of the wafer support member and the inner wall of the process chamber. According to a process chamber so configured, the purge gas nozzles discharge purge gases to create a gas curtain, thereby preventing the first reactive gas and the second reactive gas from being mixed.

However, the gas curtain cannot completely prevent mixture of the reactive gases but may allow one of the reactive gases to flow through the gas curtain to be mixed with the other reactive gas partly because the gases flow along the rotation direction due to the rotation of the wafer support member. In addition, the first (second) reactive gas discharged from the first (second) gas outlet nozzle may flow through the center portion of the wafer support member to meet the second (first) gas, because centrifugal force is not strongly applied to the gases in a vicinity of the center of the rotating wafer support member. Once the reactive gases are mixed in the chamber, an MLD (or ALD) mode film deposition cannot be carried out as expected.

Patent Document 3 listed below discloses a process chamber that is divided into plural process areas along the circumferential direction by plural partitions. Below the partitions, a circular rotatable susceptor on which plural wafers are placed is provided leaving a slight gap in relation to the partitions. In addition, at least one of the process areas serves as an evacuation chamber. In such a process chamber, process gas introduced into one of the process areas may diffuse into the adjacent process area through the gap below the partition, and be mixed with another process gas introduced into the adjacent process area. Moreover, the process gases may be mixed in the evacuation chamber, so that the wafer is exposed to the two process gases at the same time. Therefore, ALD (or MLD) mode deposition cannot be carried out in a proper manner by this process chamber.

Patent Document 4 listed below discloses a process chamber having four sector-shaped gas supplying plates each of which has a vertex angle of 45 degrees, the four gas supplying plates being located at angular intervals of 90 degrees, evacuation ports that evacuate the process chamber and are located between the adjacent two gas supplying plates, and a susceptor that holds plural wafers and is provided in order to oppose the gas supplying plate. The four gas supplying plates can discharge AsH₃ gas, H₂ gas, trimethyl gallium (TMG) gas, and H₂ gas, respectively.

However, Patent Document 4 does not provide any realistic measures to prevent two source gases (AsH₃, TMG) from being mixed. Because of the lack of such measures, the two source gases may be mixed around the center of the susceptor and through the H₂ gas supplying plates. Moreover, because the evacuation ports are located between the adjacent two gas supplying plates to evacuate the gases upward, particles are blown upward from the susceptor surface, which leads to wafer contamination.

Patent Document 5 listed below discloses a process chamber having a circular plate that is divided into four quarters by partition walls and has four susceptors respectively provided in the four quarters, four injector pipes connected into a cross shape, and two evacuation ports located near the corresponding susceptors. In this process chamber, four wafers are mounted in the corresponding four susceptors, and the four injector pipes rotate around the center of the cross shape above the circular plate while ejecting a source gas, a purge gas, a reactive gas, and another purge gas, respectively.

In the process chamber of Patent Document 5, after one of the injector pipes passes over one of the quarters, this quarter cannot be purged by the purge gas in a short period of time. In addition, the reactive gas in one of the quarters can easily flow into an adjacent quarter. Therefore, it is difficult to perform an MLD (or ALD) mode film deposition.

When a film is formed using the film deposition apparatus as disclosed in Patent Documents 1 to 5, the generally used method of detecting a rotation position of a turntable is to use a photosensor which detects a rotation position of the turntable by using a kicker disposed on a rotary shaft of the turntable. FIG. 42 is a diagram for explaining a method of detecting a rotation position of a turntable in the film deposition apparatus according to the related art.

As illustrated in FIG. 42, a red LED 123 that emits a light beam parallel to a rotary shaft 122, and a photodiode 124 that receives the light beam from the LED 123 are disposed on an internal wall 126 of a vacuum chamber in a position which is distant from the rotary shaft 122 and located under a turntable 121. A kicker 125 which can interrupt the light beam from the LED 123 is disposed on a side circumference of the rotary shaft 122. According to this composition, each time the rotary shaft 122 is rotated one revolution, the optical axis of the light beam from the LED 123 is interrupted by the kicker 125, and it is possible to detect a rotation position of the turntable 121.

When the film deposition apparatus according to the related art as illustrated in FIG. 42 is used, the turntable 121 must be arranged with a large diameter to place four to six wafers on the turntable in a circular formation. When a rotation position of the turntable is detected using the photosensor and the kicker provided in the film deposition apparatus according to the related art, a detection error of a rotation position in the circumferential direction will be excessively large. For example, if the diameter of the turntable 121 is equal to 960 mm and a detection error of a rotational position at the leading end of the kicker (with the 8-mm height) disposed on the rotary shaft with the diameter of 80 mm is ±0.1 mm, the accuracy of a rotation position in the circumferential direction of the turntable 121 must be ±1 mm. If the accuracy of a rotation position is ±1 mm, when the wafer with the diameter of 300 mm is placed in the recess with the diameter of 304 mm, it is difficult to place the wafer in position in the recess with sufficient accuracy, and it is difficult to certainly take out the wafer from the turntable. Moreover, in the high-speed ALD apparatus which performs the ALD formation when the turntable is rotated at high speed, the turntable and the rotary shaft must be arranged in the vacuum chamber, and it is very difficult to arrange the kicker and the photosensor in the ALD apparatus.

Patent Document 6 (Patent Documents 7, 8) listed below discloses a film deposition apparatus preferably used for an Atomic Layer CVD method that causes plural gases to be alternately adsorbed on a target (a wafer). In the apparatus, a susceptor that holds the wafer is rotated, while source gases and purge gases are supplied to the susceptor from above. Paragraphs 0023, 0024, and 0025 of Patent Document 6 describe partition walls that extend in a radial direction from a center of a chamber, and gas ejection holes that are formed in a bottom of the partition walls in order to supply the source gases or the purge gas to the susceptor, so that an inert gas as the purge gas ejected from the gas ejection holes produces a gas curtain. Regarding evacuation of the gases, paragraph 0058 of Patent Document 6 describes that the source gases are evacuated through an evacuation channel 30a, and the purge gases are evacuated through an evacuation channel 30b.

In the composition of Patent Document 6, the source gases can flow into a purge gas compartment from source gas compartments located in both sides of the purge gas compartment and be mixed with each other in the purge gas compartment. As a result, a reaction product is generated in the purge gas compartment, which may cause particles to fall onto the wafer.

Patent Document 1: U.S. Pat. No. 7,153,542

Patent Document 2: Japanese Laid-Open Patent Publication No. 2001-254181

Patent Document 3: Japanese Patent No. 3,144,664

Patent Document 4: Japanese Laid-Open Patent Publication No. 04-287912

Patent Document 5: U.S. Pat. No. 6,634,314

Patent Document 6: Japanese Laid-Open Patent Publication No. 2007-247066

Patent Document 7: United States Patent Application Publication No. 2007/0218701

Patent Document 8: United States Patent Application Publication No. 2007/0218702

### SUMMARY OF THE INVENTION

In an aspect of this disclosure, there is provided a film deposition apparatus and a film deposition method which carry out appropriate film deposition processing without jeopardizing high production throughput, by performing plural cycles of alternately supplying plural reactive gases to the substrate to form plural layers of the reaction products of the reactive gases on the substrate without allowing the plural reactive gases to be mixed on the wafer, which carry out accurate detection and correction of a rotation position of the turntable, rotated at high speed, with sufficient accuracy of rotation position, and which certainly carry out conveyance of the substrate from the interior to the exterior of the vacuum chamber and vice versa.

In another aspect of this disclosure, there is provided a film deposition apparatus which deposits a thin film on a substrate by performing a cycle of alternately supplying at least two kinds of source gases, including a first reactive gas and a second reactive gas, to produce a layer of a reaction product in a vacuum chamber, the film deposition apparatus including: a turntable that is rotatably arranged in the vacuum chamber and includes a substrate mounting part on which the substrate is mounted; first and second reactive gas supplying portions that are arranged to extend from mutually different circumferential positions of the turntable to a center of rotation of the turntable to respectively supply the first reactive gas and the second reactive gas; a first separation gas supplying portion that is arranged to extend from a circumferential position of the turntable between the first reactive gas supplying portion and the second reactive gas supplying portion to the center of rotation to supply a first separation gas that separates the first reactive gas and the second reactive gas; a first undersurface area in an undersurface of a top plate of the vacuum chamber which area is arranged at a first height from the turntable to include the first reactive gas supplying portion; a first space that is arranged between the first undersurface area and the turntable; a second undersurface area in an undersurface of the top plate which area is arranged at a position apart from the first undersurface area and at a second height from the turntable to include the second reactive gas supplying portion; a second space that is arranged between the second undersurface area and the turntable; a third undersurface area in an undersurface of the top plate which area is arranged at a third height from the turntable to include the first separation gas supplying portion, the third height smaller than the first height and the second height, and the third undersurface area extending on both sides of the first separation gas supplying portion along a rotational direction of the turntable; a third space that is arranged between the third undersurface area and the turntable, the third space having the third height from the turntable and allowing the first separation gas supplied from the first separation gas supplying portion to flow into the first space and the second space; a position detecting unit that detects a rotation position of the turntable; a detection part that is arranged at a circumferential position of the turntable and detected by the position detecting unit; a core area in an undersurface of the top plate, the core area including a second separation gas supplying portion arranged on a side of the substrate mounting part around the center of rotation of the turntable to supply a second separation gas which separates the first reactive gas and the second reactive gas; and an exhaust port that is arranged to exhaust the first reactive gas and the second reactive gas together with both the first separation gas discharged to both sides of the third space and the second separation gas discharged from the core area.

In another aspect of this disclosure, there is provided a film deposition method which deposits a thin film on a substrate by performing a cycle of alternately supplying at least two kinds of source gases, including a first reactive gas and a second reactive gas, to produce a layer of a reaction product in a vacuum chamber, wherein a height of an area, to which a first separation gas that separates the first reactive gas and the second reactive gas is supplied, between an upper surface of a turntable and a top plate of the turntable on which the substrate is placed is lower than a height of an area, to which the first reactive gas and the second reaction gas are supplied, between the turntable upper surface and the top plate, and wherein the first separation gas is supplied to a narrow space arranged between the turntable upper surface and the top plate, a second separation gas that separates the first reactive gas and the second reactive gas is supplied to a core area in an undersurface of the top plate around a center of rotation of the turntable, and the first reactive gas and the second reactive gas which are separated from each other are exhausted together with the first separation gas and the second separation gas, the film deposition method including: correcting a rotation position of the turntable; placing the substrate on the turntable the rotation position of which is corrected; rotating the turntable on which the substrate is placed; depositing a thin film on a surface of the substrate by repeating a cycle of heating the turntable from a bottom of the turntable, supplying the first reactive gas and the second reactive gas respectively from a first reactive gas supplying portion and a second reactive gas supplying portion, which are arranged at mutually different circumferential positions of the turntable, supplying the first separation gas from a first separation gas supplying portion arranged between the first reactive gas supplying portion and the second reactive gas supplying portion, moving the substrate while the turntable is rotated, supplying the first reactive gas to the surface of the substrate, stopping the supply of the first reactive gas, supplying the second reactive gas to the surface of the substrate, and stopping the supply of the second reactive gas; and taking out the substrate from the turntable the rotation position of which is corrected.

Other aspects, features and advantages of this disclosure will be apparent from the following detailed description when read in conjunction with the accompanying drawings.

### BRIEF DESCRIPTION OF THE DRAWINGS

FIG. 1 is a cross-sectional view of a film deposition apparatus of a first embodiment of the invention.

FIG. 2 is a perspective view illustrating the composition of the film deposition apparatus of the first embodiment.

FIG. 3 is a diagram illustrating the composition of the film deposition apparatus of the first embodiment.

FIG. 4 is a perspective view illustrating the arrangement of a position detecting unit and a detection part in the film deposition apparatus of the first embodiment.

FIGS. 5A and 5B are cross-sectional views illustrating operation of the position detecting unit in the film deposition apparatus of the first embodiment.

FIGS. 6A and 6B are cross-sectional views illustrating first through third spaces in the film deposition apparatus of the first embodiment.

FIGS. 7A and 7B are cross-sectional views illustrating the dimensions of a third undersurface portion in the film deposition apparatus of the first embodiment.

FIG. 8 is a perspective view illustrating a first reactive gas supplying portion in the film deposition apparatus of the first embodiment.

FIG. 9 is a cross-sectional view of the part of the film deposition apparatus of the first embodiment taken along line A-A indicated in FIG. 3.

FIG. 10 is a cross-sectional view of the film deposition apparatus of the first embodiment taken along line B-B indicated in FIG. 3.

FIG. 11 is a cut-way perspective view of the part of the film deposition apparatuses of the first embodiment.

FIG. 12 is a block diagram illustrating the composition of a control part of the film deposition apparatus of the first embodiment.

FIG. 13 is a flowchart for explaining the procedure of a film deposition method performed by the film deposition apparatus of the first embodiment.

FIG. 14 is a diagram for explaining the film deposition method using the film deposition apparatus of the first embodiment of the invention, and illustrating the flows of the first reactive gas, the second reactive gas, and the first separation gas.

FIG. 15 is a cross-sectional view illustrating the composition of a film deposition apparatus of a first modification of the first embodiment.

FIG. 16 is a perspective view illustrating the arrangement of a position detecting unit and a detection part in the film deposition apparatus of the first modification of the first embodiment.

FIG. 17 is a cross-sectional view illustrating the composition of a film deposition apparatus of a second modification of the first embodiment.

FIG. 18 is a perspective view illustrating the arrangement of a position detecting unit and a detection part in the film deposition apparatus of the second modification of the first embodiment.

FIG. 19 is a cross-sectional view illustrating the composition of a film deposition apparatus of a third modification of the first embodiment.

FIG. 20 is a perspective view illustrating the arrangement of a position detecting unit and a detection part in the film deposition apparatus of the third modification of the first embodiment.

FIGS. 21A and 21B are diagrams for explaining operation of the position detecting unit in the film deposition apparatus of the third modification of the first embodiment.

FIG. 22 is a cross-sectional view illustrating the composition of a film deposition apparatus of a fourth modification of the first embodiment.

FIG. 23 is a cross-sectional view illustrating the composition of a film deposition apparatus of a fifth modification of the first embodiment.

FIG. 24 is a perspective view illustrating the arrangement of a position detecting unit and a detection part in the film deposition apparatus of the fifth modification of the first embodiment.

FIG. 25A and FIG. 25B are enlarged views illustrating the detection part of the turntable in the film deposition apparatus of the fifth modification of the first embodiment.

FIG. 26 is a flowchart explaining the procedure of a position compensation process by the film deposition apparatus of the fifth modification of the first embodiment.

FIGS. 27A, 27B and 27C are cross-sectional views illustrating the laser sensor and the turntable in the position compensation process by the film deposition apparatus of the fifth modification of the first embodiment.

FIG. 28 is a cross-sectional view illustrating the composition of a film deposition apparatus of a sixth modification of the first embodiment.

FIG. 29 is a perspective view illustrating the arrangement of a position detecting unit and a detection part in the film deposition apparatus of the sixth modification of the first embodiment.

FIGS. 30A and 30B are enlarged views illustrating the detection part of the turntable in the film deposition apparatus of the sixth modification of the first embodiment.

FIG. 31 is a flowchart for explaining the procedure of the position compensation process by the film deposition apparatus of the sixth modification of the first embodiment.

FIGS. 32A, 32B and 32C are diagrams illustrating the position detecting unit and the detection part in the position compensation process by the film deposition apparatus of the sixth modification of the first embodiment.

FIG. 33 is a cross-sectional view illustrating a configuration of a top plate in a third undersurface portion in a film deposition apparatus of a seventh modification of the first embodiment.

FIGS. 34A, 34B and 34C are cross-sectional views illustrating other configurations of the undersurface of the top plate at the third undersurface portion in a film deposition apparatus of an eighth modification of the first embodiment.

FIGS. 35A, 35B and 35C are bottom views illustrating other configurations of gas discharge holes of a first reactive gas supplying portion in a film deposition apparatus of a ninth modification of the first embodiment.

FIGS. 35D-35G are bottom views illustrating other configurations of a third undersurface portion in the film deposition apparatus of the ninth modification of the first embodiment.

FIG. 36 is a diagram illustrating the composition of a film deposition apparatus of a tenth modification of the first embodiment.

FIG. 37 is a diagram illustrating the composition of a film deposition apparatus of an eleventh modification of the first embodiment.

FIG. 38 is a perspective view illustrating the composition of a film deposition apparatus of a twelfth modification of the first embodiment.

FIG. 39 is a diagram illustrating the composition of a film deposition apparatus of a thirteenth modification of the first embodiment.

FIG. 40 is a cross-sectional view illustrating the composition of a film deposition apparatus of a fourteenth modification of the first embodiment.

FIG. 41 is a plan view illustrating the composition of a substrate processing apparatus of a second embodiment of the invention.

FIG. 42 is a diagram for explaining a method of detecting a rotation position of a turntable in a film deposition apparatus according to the related art.

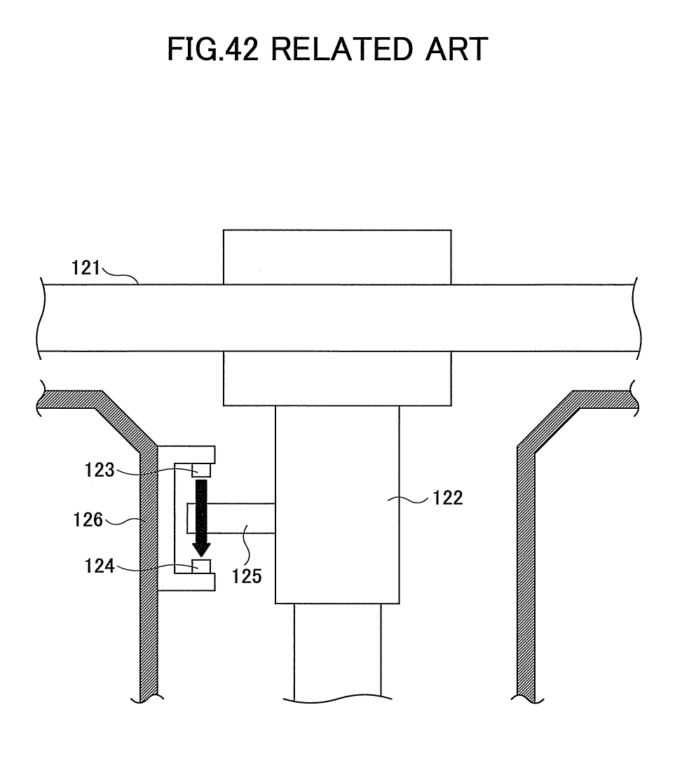

### DETAILED DESCRIPTION OF PREFERRED EMBODIMENTS

A description will be given of embodiments of the invention with reference to the accompanying drawings.

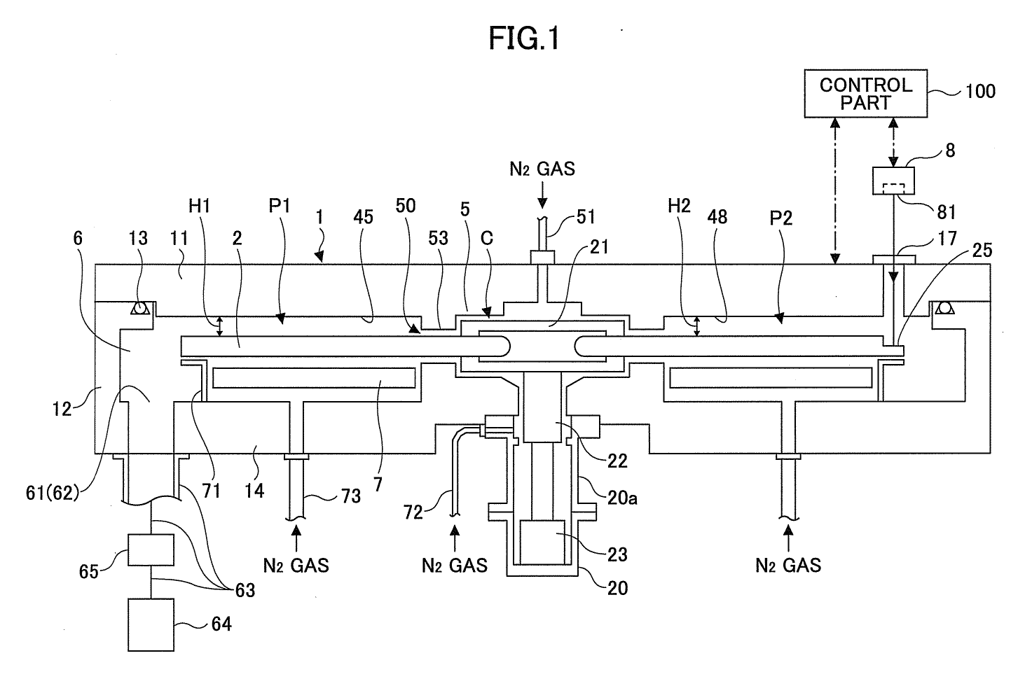

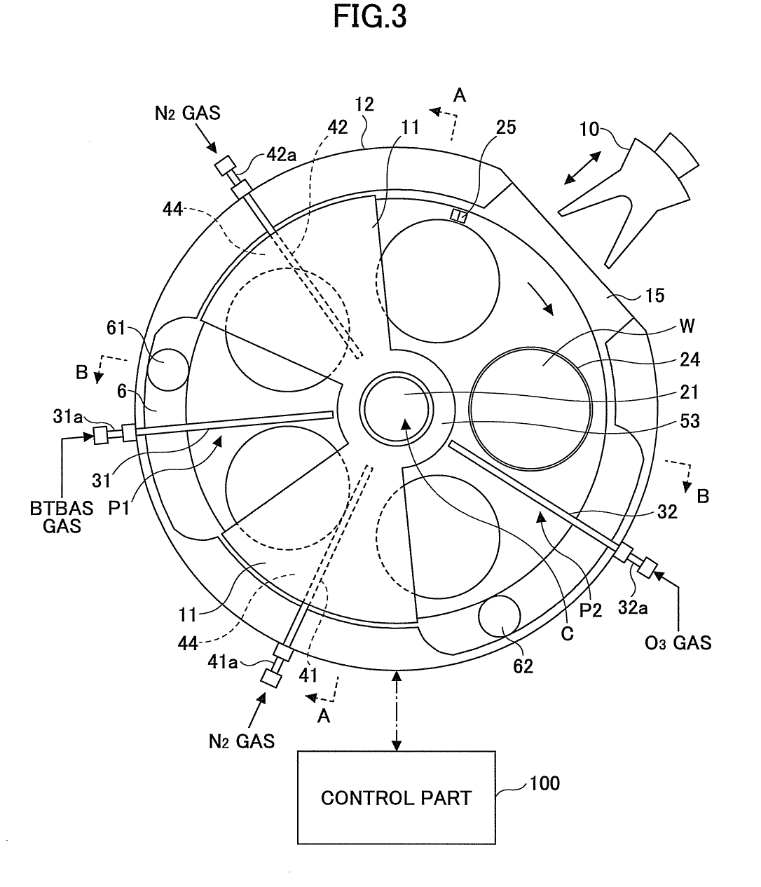

Referring to FIGS. 1 through 12, the composition of a film deposition apparatus of a first embodiment of the invention will be described. The cross section of the film deposition apparatus of this embodiment illustrated in FIG. 1 is taken along line B-B indicated in FIG. 3.

As illustrated in FIGS. 1 through 3, the film deposition apparatus of this embodiment includes a vacuum chamber 1, a turntable 2, a first reactive gas supplying portion 31, a second reactive gas supplying portion 32, first separation gas supplying portions 41 and 42, and a laser sensor 8. The laser sensor 8 corresponds to a position detecting unit in the claims.

As illustrated in FIGS. 1 through 3, the vacuum chamber 1 is a flattened container component having a generally circular configuration. The vacuum chamber 1 includes a top plate 11, a container main part 12, an O ring 13, and a base part 14.

The top plate 11 is arranged so that the top plate 11 may be separated from the container main part 12. The top plate 11 is pushed against the container main part 12 via the O ring 13 (which is a sealing member) by a reduced internal pressure of the vacuum chamber, so that an airtight condition is maintained. When the top plate 11 is separated from the container main part 12, the top plate 11 is lifted by a drive mechanism (which is not illustrated).

Next, among the parts accommodated in the vacuum chamber 1, the top plate 11, the turntable 2, and the parts located below the top plate 11 and above the turntable 2 will be described. Namely, the turntable 2, the first reactive gas supplying portion 31, the second reactive gas supplying portion 32, the first separation gas supplying portions 41 and 42, the top plate 11, and the second separation gas supplying portion 51 will be explained.

As illustrated in FIG. 1, the turntable 2 is rotatably arranged so that the turntable 2 has a center of rotation at the center of the vacuum chamber 1. The turntable 2 includes case bodies 20 and 20a, a core part 21, a rotary shaft 22, a drive part 23, recesses 24, and a detection part 25.

The turntable 2 is fixed at its center to the core part 21 of a cylindrical shape, and the core part 21 is fixed to the upper end of the rotary shaft 22 which extends in the perpendicular direction. The rotary shaft 22 penetrates a base part 14 of the vacuum chamber 1, and is attached at its bottom to the drive part 23 which rotates the rotary shaft 22 clockwise around the vertical axis. The rotary shaft 22 and the drive part 23 are accommodated in the cylindrical case body 20, and the upper surface of the case body 20 is open. The case bodies 20 and 20a attached together are arranged so that the flange part provided in the upper surface of the case body 20a is attached to the undersurface of the base part 14 of the vacuum chamber 1 airtightly and the airtight condition of the internal atmosphere of the case bodies 20 and 20a to the external atmosphere is maintained.

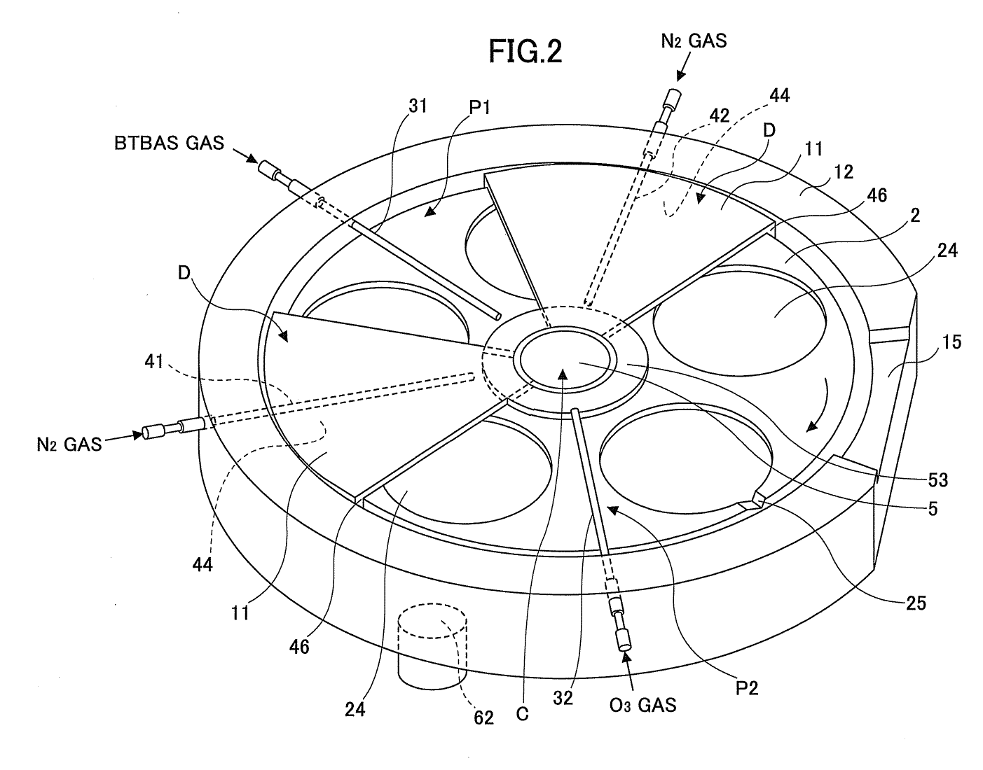

As illustrated in FIGS. 2 and 3, plural recesses 24 (five recesses in the illustrated example) are formed in the surface part of the turntable 2, in order to place five or more wafers (which are substrates) on the turntable 2 in the rotational direction (the circumferential direction) of the turntable 2.

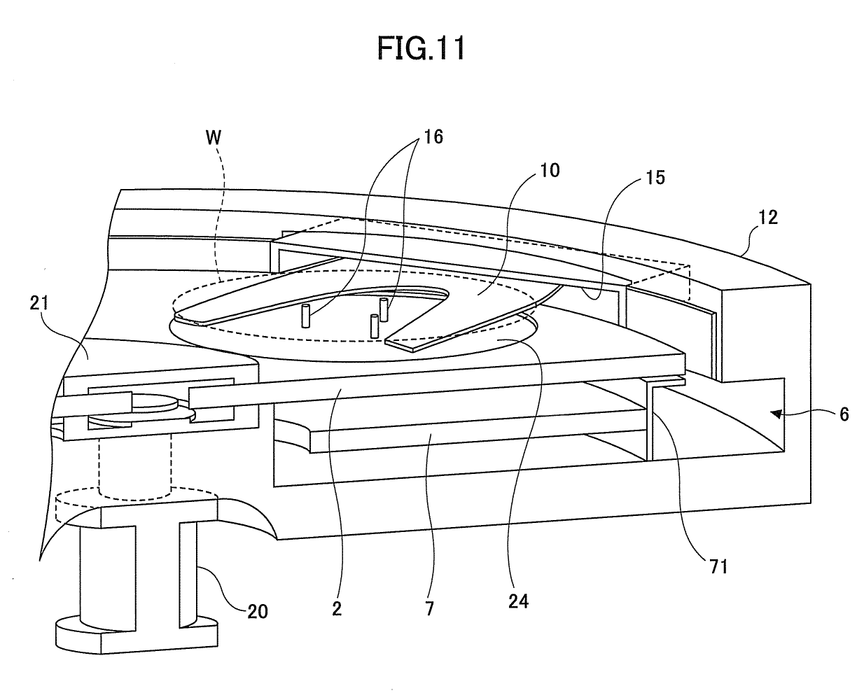

The recesses 24 have a circular configuration. Each recess 24 is for positioning the wafer and preventing the wafer from being thrown out by a centrifugal force when the turntable 2 is rotated. Each recess 24 corresponds to a substrate mounting part in the claims. For the sake of convenience, only one wafer W placed in one recess 24 is illustrated in FIG. 3. As in the illustrated example, the recess 24 has a diameter that is slightly larger than the diameter of the wafer, for example, by 4 mm, and has a depth that is equivalent to the thickness of the wafer. Therefore, when the wafer is placed in the recess 24, the surface of the wafer is substantially flush with the upper surface of the turntable 2 (in the area in which the wafer is not placed). If the difference in height between the surface of the wafer and the surface of the turntable 2 is relatively large, gas flow pressure fluctuations will arise in the relatively large step part, which may affect the thickness uniformity across the wafer. This is why the surface of the wafer and the surface of the turntable 2 are arranged to have the same height. This means that the surface of the wafer (substrate) placed in the recess 24 (substrate mounting part) is arranged at the same height as the surface of the turntable 2, or the surface of the wafer (substrate) is lower than the surface of the turntable 2. It is preferred that the difference in height is close to zero as much as possible to the extent according to machining accuracy. It is preferred that the difference in height is smaller than or equal to about 5 mm. In order to support the back of the wafer and lift the wafer up and down, the three through holes through which three elevation pins (which will be described later with reference to FIG. 11 later) are raised or lowered are formed in the bottom of the recess 24.

The substrate mounting parts are not limited to the recesses. The substrate mounting parts may be formed by, for example, guide members that are placed at predetermined angular intervals on the turntable 2 to hold the peripheral edges of the wafers. For example, the substrate mounting parts may be constituted by electrostatic chuck mechanisms disposed on the turntable 2. When such chuck mechanisms are arranged on the turntable 2, the area in which the wafer is placed by the electrostatic attraction of the corresponding chuck mechanism serves as a substrate mounting part.

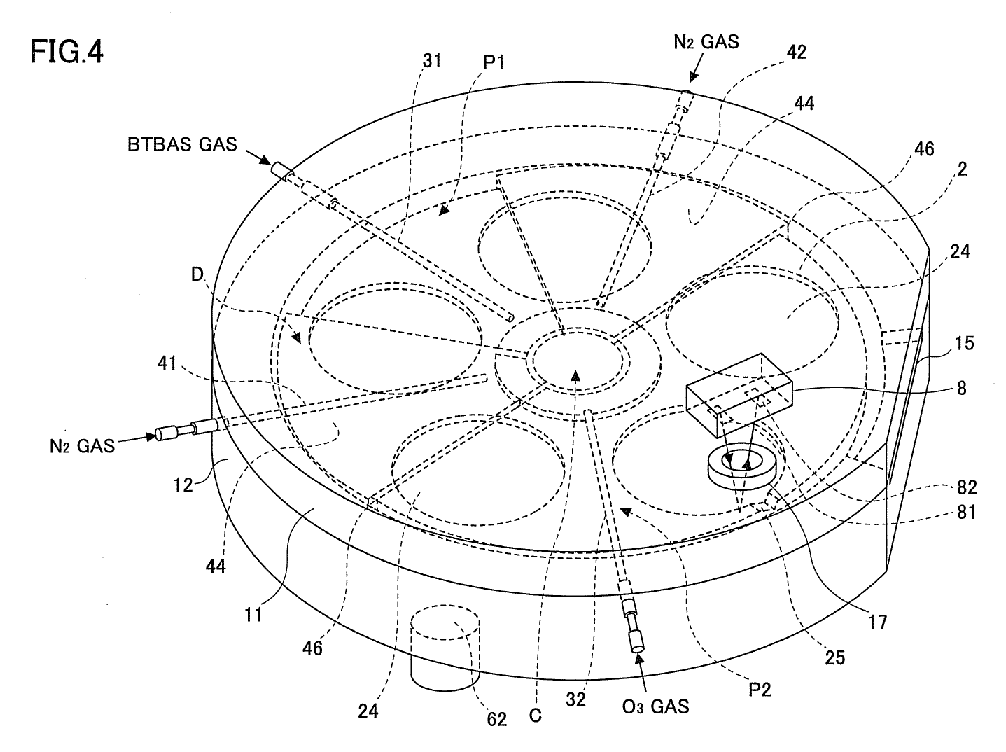

As illustrated in FIGS. 1 and 4, the detection part 25 is formed at the circumference of the upper surface of the turntable 2. The detection part 25 is for performing position compensation of a rotation position of the turntable 2 on the basis of a rotation position of the turntable 2 when the turntable 2 is rotated and the detection part 25 is detected by the laser sensor 8 (position detecting unit). The configuration of the detection part 25 is optional provided that it is detectable by the laser sensor 8. The detection part 25 may be disposed at any height position that may be higher than or lower than the height of the surface of the turntable 2. In this embodiment, the detection part 25 is a scribed line which is formed in a circumferential portion of the upper surface of the turntable 2 and extends in the radial direction of the turntable 2.

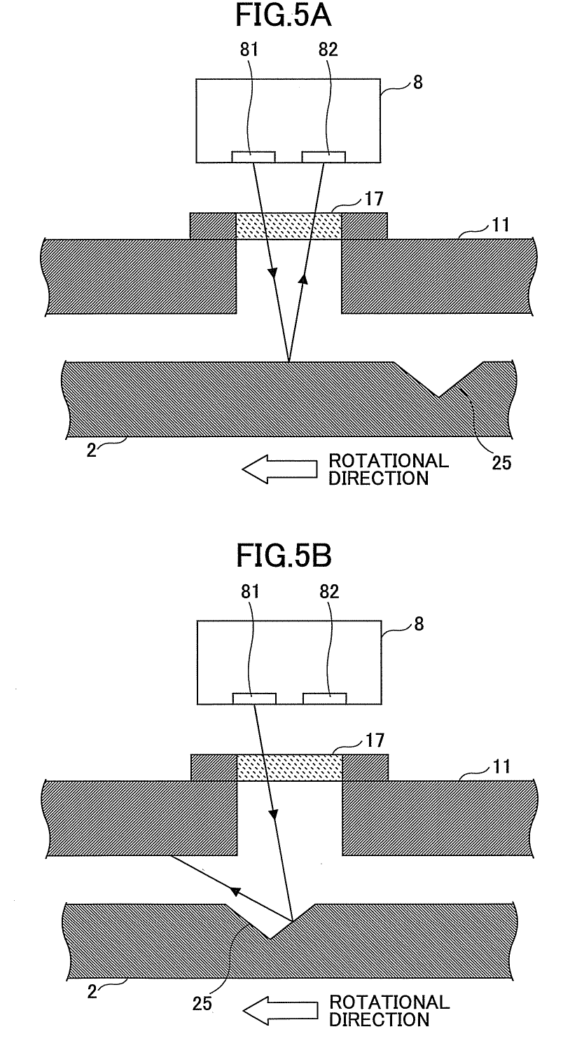

Because the detection part 25 in this embodiment is a scribed line formed in the circumferential portion of the turntable 2 and extending in the radial direction of the turntable 2, the cross section of the detection part 25 perpendicular to the radial direction of the turntable 2 is a slot having a triangular cross section as illustrated in FIG. 5A.

Provided that the detection part 25 is disposed in a portion of the turntable 2 in order to detect a rotation position of the turntable 2 with good accuracy, the location of the detection part 25 is not restricted to the upper surface of the turntable 2. The detection part 25 may be disposed on a side circumferential surface or an undersurface of the turntable 2.

In order to detect the detection part 25 of the turntable 2, the laser sensor 8 is disposed in a position higher than the circumference of the upper surface of the turntable 2, as illustrated in FIGS. 4, 5A, and 5B. The laser sensor 8 is for detecting passage of the detection part 25 provided in the upper surface of the turntable 2 when the turntable 2 is rotated. The laser sensor 8 includes a light emitting element 81 which emits a laser beam, and a light receiving element 82 which receives the laser beam emitted from the light emitting element 81. It is not necessary to dispose the laser sensor 8 in the interior of the vacuum chamber 1. In this embodiment, the laser sensor 8 is arranged above the top plate 11 of the vacuum chamber 1 as illustrated in FIG. 1. In this case, an entrance window 17 is formed in the top plate 11 of the vacuum chamber 1 at a position at which the laser sensor 8 is projected in parallel to the rotary shaft of the turntable 2. The entrance window 17 is for enabling a laser beam emitted from the light emitting element 81 of the laser sensor 8 to enter into the upper surface of the turntable 2, and for enabling a laser beam reflected from the upper surface of the turntable 2 to enter into the light receiving element 82 of the laser sensor 8.

Provided that the detection part of the turntable 2 is detectable, the location of the laser sensor 8 being disposed is not limited to the exterior of the vacuum chamber 1. Alternatively, the laser sensor 8 may be disposed in the interior of the vacuum chamber 1. In this case, forming the entrance window 17 in the top plate 11 of the vacuum chamber 1 may be omitted.

Next, the detection of a rotation position of the turntable 2 using the laser sensor 8 and the detection part 25 in the film deposition apparatus of this embodiment will be described with reference to FIGS. 5A and 5B.

FIGS. 5A and 5B are cross-sectional views illustrating operation of the position detecting unit (the laser sensor 8) in the film deposition apparatus of this embodiment to detect the detection part 25.

As illustrated in FIG. 5A, a relative position and a relative angle between the laser sensor 8 and the entrance window 17 are adjusted so that, when the laser beam emitted from the light emitting element 81 enters into the area of the upper surface of the turntable 2 where the detection part 25 is not formed, almost all the reflected laser beam may pass through the entrance window 17 and it may be received by the light receiving element 82 of the laser sensor 8. The light receiving amount of the light receiving element 82 at this time is set to E1.

On the other hand, as illustrated in FIG. 5B, when the turntable 2 is rotated and the detection part 25 is moved to the position where the laser beam emitted from the light emitting element 81 enters into the turntable 2, the direction of a laser beam being reflected from the detection part 25 (which is a scribed line having a triangular cross section) changes, and the quantity of the reflected laser beam which enters into the light receiving element 82 of the laser sensor 8 decreases. The light receiving amount of the light receiving element 82 at this time is set to E2. That is, the condition of the light receiving amount is set to E2<E1.

Accordingly, if a difference of the light receiving amount (E2−E1) is detected, it can be determined whether the detection part 25 formed in the upper surface of the turntable 2 has passed through the position beneath the laser sensor 8 and the entrance window 17. If a rotation position of the turntable 2 when the passage of the detection part 25 is detected by the laser sensor 8 is used as the reference position, the rotation position of the turntable 2 can be corrected with good accuracy.

Specifically, for example, if the diameter of the turntable 2 is equal to 960 mm and a scribed line having a depth of 2 mm, a width of 1 mm in the rotational direction and a length of 5 mm in the radial direction is formed in the circumferential portion of the upper surface of the turntable 2, the rotation position detection and correction can be carried out with the precision of ±0.3 mm.

As illustrated in FIGS. 2 and 3, in order to respectively supply the first reactive gas, the second reactive gas, and the first separation gas to the substrate mounting part of the recess 24 in the turntable 2, the first reactive gas supplying portion 31, the second reactive gas supplying portion 32, and the two first separation gas supplying portions 41 and 42 are arranged in the vacuum chamber 1 to respectively extend from mutually different positions of the circumference of the vacuum chamber 1 (or the circumference of the turntable 2) to the center of rotation of the turntable.

Each of the first reactive gas supplying portion 31, the second reactive gas supplying portion 32, and the first separation gas supplying portions 41 and 42 is constituted by a nozzle in which plural discharge holes for discharging the reactive gas or the separation gas are perforated on the bottom side of the nozzle and arranged at given intervals in the length direction of the nozzle.

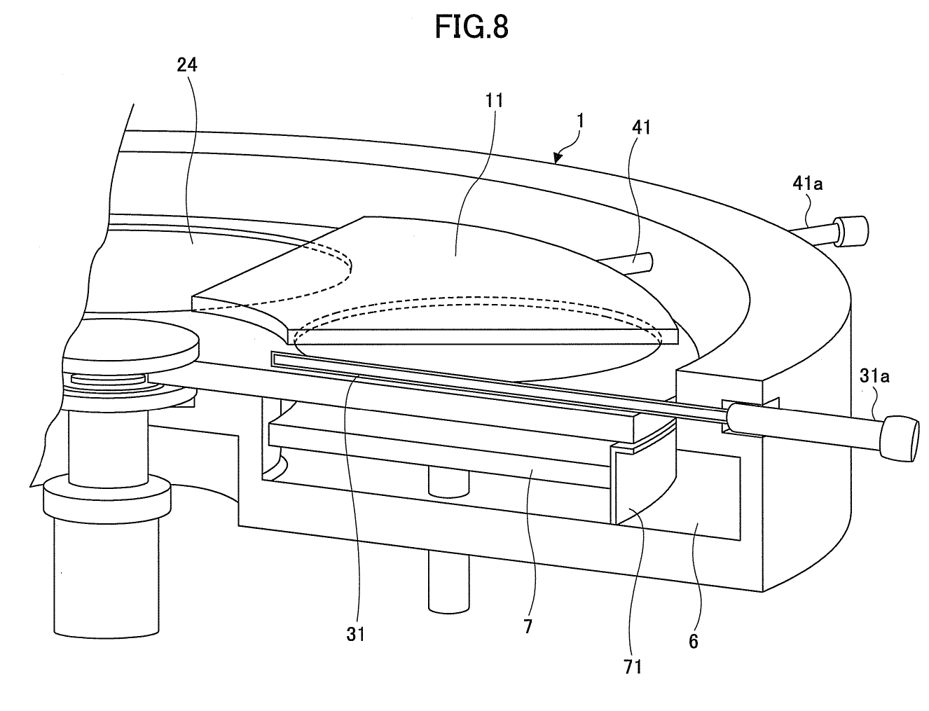

For example, the first reactive gas supplying portion 31, the second reactive gas supplying portion 32, and the first separation gas supplying portions 41 and 42 are attached to the side wall of the vacuum chamber 1, and gas inlet ports 31a, 32a, 41a and 42a which are provided in the base end parts of the portions 31, 32, 41 and 42 respectively are arranged to penetrate the side wall of the vacuum chamber 1. In this embodiment, as is partially illustrated in FIG. 8, the gas inlet ports 31a, 32a, 41a and 42a are introduced from the side wall of the vacuum chamber 1.

Alternatively, the gas inlet ports 31a, 32a, 41a and 42a may be introduced from an annular projection portion 53 (which will be described later). In this case, an L-shaped conduit which includes first openings that are open to the circumferential side of the projection portion 53 and second openings that are open to the outside surface of the top plate 11 is provided in the vacuum chamber 1. Specifically, the first reactive gas supplying portion 31, the second reactive gas supplying portion 32 and the first separation gas supplying portions 41 and 42 are connected to the first openings of the L-shaped conduit in the interior of the vacuum chamber 1, and in the exterior of the vacuum chamber 1, the gas inlet ports 31a, 32a, 41a and 42a are connected to the second openings of the L-shaped conduit.

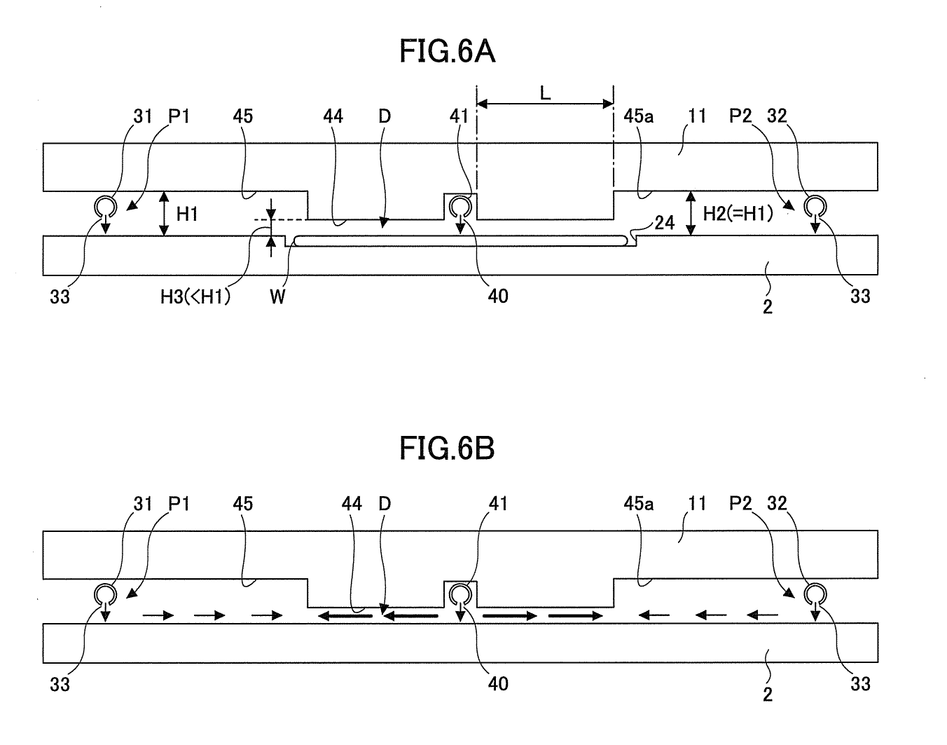

As illustrated in FIGS. 6A and 6B, in each of the first reactive gas supplying portion 31 and the second reactive gas supplying portion 32, discharge holes 33 for discharging the reactive gas are perforated on the bottom side of the nozzle and arranged at given intervals in the length direction of the nozzle. For example, as for each of the first reactive gas supplying portion 31 and the second reactive gas supplying portion 32 in this embodiment, the aperture diameter of each of the discharge holes 33 is equal to about 0.5 mm, and the intervals at which the discharge holes 33 are arrayed in the length direction of the nozzle are equal to about 10 mm.

As illustrated in FIGS. 6A and 6B, in each of the first separation gas supplying portions 41 and 42, discharge holes 40 for discharging the separation gas are perforated on the bottom side of the nozzle and arranged at given intervals in the length direction of the nozzle. For example, as for each of the first separation gas supplying portions 41 and 42 in this embodiment, the aperture diameter of each of the discharge holes 40 is equal to about 0.5 mm, and the intervals at which the discharge holes 40 are arrayed in the length direction of the nozzle are equal to about 10 mm.

The first reactive gas supplying portion 31 and the second reactive gas supplying portion 32 are respectively connected to the first reactive gas supply source and the second reactive gas supply source which are disposed in the exterior of the vacuum chamber 1. The first separation gas supplying portions 41 and 42 are connected to the first separation gas supply source which is disposed in the exterior of the vacuum chamber 1.

In this embodiment, the second reactive gas supplying portion 32, the first separation gas supplying portion 41, the first reactive gas supplying portion 31, and the first separation gas supplying portion 42 are arranged clockwise in this order.

In this embodiment, for example, BTBAS (bis (tertiary-butylamino) silane) gas may be used as the first reactive gas. For example, O₃ (ozone) gas may be used as the second reactive gas. For example, N₂ (nitrogen) gas may be used as the first separation gas.

The first separation gas is not limited to N₂ gas. Alternatively, inert gas, such as Ar, may be used instead. Moreover, instead of inert gas, hydrogen gas may be used. If the first separation gas used is gas which does not affect film deposition processing, the kind of the gas is optional.

As illustrated in FIGS. 1-3 and GA, the undersurface of the top plate 11 is provided with a first undersurface portion 45 (a first undersurface area) which is the surface separated from the upper surface of the turntable 2 by a distance H1, a second undersurface portion 45a (a second undersurface area) which is the surface separated from the upper surface of the turntable 2 by a distance H2, and a third undersurface portion 44 (a third undersurface area) which is formed between the first undersurface portion 45 and the second undersurface portion 45a, and separated from the upper surface of the turntable 2 by a distance H3. Moreover, a projection portion 53 adjoining the center-of-rotation side of each of the first undersurface portion 45 and the second undersurface portion 45a, and a center-of-rotation portion 5 corresponding to the core part 21 are provided in the undersurface of the top plate 11.

The first undersurface portion 45, the second undersurface portion 45a, and the third undersurface portion 44 are the areas of the undersurface of the top plate 11 which include the first reactive gas supplying portion 31, the second reactive gas supplying portion 32, and the first separation gas supplying portion 41 respectively. The third undersurface portion 44 is divided into two parts by the first separation gas supplying portion 41.

As illustrated in FIGS. 1-3 and 6A, the upper surface of the turntables 2 and each of the four areas (provided in the undersurface of the top plate 11), including the first undersurface portion 45, the second undersurface portion 45a, and the two third undersurface portions 44, respectively form a first space P1, a second space P2, and two third spaces D therebetween.

As illustrated in FIGS. 6A and 6B, the first undersurface portion 45 is an area of the undersurface of the top plate 11 containing the first reactive gas supplying portion 31. The second undersurface portion 45a is an area of the undersurface of the top plate 11 containing the second reactive gas supplying portion 32. The third undersurface portion 44 is an area of the undersurface of the top plate 11 containing the first separation gas supplying portions 41 and 42.

The distance from the central axis of the first separation gas supplying portion 41 or 42 to each of the ends of the third undersurface portion 44 of the sector form in the rotational direction of the turntable 2 is set to the same length.

In this case, the circumferential length of the part in the third undersurface portion 44 of the top plate 11 near the circumference of the turntable 2 can be enlarged. This is because, when the turntable 2 is rotated, the flow rate of the gas directed to the part of the third undersurface portion 44 from the upstream side in the rotational direction is higher as the part is nearer to the circumference of the turntable 2.

In this embodiment, the wafer W with a diameter of 300 mm is used as the substrate being processed, and the circumferential length (the length of the arc of the circle coaxial to the circle of the turntable 2) of the third undersurface portion 44 at the projection portion 53 which is 140 mm distant from the center of rotation is set to 146 mm, and the circumferential length of the third undersurface portion 44 at the position of the outermost part of the recess 24 (substrate mounting part) is set to 502 mm. As illustrated in FIG. 6A, the circumferential length L of the third undersurface portion 44 of the top plate 11 located at the end of the first separation gas supplying portion 41 (42) in the position of this outermost part is set to 246 mm.

As illustrated in FIGS. 1-3 and GA, the first undersurface portion 45 of the top plate 11 containing the first reactive gas supplying portion 31 is disposed at the first height H1 from the turntable 2. The second undersurface portion 45a containing the second reactive gas supplying portion 32 is disposed at the second height H2 from the turntable 2, as illustrated in FIGS. 1 and 6A. The third undersurface portion 44 containing the first separation gas supplying portion 41 is disposed at the third height H3 from the turntable 2, as illustrated in FIG. 6A. The third height H3 is smaller than the first height H1 and the second height H2.

Although the relation between the first height H1 and the second height H2 is not limited, it can be set to H1=H2, for example. In this embodiment, the conditions H3<H1=H2 may be set up.

As illustrated in FIG. 6A, the third undersurface portion 44 that is the undersurface of the top plate 11 disposed at the third height H3 from the turntable 2 exists on both sides of the first separation gas supplying portion 41 in the rotational direction, and the first undersurface portion 45 and the second undersurface portion 45a that are higher than the third undersurface portion 44 exist on both sides of the third undersurface portion 44 in the rotational direction. In other words, the third space D exists on both sides of the first separation gas supplying portion 41 in the rotational direction, and the first space P1 and the second space P2 exist on both sides of the third space D in the rotational direction. Similarly, the third space D exists between the opposite side of the first space P1 and the opposite side of the second space P2.

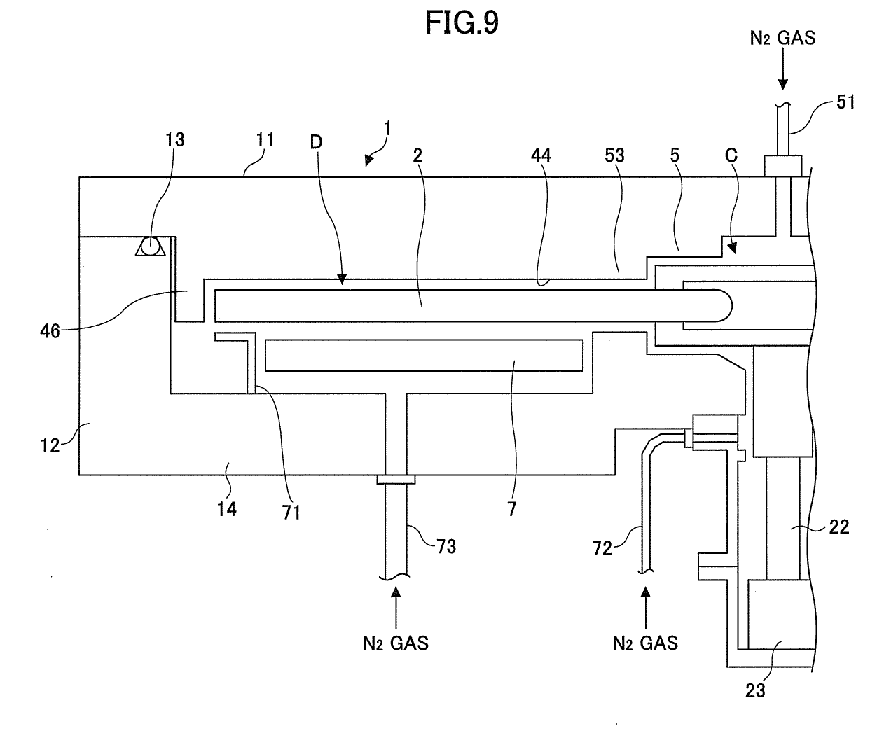

As illustrated in FIG. 9, the edge part of the undersurface of the top plate 11 corresponding to the third space D (which is located at the outer peripheral part of the vacuum chamber 1) is formed into an L-shaped curved part 46 that faces the outer circumferential end face of the turntable 2. The top plate 11 can be removed from the container main part 12, and there is provided a small gap between the outer circumferential wall of the curved part 46 and the inside wall of the container main part 12. Similar to the third undersurface portion 44, the curved part 46 is also provided in order to prevent mixing of the first reactive gas and the second reactive gas when they are infiltrated. The gap between the inner circumferential wall of the curved part 46 and the outer circumferential end face of the turntable 2, and the gap between the outer circumferential end face of the curved part 46 and the container main part 12 are set to be the same size as the third height H3 of the undersurface portion 44 from the upper surface of the turntable 2. In the upper-surface-side area of the turntable 2, the inner circumferential wall of the curved part 46 provides the function that is the same as the function of the inner circumferential wall of the vacuum chamber 1.

The top plate 11 of the vacuum chamber 1 in the cross sections illustrated in FIGS. 2 and 3 is cut horizontally at the height position which is lower than the first undersurface portion 45 and the second undersurface portion 45a and higher than the first separation gas supplying portion 41 or 42.

The operation of separating the atmosphere of the first space P1 and the atmosphere of the second space P2 which is provided by the third space D will now be described.

The third undersurface portion 44 in combination with the first separation gas supplying portion 41 is for preventing infiltration of the first reactive gas and the second reactive gas to the third space D, and thereby preventing mixture of the first reactive gas and the second reactive gas. That is, the third space D prevents infiltration of the second reactive gas from the side that is opposite to the rotational direction of the turntable 2, and prevents infiltration of the first reactive gas from the side that is the same as the rotational direction of the turntable 2. The “prevention of infiltration of the gas” means that the first separation gas sent from the first separation gas supplying portion 41 is spread into the third space D and blown off to the second space P2 that is located beneath the adjoining second undersurface portion 45a, and thereby preventing infiltration of the gas sent from the second space P2. The state in which infiltration of the gas is prevented does not mean the state in which the gases from the first space P1 and the second space P2 do no enter the third space D at all, but the state in which some of the gases enter but the first reactive gas and the second reactive gas respectively entering from the left side and the right side are not mixed together in the third space D. As long as these states are maintained, the operation of separating the atmosphere of the first space P1 and the atmosphere of the second space P2 by the third space D is maintained. Because the gas which is adsorbed into the wafer can pass through the inside of the third space D, the gas entering from the adjoining space means the gas in the gaseous phase.

As illustrated in FIG. 6A, the height H3 of the third undersurface portion 44 of the top plate 11 from the turntable 2 is, for example, in a range between about 0.5 mm and about 10 mm. It is preferred that the height H3 is set to about 4 mm. In this case, the rotational speed of the turntable 2 is set in a range between 1 rpm and 500 rpm. In order to secure the separating function of the third undersurface portion 44, the height H3 of the third undersurface portion 44 from the turntable 2 and the dimensions of the third undersurface portion 44 have to be set up based on the experimental results according to the use range of the rotational speed of the turntable 2.

The first separation gas is not restricted to N₂ gas. Inert gas, such as Ar gas, may be used instead, and not only inert gas but also hydrogen gas may be used. The first separation gas is not limited to a specific kind of gas, if the gas does not affect the film deposition processing.

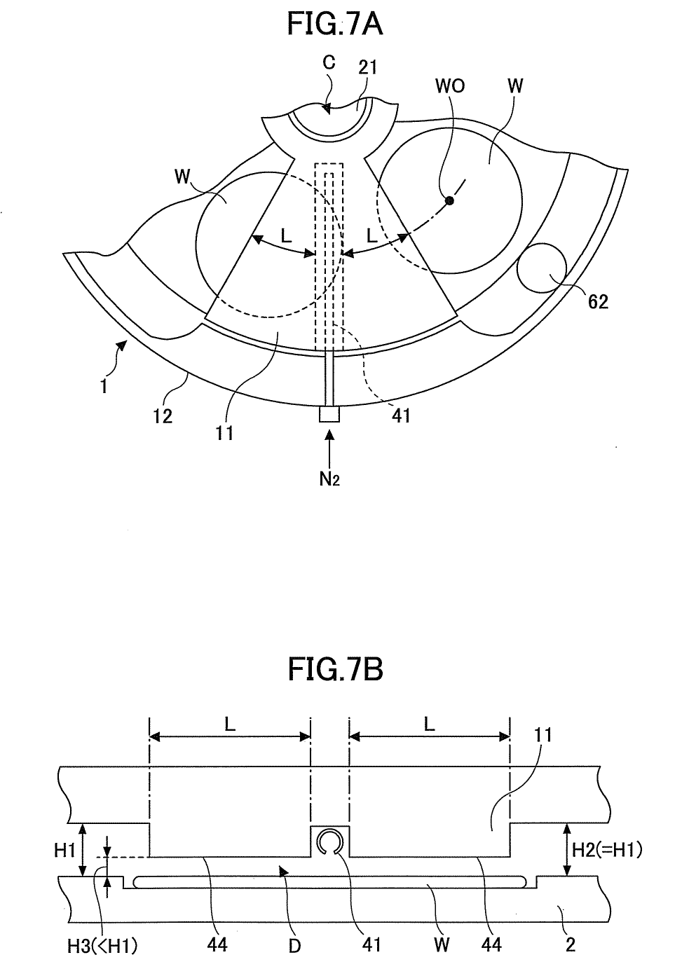

The third undersurface portion 44 forms the narrow space which is located on both sides of the first separation gas supplying portion 41 (42) respectively. When the wafer W with the diameter of 300 mm is used as the substrate being processed, it is preferred that the width dimension L of the portion of the first separation gas supplying portion 41 where the center WO of the wafer W passes through in the rotational direction of the turntable 2, as illustrated in FIGS. 7A and 7B, is 50 mm or more. If the width dimension L is smaller than 50 mm, it is necessary to make smaller the third height H3, which is the distance between the third undersurface portion 44 and the turntable 2, accordingly, in order to effectively prevent the reactive gases from entering the third space D (the narrow space which is defined by the third height H3 smaller than the first height H1 and the second height H2).

The rotating speed of a point on the turntable 2 becomes higher for a constant rotational speed as the distance from the center of rotation of the turntable 2 increases. If the third height H3 that is the distance between the third undersurface portion 44 and the turntable 2 is set to a certain height, the width dimension L needed for acquiring the reactive gas infiltration prevention effect becomes large as the distance of the portion from the center of rotation of the turntable 2 becomes large. If the width dimension L is smaller than 50 mm, it is necessary to make even smaller the third height H3 which is the distance between the third undersurface portion 44 and the turntable 2. In such a case, the improvement to reduce the vibrations of the turntable 2 as much as possible is required, in order to prevent the collision of the third undersurface portion 44 with the turntable 2 or the wafer W when the turntable 2 is rotated.

Moreover, if the rotational speed of the turntable 2 is high, the reactive gases from the upstream of the third undersurface portion 44 easily enters into the space below the third undersurface portion 44. If the width dimension L is smaller than 50 mm, the rotational speed of the turntable 2 must be made low. This makes it difficult to increase the throughput. Therefore, it is preferred that the width dimension L is 50 mm or more.

However, the size of the third undersurface portion 44 may be adjusted according to the process parameters and the wafer size which are used, regardless of the above-mentioned value of width dimension L.

As long as the third space D (the narrow space) is defined by such a height that forms the flow of the separation gas from the third space D to the first space P1 (or the second space P2), the third height H3 of the third space D may be adjusted according to the process parameters and the wafer size and according to the area of the third undersurface portion 44.

The projection portions 53 of the top plate 11 in the first undersurface portion 45 and the second undersurface portion 45a are the areas which are located between the circumference side of the core part 21 and the center-of-rotation side of each area and face the upper surface of the turntable 2, as illustrated in FIG. 1. The projection portions 53 of the top plate 11 are continuously formed to the center-of-rotation side of each area to be integral with the two third undersurface portions 44, as illustrated in FIG. 9, and the undersurfaces of the projection portions 53 are flush with the third undersurface portions 44. However, the projection portions 53 of the top plate 11 and the third undersurface portions 44 may not necessarily be integral with each other, but they may be separate parts.

The center-of-rotation portion 5 of the top plate 11 is an area located in the center-of-rotation side of the projection portion 53. In this embodiment, the boundary between the projection portion 53 and the center-of-rotation portion 5 may be provided, for example, on the circumference which has a radius of 140 mm from the center of rotation.

As illustrated in FIGS. 1 and 9, the second separation gas supplying portion 51 penetrates the top plate 11 of the vacuum chamber 1, and is connected to the core of the vacuum chamber 1. The second separation gas supplying portion 51 is for supplying the second separation gas to the core area C which is the space between the top plate 11 and the core part 21. Although the second separation gas is not restricted to a specific gas, for example, N₂ gas may be used as the second separation gas.

The second separation gas supplied to the core area C is discharged to the circumference along the surface on the side of the substrate mounting part of the turntable 2 through the narrow gap 50 between the projection portion 53 and the turntable 2. Because the space surrounded by the projection portion 53 is filled with the second separation gas, mixing of the first reactive gas and the second reactive gas is prevented through the core of the turntable 2 between the first space P1 and the second space P2. Namely, the film deposition apparatus is provided with the core area C which is surrounded by the center-of-rotation portion of the turntable 2 and the vacuum chamber 1 in order to separate the atmosphere of the first space P1 and the atmosphere of the second space P2, the second separation gas is supplied to the core area C, and, in the core area C, the discharge hole which discharges the second separation gas to the upper surface of the turntable 2 is disposed along the rotational direction. The discharge hole is equivalent to the narrow gap 50 between the projection portion 53 and the turntable 2.

Next, among the parts accommodated in the vacuum chamber 1, the parts which are disposed on the outer circumferential side of the turntable 2 and located below the turntable 2 and above the base part 14 will be described. Namely, the container main part 12 and the exhaust space 6 will be described.

As illustrated in FIG. 9, the inner peripheral wall of the container main part 12 in the third space D is adjacent to the outer circumference side of the curved part 46 and it is formed into a vertical surface. On the other hand, as illustrated in FIG. 1, the portions of the container main part 12 other than the third space D are constructed such that the portion from the part which faces the outer circumferential end face of the turntable 2 to the part which faces the base part 14 is cut off to have a rectangular cross-section. This cut-off portion of the container main part 12 is formed as the exhaust space 6.

As illustrated in FIGS. 1 and 3, two exhaust ports 61 and 62 are disposed on the bottom of the exhaust space 6. Each of the exhaust ports 61 and 62 is connected through an exhaust pipe 63 to a common vacuum pump 64 which is a vacuum exhaust unit of the film deposition apparatus. A pressure regulation unit 65 is disposed in the exhaust pipe 63 between the exhaust port 61 and the vacuum pump 64. The pressure regulation unit 65 may be disposed for each of the exhaust ports 61 and 62, or a common pressure regulation unit 65 may be disposed for the exhaust ports 61 and 62. The exhaust ports 61 and 62 are formed on both sides of the third space D in the rotational direction and respectively exhaust the first reactive gas and the second reactive gas so that the separating function of the third space D may work certainly.

In this embodiment, the exhaust port 61 is disposed between the first reactive gas supplying portion 31 and the third space D that adjoins the downstream side of the first reactive gas supplying portion 31 in the rotational direction of the turntable, and the exhaust port 62 is disposed between the second reactive gas supplying portion 32 and the third space D that adjoins the downstream side of the second reactive gas supplying portion 32 in the rotational direction of the turntable.

The number of exhaust ports installed is not restricted to two. Additionally, a third exhaust port may be installed between the third space D that includes the first separation gas supplying portion 42 and the second reactive gas supplying portion 32 that adjoins the downstream side of the third space D in the rotational direction. Alternatively, four or more exhaust ports may be installed.

Next, among the parts accommodated in the vacuum chamber 1, the parts which are located below the turntable 2 and down to the base part 14 of the vacuum chamber 1 will be described. Namely, the heater unit 7 (heating part), the cover member 71, the base part 14, the third separation gas supplying portion 72, and the fourth separation gas supplying portion 73 will be described.

The heater unit 7 is disposed in the space between the turntable 2 and the base part 14 of the vacuum chamber 1, as illustrated in FIGS. 1 and 8. The heater unit 7 is for heating the wafer on the turntable 2 through the turntable 2 to the predetermined temperature according to the process specifications. Instead of being disposed in the space below the turntable 2, the heater unit 7 may be disposed in the space above the turntable 2. Alternatively, the heater unit 7 may be provided in both the space above the turntable 2 and the space below the turntable 2. The heater unit 7 is not restricted to a heater unit using a resistance heating element. Alternatively, an infrared lamp may be used as the heater unit 7. The reflector (reflecting plate) may be provided in the lower half portion of the heater unit 7 for reflecting the heat, generated by the heater unit 7 and directed to the lower half portion, toward the upper portion, and for raising thermal efficiency.

The temperature of the turntable 2 heated by the heater unit 7 is measured by a thermocouple which is embedded in the base part 14 of the vacuum chamber 1. The value of the temperature measured by the thermocouple is sent to the control part 100, and the control part 100 controls the heater unit 7 so that the temperature of the turntable 2 may be held at the predetermined temperature.

The cover member 71 is disposed in the circumferential side and the lower part of the turntable 2 to partition the lower part space of the turntable 2 and the exhaust space 6. The cover member 71 is formed to surround all the circumference of the heater unit 7. The cover member 71 is provided to reduce the gap between the fold-back side and the undersurface of the turntable 2, in order to prevent entering of the first reactive gas and the second reactive gas into the inner circumference side of the cover member 71.

The base part 14 approaches near the core and the core part 21 of the turntable 2 at the bottom with a narrow gap in the part on the side of the center of rotation from the space where the heater unit 7 is arranged. The base part 14 in the through hole of the rotary shaft 22 which penetrates the base part 14, has a narrow gap between the inner circumference side of the through hole and the rotary shaft 22. The through hole is formed to communicate with the case body 20.

The third separation gas supplying portion 72 is formed in the case body 20. The third separation gas supplying portion 72 is for supplying the third separation gas to the narrow space. Although the third separation gas is not limited to a specific gas, for example, N₂ gas may be used as the third separation gas.

The fourth separation gas supplying portion 73 is disposed in the base part 14 of the vacuum chamber 1 at two or more positions below the heater unit 7 along the rotational direction. The fourth separation gas supplying portion 73 is for supplying the fourth separation gas to the space where the heater unit 7 is arranged. Although the fourth separation gas is not limited to a specific gas, for example, N₂ gas may be used as the fourth separation gas.

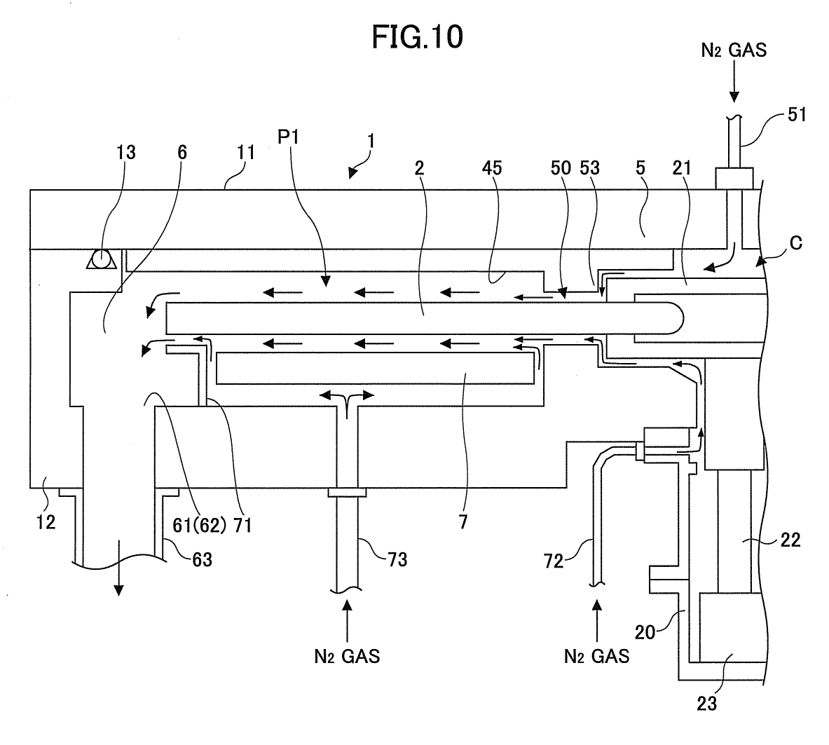

The flow of the third separation gas and the flow of the fourth separation gas are as indicated by the arrows in FIG. 10. By forming the third separation gas supplying portion 72 and the fourth separation gas supplying portion 73, N₂ gas is supplied to the space from the case body 20 to the space of the heater unit 7, and N₂ gas from the gap between the turntable 2 and the cover member 71 is exhausted to the exhaust ports 61 and 62 via the exhaust space 6. Because the flow of the first reactive gas and the second reactive gas from one of the first space P1 and the second space P2 back to the other via the lower part of the turntable 2 is prevented, the third separation gas functions as the separation gas to separate the first reactive gas and the second reactive gas. Because entering of the first reactive gas and the second reactive gas from the first space P1 and the second space P2 into the space under the turntable 2 where the heater unit 7 is arranged is prevented, the fourth separation gas functions to prevent the first reactive gas and the second reactive gas from being adsorbed in the heater unit 7.

Next, the portion disposed in the exterior of the vacuum chamber 1 and the portion provided for conveyance with the exterior of the vacuum chamber 1 will be described.

As illustrated in FIGS. 2, 3 and 11, the conveyance port 15 for delivering the wafer between the external conveyance arm 10 and the turntable 2 is formed in the side wall of the vacuum chamber 1, and this conveyance port 15 is opened and closed by the gate valve which is not illustrated. The delivery of the wafer W is performed between the recess 24 (which is the substrate mounting part in the turntable 2) and the conveyance arm 10 at the position of the conveyance port 15, and the mechanism for raising and lowering the delivery pins 16 which penetrate the recess 24 and lift the back surface of the wafer is disposed at the portion beneath the turntable 2 corresponding to the delivery position.

In the film deposition apparatus of this embodiment illustrated in FIGS. 1 and 3, the control part 100 which includes a computer for controlling operation of the whole apparatus is arranged.

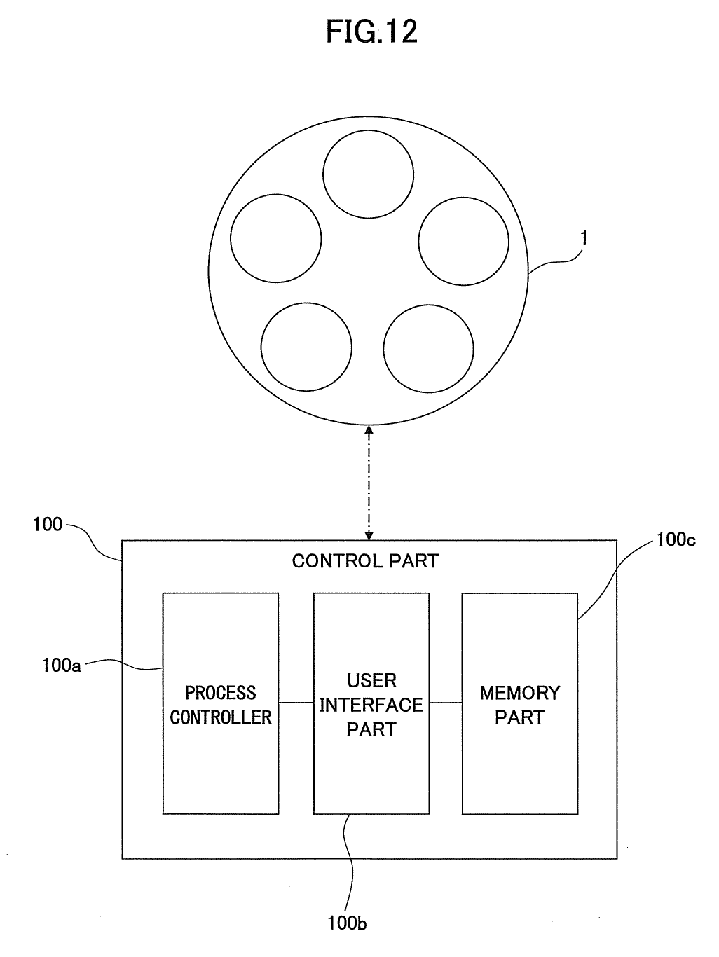

As illustrated in FIG. 12, a process controller 100a which includes a CPU and controls the respective parts of the film deposition apparatus, a user-interface part 100b, and a storage part 100c are arranged in the control part 100.

The user-interface part 100b includes a keyboard which is used by the process manager who manages the film deposition apparatus to input a control command, and a display which visualizes and displays the operating status of the film deposition apparatus.

In the storage part 100c, the specifications which contain a control program (software), processing condition data, etc. for causing the film deposition apparatus to perform various processes under the control of the process controller 10a are stored. If needed, arbitrary specifications are read from the storage part 100c in response to the instruction from the user-interface part 100b, and the process controller 100a is caused to execute the control program so that the requested processing is performed by the film deposition apparatus under the control of the process controller 100a. The specifications, such as the control program and the processing condition data, stored in a computer-readable storage medium (for example, a hard disk, a compact disk, a magneto-optic disk, a memory card, a floppy disk, etc.), may be installed in the process controller 100a, or may be downloaded from other equipment to the process controller 10a at any time via a leased communication line or a network.

Next, the film deposition method performed by the film deposition apparatus of this embodiment will be described with reference to FIGS. 11, 13, and 14.

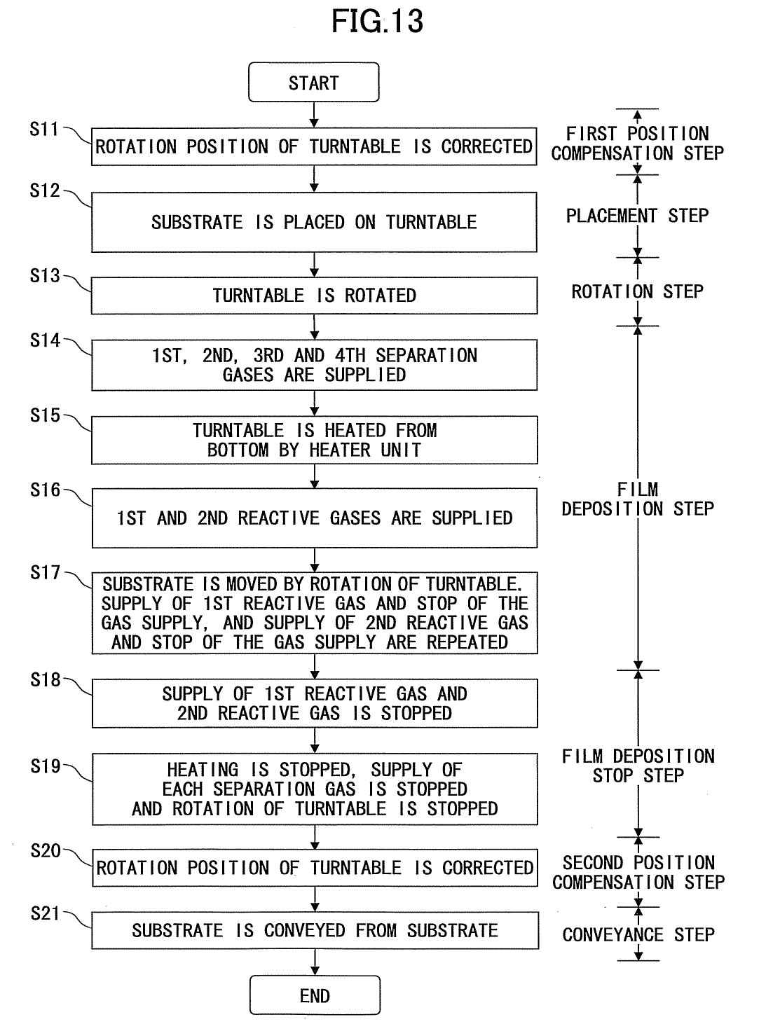

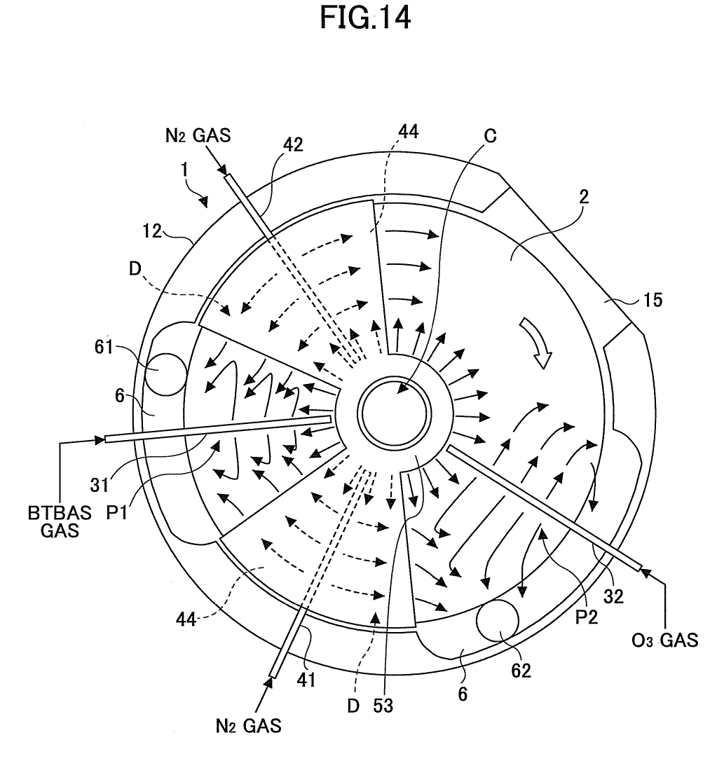

FIG. 13 is a flowchart for explaining the procedure of the film deposition method using the film deposition apparatus of this embodiment. FIG. 14 is a diagram for explaining the film deposition method using the film deposition apparatus of this embodiment, and illustrating the flows of the first reactive gas, the second reactive gas, and the first separation gas.

Similar to FIG. 3, the cross section of the film deposition apparatus in which the top plate 11 of the vacuum chamber 1 is cut horizontally at the position that is lower than the first undersurface portion 45 and the second undersurface portion 45a and higher than the first separation gas supplying portion 41 or 42 is illustrated in FIG. 14.

As is illustrated in steps S11 to S21 of FIG. 13, the film deposition method of this embodiment includes: a first position compensation step which corrects the rotation position of the turntable; a placement step which places the substrate on the turntable; a rotation step which rotates the turntable; a film deposition step in which the turntable is heated from the bottom, the first reactive gas and the second reactive gas are supplied from the first reactive gas supplying portion and the second reactive gas supplying portion, the heated first separation gas is supplied from the first separation gas supplying portion, the substrate is moved with rotation of the turntable 2, supply of the first reactive gas to the surface of the substrate, stop of the supply of the first reactive gas, supply of the second reactive gas, and stop of the supply of the second reactive gas are repeated to form a thin film on the substrate; a film deposition stop step which stops the supply of the first reactive gas and the second reactive gas from the first reactive gas supplying portion and the second reactive gas supplying portion, stops heating of the substrate, stops the supply of each separation gas, and stops rotation of the turntable; a second position compensation step that corrects the rotation position of the turntable; and a conveyance step which takes out the substrate by the conveyance arm.

Upon start of the procedure of FIG. 13, the first position compensation step of step S11 is performed. Step S11 is a step which performs position compensation of the turntable using the position detecting unit provided in the outside of the vacuum chamber on the basis of the rotation position when detecting the detection part of the turntable. Specifically, the turntable 2 is rotated at a rotational speed that is smaller than the rotational speed of the turntable 2 in the normal film deposition step. A change of the light receiving amount E1 of the laser sensor 8 is measured, the rotation position at which the light receiving amount is changed to the value E2 that is smaller than E1 is set to a new reference position (zero), and the rotation position of the turntable is corrected. Because the rotational speed of the turntable 2 in the rotation position compensation step is smaller than the rotational speed in the normal film deposition step, it can be set to 1 rpm or less.

Next, the placement step of step S12 is performed. Step S12 is a step which places the substrate on the turntable the rotation position of which is corrected, through the conveyance port by using the conveyance arm.

Specifically, as illustrated in FIG. 11, the gate valve is opened, and the wafer W from the exterior is delivered to the recess 24 of the turntable 2 through the conveyance port 15 by using the conveyance arm 10. This delivery is performed, as illustrated in FIG. 11, when the recess 24 is stopped at the position which faces the conveyance port 15, and the delivery pins 16 are lifted and lowered from the bottom side of the vacuum chamber via the through holes of the bottom of the recess 24. The delivery of the wafer W is performed by rotating the turntable 2 intermittently, and the wafers W are placed in the five concavities 24 of the turntable 2, respectively.

Subsequently, the rotation step of step S13 is performed. Step S13 is a step which rotates the turntable 2.

Subsequently, the film deposition step of steps S14 to S17 is performed. Step S14 is a step which supplies the first separation gas, the second separation gas, the third separation gas, and the fourth separation gas from the first separation gas supplying portion, the second separation gas supplying portion, the third separation gas supplying portion, and the fourth separation gas supplying portion, respectively. Step S15 is a step which heats the turntable from the bottom by using the heater unit. Step S16 is a step which supplies the first reactive gas and the second reactive gas from the first reactive gas supplying portion 31 and the second reactive gas supplying portion 32, respectively. Step S17 is a step which moves the substrate while the turntable 2 is rotated, and repeats supply of the first reactive gas to the surface of the substrate, stop of the supply of the first reactive gas, supply of the second reactive gas, and stop of the supply of the second reactive gas, so that a thin film is deposited on the substrate.

First, in the film deposition step, step S14 is performed. The internal pressure of the vacuum chamber 1 is set to a predetermined negative pressure by using the vacuum pump 64, and the first separation gas, the second separation gas, the third separation gas, and the fourth separation gas are supplied from the first separation gas supplying portion 41 or 42, the second separation gas supplying portion 51, the third separation gas supplying portion 72, and the fourth separation gas supplying portion 73, respectively.

Subsequently, step S15 is performed. The substrate W is heated by the heater unit 7. In this process, after the wafer W is placed on the turntable 2, the substrate is heated to 300 degrees C. by using the heater unit 7. Alternatively, this process may be performed such that the turntable 2 is beforehand heated to 300 degrees C. by using the heater unit 7, and the wafer W is placed on the heated turntable 2 in order to be heated therein.

Subsequently, step S16 is performed. The first reactive gas and the second reactive gas are supplied from the first reactive gas supplying portion 31 and the second reactive gas supplying portion 32 respectively. In this embodiment, BTBAS gas and O₃ gas are discharged from the first reactive gas supplying portion 31 and the second reactive gas supplying portion 32 respectively. At this time, the temperature of the substrate W is measured by using the temperature sensor, to ensure that the temperature of the substrate W is stably maintained at the predetermined temperature. This measurement may be performed using a radiation thermometer disposed on the bottom of the turntable 2.

In this embodiment, steps S14, S15 and S16 are performed sequentially in this order. Alternatively, the sequence of performing steps S14, S15 and S16 may be altered or may be started simultaneously. For example, these steps may be performed such that BTBAS gas and O₃ gas are discharged from the first reactive gas supplying portion 31 and the second reactive gas supplying portion 32 respectively, and at the same time, N₂ gas (which is the first separation gas) is discharged from the first separation gas supplying portions 41 and 42.

After the steps S14 to S16 are performed in this manner, step S17 is performed. Namely, the substrate is moved while the turntable 2 is rotated, and supply of the first reactive gas to the surface of the substrate, stop of the supply of the first reactive gas, supply of the second reactive gas, and stop of the supply of the second reactive gas are repeated, so that a thin film is deposited on the substrate.

While the turntable 2 is rotated, the wafer W alternately passes through the first space P1 in which the first reactive gas supplying portion 31 is formed and the second space P2 in which the second reactive gas supplying portion 32 is formed. Thus, BTBAS gas is adsorbed and subsequently O₃ gas is adsorbed, and BTBAS molecules are oxidized and one or more layers of the molecules of silicon oxide are formed, so that the molecular layers of silicon oxide are laminated one by one and the silicon oxide film with a predetermined film thickness is deposited on the substrate.

At this time, N₂ gas (which is the second separation gas) is also supplied from the second separation gas supplying portion 51, and the N₂ gas is discharged along the surface of the turntable 2 from the core area C, (or from the area between the projection portion 53 and the core of the turntable 2. In this example, as previously described, the inner peripheral wall of the vacuum chamber 1 along the space beneath the first undersurface portion 45 and the second undersurface portion 45a in which the first reactive gas supplying portion 31 and the second reactive gas supplying portion 32 are arranged, is cut off to form the relatively large space. The exhaust ports 61 and 62 are disposed below this large space, and the pressure of the space beneath the first undersurface portion 45 and the second undersurface portion 45a is lower than the pressure of each of the narrow space beneath the third undersurface portion 44 and the core area C. This is because the pressure difference between the narrow space D beneath the third undersurface portion 44 and the space in which the first (the second) reactive gas supplying portion 31 (32) is arranged, or the pressure difference between the narrow space D and the first space P1 (or the second space P2) is maintained by the third height H3 of the narrow space D.

FIG. 14 illustrates the flows of the gases when the gases are discharged from the respective portions. As illustrated in FIG. 14, O₃ gas, which is discharged from the bottom side of the second reactive gas supplying portion 32 to hit the surfaces of the turntable 2 (other than the surface of the wafer W placed in the recess 24, the surface of the recess 24 in which no wafer W is placed, and the surface of the recess 24) and directed to the upstream position in the rotational direction along the surfaces of the turntable 2, is brought back by N₂ gas which is sent from the upstream position in the rotational direction, and flows into the exhaust space 6 through the gap between the circumference of the turntable 2 and the inner circumferential wall of the vacuum chamber 1, so that the O₃ gas is exhausted from the exhaust port 62.

As illustrated in FIG. 14, O₃ gas, which is discharged from the bottom side of the second reactive gas supplying portion 32 to hit the surfaces of the turntable 2 and directed to the downstream position in the rotational direction along the surfaces of the turntable 2, is partially brought back to the exhaust port 62 because the flow of N₂ gas sent from the core area C and the intake action of the exhaust port 62. The O₃ gas is partially directed to the third space D adjoining the downstream position and tends to flow into the space beneath the third undersurface portion 44.

However, the height and the length in the rotational direction of the third undersurface portion 44 are set to the dimensions needed for preventing entry of the gases into the space beneath the third undersurface portion 44, according to the process parameters including the flow rates of the gases at the time of operation, the O₃ gas mentioned above can hardly flow into the space beneath the third undersurface portion 44 as illustrated in FIG. 6B. Even if the O₃ gas mentioned above partially flows into the space, it cannot reach the position adjacent to the first separation gas supplying portion 41. The O₃ gas is brought back to the upstream position in the rotational direction (on the side of the second space) by N₂ gas sent from the first separation gas supplying portion 41, and flows into the exhaust space 6 through the gap between the circumference of the turntable 2 and the inner circumferential wall of the vacuum chamber 1, together with the N₂ gas discharged from the core area C, so that the O₃ gas is exhausted from the exhaust port 62.

As illustrated in FIG. 14, BTBAS gas, which is discharged from the bottom side of the first reactive gas supplying portion 31 and directed to both the upstream position and the downstream position in the rotational direction along the surface of the turntable 2, cannot enter into the space beneath the third undersurface portion 44 that adjoins the upstream position and the downstream position in the rotational direction. Even if the BTBAS gas partially enters, the BTBAS gas is brought back to the side of the first space P1 and exhausted from the exhaust port 61 via the exhaust space 6 together with the N₂ gas sent from the core area C. In each third space D, entry of the BTBAS gas or O₃ gas, which is the reactive gas flowing in the atmosphere, is prevented, but the gas molecules adsorbed in the wafer pass through the space beneath the third undersurface portion 44 and contribute to the film deposition.

The BTBAS gas in the first space P1 and the O₃ gas in the second space P3 tend to enter into the core area C. However, the second separation gas is discharged from the core area C to the circumference of the turntable 2 as illustrated in FIGS. 10 and 14, entry of the BTBAS gas and the O₃ gas is prevented by the second separation gas. Even if the BTBAS gas and the O₃ gas partially enter, the gases are brought back and flowing of the gases into the first space P1 and the second space P2 through the core area C is prevented.

As previously described, the narrow gap between the curved part 46 and the outer circumferential end face of the turntable 2 is formed in the third space D, to prevent passage of the gas through the narrow gap. The flow of the BTBAS gas in the first space P1 (and the O₃ in the second space P3) into the second space P2 (the first space P1) via the outside of the turntable 2 is also prevented. Therefore, the atmosphere of the first space P1 and the atmosphere of the second space P2 are completely separated by the two third spaces D, and the BTBAS gas is exhausted from the exhaust port 61, and the O₃ gas is exhausted from the exhaust port 62. As a result, the first reactive gas BTBAS gas and the second reactive gas O₃ gas are not mixed on the wafer in the atmosphere. Because the N₂ gas which is the second separation gas is supplied to the space beneath the turntable 2 in this example, the flow of the gas into the exhaust space 6 through the space beneath the turntable 2 is also prevented. Mixing of the BTBAS gas and the O₃ gas is thus prevented.

After the film deposition processing is performed, the film deposition stop step of steps S18 and S19 is performed. Step S18 is a step which stops the supply of the first reactive gas from the first reactive gas supplying portion 31 and the supply of the second reactive gas from the second reactive gas supplying portion 32. Step S19 is a step which stops heating of the turntable and the substrate by using the heater unit 7, stops the supply of the first separation gas, the second separation gas, the third separation gas and the fourth separation gas, and stops the rotation of the turntable 2.

Subsequently, the second position compensation step of step S20 is performed. Step S20 is a step which performs position compensation of the turntable using the position detecting unit provided in the outside of the vacuum chamber, on the basis of the rotation position obtained when the detection part of the turntable is detected. This step is the same as the first position compensation step of step S11 mentioned above.

After the second position compensation step is performed, the conveyance step of step S21 is performed. Step S21 is a step which takes out the substrate through the conveyance port 15 from the turntable the rotation position of which is corrected, by using the conveyance arm 10.

Next, an example of the process parameters will be described. For example, when a wafer W with the diameter of 300 mm is used as a substrate to be processed, the rotational speed of the turntable 2 is set to a rotational speed in a range of 1 rpm and 500 rpm, the process pressure is set to 1067 Pa (8 Torr), and the heating temperature of the wafer W is set to 350 degrees C. For example, the flow rates of BTBAS gas and O₃ gas are set to 100 sccm and 10000 sccm respectively. For example, the flow rate of N₂ gas from the separation gas nozzle 41 or 42 is set to 20000 sccm, and the flow rate of N₂ gas from the second separation gas supplying portion 51 of the core of the vacuum chamber 1 is set to 5000 sccm. For example, the number of cycles of the supply of the reactive gases to one wafer (or the number of times in which the wafer passes through each of the first space P1 and the second space P2) is set to 600 cycles, although it may vary depending on the target film thickness.

In this embodiment, two or more wafers W are arranged on the turntable 2 in the rotational direction of the turntable 2, and the turntable 2 is rotated, so that each wafer passes through the first space P1 and the second space P2. The so-called ALD (or MLD) process is performed, and the film deposition processing can be performed with high throughput. The third space D with a low ceiling surface is disposed between the first space P1 and the second space P2 in the rotational direction, and the separation gas is discharged from the core area C, which is surrounded by the center-of-rotation portion and the vacuum chamber 1 of the turntable 2, to the circumference of the turntable 2. The reactive gases are exhausted via the gap between the circumference of the turntable 2 and the inner circumferential wall of the vacuum chamber 1 with the separation gas being discharged from the core area C and the separation gas being spread to the both sides of the third space D. Mixing of the first and second reactive gases can be prevented, and the film deposition processing can be performed with high throughput. This invention is applicable to the case in which one wafer W is placed on the turntable 2.

The reactive gases that may be used in the film deposition apparatus of the invention are dichlorosilane (DCS), hexachlorodisilane (HCD), trimethyl aluminum (TMA), tetrakis-ethyl-methyl-amino-zirconium (TEMAZr), tris(dimethyl amino) silane (3DMAS), tetrakis-ethyl-methyl-amino-hafnium (TEMHf), bis(tetra methyl heptandionate) strontium (Sr(THD)₂), (methyl-pentadionate)(bis-tetra-methyl-heptandionate) titanium (Ti(MPD)(THD)), monoamino-silane, or the like.

As described above, according to the film deposition apparatus of this embodiment, it is possible to perform the film deposition processing with a high throughput, and it is possible to prevent two or more reactive gas from being mixed on the substrate. The film deposition apparatus of this embodiment includes the detection part disposed in the circumference of the turntable and the position detecting unit for detecting the detection part, and it is possible to carry out accurate detection and correction of a rotation position of the turntable, and it is possible to certainly carry out conveyance of the substrate from the interior to the exterior of the vacuum chamber and vice versa.

In the film deposition apparatus of this embodiment, two kinds of reactive gases are used. The present invention is not restricted to this embodiment. The present invention is also applicable to the cases in which three or more kinds of reactive gases are supplied to the substrate. For example, in a case in which three kinds of reactive gases are used as the first reactive gas, the second reactive gas, and the third reactive gas, the first reactive gas supplying portion, the first separation gas supplying portion, the second reactive gas supplying portion, the first separation gas supplying portion, the third reactive gas supplying portion, and the first separation gas supplying portion may be arranged in this order around the circumference of the vacuum chamber 1 in the circumferential direction, and the areas of the undersurfaces of the top plate 11 of the vacuum chamber 1 including the respective gas supplying portions may be formed.

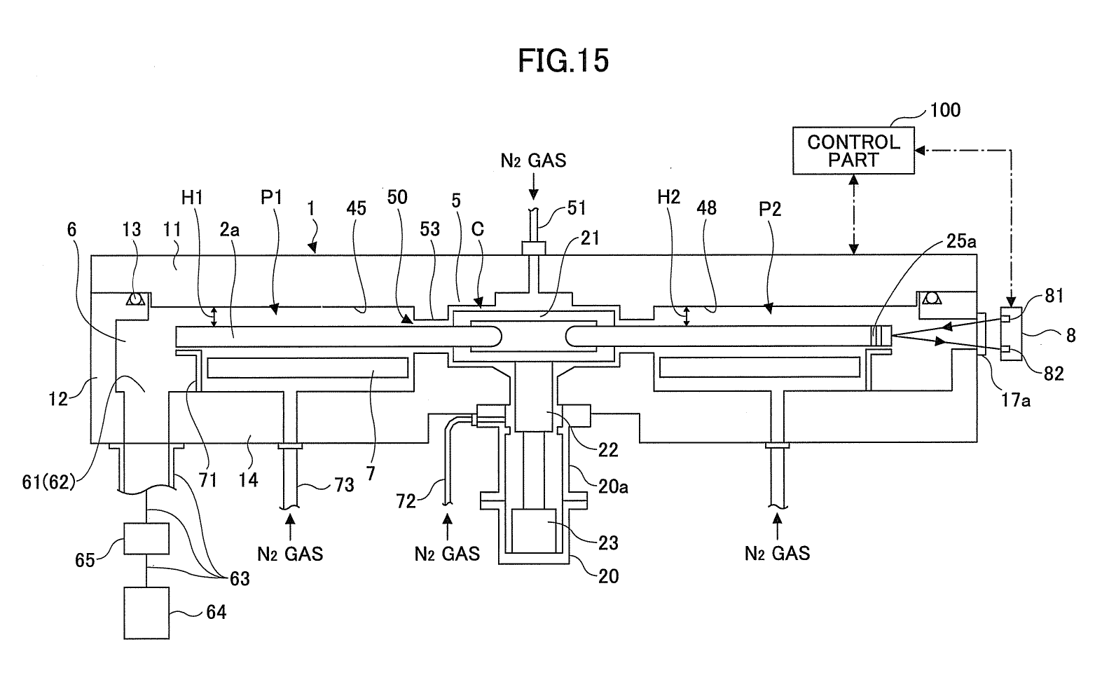

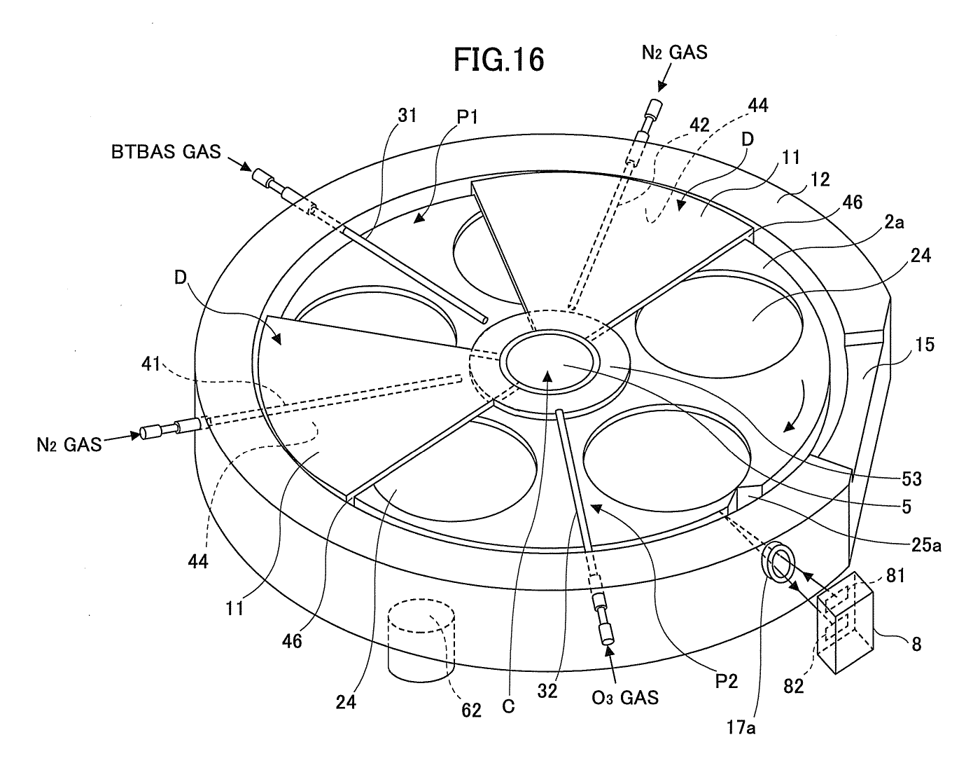

Next, with reference to FIGS. 15 and 16, the film deposition apparatus of a first modification of the first embodiment of the invention will be described.

FIG. 15 is a cross-sectional view illustrating the composition of the film deposition apparatus of this modification. FIG. 16 is a perspective view illustrating the arrangement between a position detecting unit and a detection part in the film deposition apparatus of this modification. In FIGS. 15 and 16, the elements which are the same as corresponding elements in the previously described embodiment are designated by the same reference numerals, and a description thereof will be omitted. Also in the subsequently described modifications and embodiments, the elements which are the same as corresponding elements in the previously described embodiment are designated by the same reference numerals, and a description thereof will be omitted.

The film deposition apparatus of this modification is different from the film deposition apparatus of the first embodiment in that a detection part is formed in the side circumference of the turntable.

Referring to FIGS. 15 and 16, the detection part 25a in this modification is different from the detection part formed on the circumference of the upper surface of the turntable in the first embodiment. The detection part 25a is formed in the side circumference of the turntable 2a, and the laser sensor 8 is arranged on the outside of the side circumference of the container main part 12 of the vacuum chamber 1.

The detection part 25a is formed in the side circumference of the turntable 2a, as illustrated in FIGS. 15 and 16. The configuration of the detection part 25a, if it is detectable by the laser sensor 8, is not limited. For example, the detection part 25a is a scribed line formed in one place of the side circumference of the turntable 2a in the shaft direction of the turntable 2a. Because the detection part 25a in this modification is the scribed line formed in the shaft direction of the turntable 2a in the side circumference of the turntable 2a, the cross section of the detection part 25a perpendicular to the rotary shaft of the turntable 2a is triangular as in the first embodiment.

As illustrated in FIGS. 15 and 16, the laser sensor 8 is disposed in the radial position outside the side circumference of the turntable 2a, so that the detection part 25a of the turntable 2a can be detected. The laser sensor 8 including the light emitting element 81 and the light receiving element 82 is the same as that of the first embodiment. The laser sensor 8 may be provided in the interior of the vacuum chamber 1 similar to the first embodiment. In this modification, the laser sensor 8 is disposed outside the side circumference of the container main part 12 of the vacuum chamber 1, as illustrated in FIGS. 15 and 16.

At this time, an entrance window 17a is formed in the position at which the laser sensor 8 is projected to the center of rotation of the turntable 2a in the side circumference of the container main part 12 of the vacuum chamber 1. The laser beam emitted from the light emitting element 81 of the laser sensor 8 enters into the side circumference of the turntable 2a. The entrance window 17a is for enabling the laser beam reflected by the side circumference of the turntable 2a to enter into the light receiving element 82 of the laser sensor 8.

Provided that the laser sensor 8 is disposed in the interior of the vacuum chamber 1, the entrance window 17a may be omitted in a manner similar to the first embodiment.

The detection of a rotation position of the turntable 2a using the laser sensor 8 and the detection part 25a in this modification is carried out in a manner similar to that of the first embodiment. For example, if the diameter of the turntable 2a is equal to 960 mm and a scribed line having a depth of 2 mm, a width of 1 mm in the rotational direction and a length of 5 mm in the radial direction is formed in the side circumference of the turntable 2a, the rotation position detection and correction can be carried out with the precision of ±0.3 mm. Therefore, if the detection part 25a is formed in the side circumference of the turntable 2a, the same effect as the first embodiment is acquired.

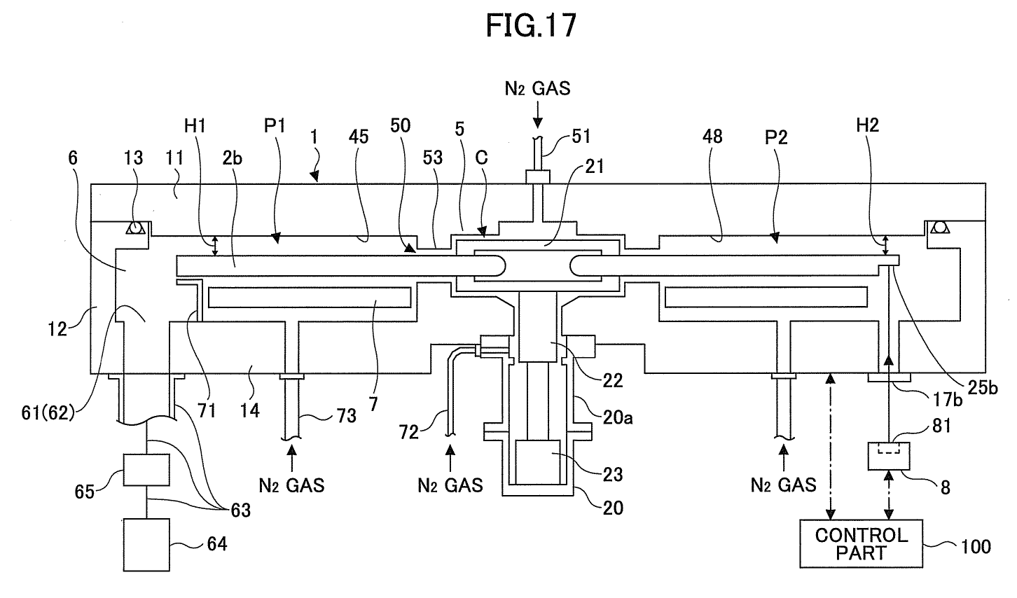

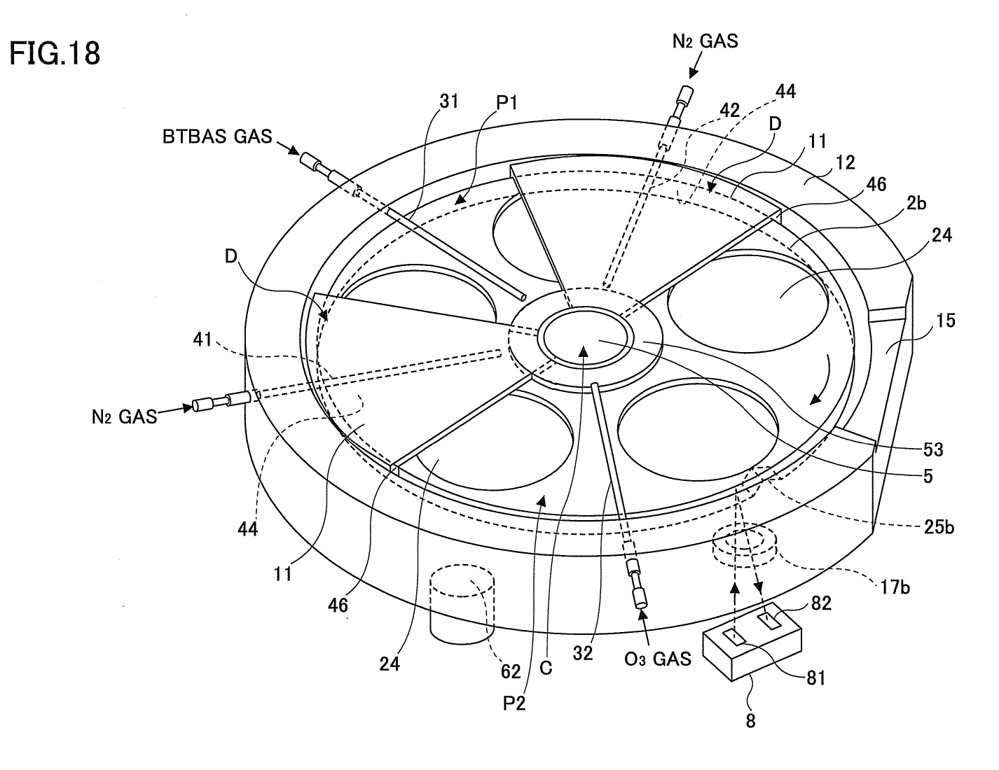

Next, with reference to FIGS. 17 and 18, the film deposition apparatus of a second modification of the first embodiment of the invention will be described.

FIG. 17 is a cross-sectional view illustrating the composition of the film deposition apparatus of this modification. FIG. 18 is a perspective view illustrating the arrangement of a position detecting unit and a detection part in the film deposition apparatus of this modification.

The film deposition apparatus of this modification is different from the film deposition apparatus of the first embodiment in that a detection part is formed in the undersurface of the turntable.

Referring to FIGS. 17 and 18, differing from the first embodiment in which the detection part is formed in the circumference of the upper surface of the turntable, the detection part 25b in this modification is formed in the undersurface of the turntable 2b, and the laser sensor 8 is arranged at the base part 14 of the vacuum chamber 1.

The detection part 25b is formed in the undersurface of the turntable 2b, as illustrated in FIGS. 17 and 18. The configuration of the detection part 25b, if it is detectable by the laser sensor 8, is not limited. For example, the detection part 25b in this modification is a scribed line formed in one place of the circumference of the undersurface of the turntable 2b in the radial direction of the turntable 2b. Because the detection part 25b is the scribed line formed in the undersurface of the turntable 2b in the shaft direction of the turntable 2b, the cross section of the detection part 25b perpendicular to the radial direction of the turntable 2b is triangular as in the first embodiment.

As illustrated in FIGS. 17 and 18, the laser sensor 8 is formed in a lower position from the circumference of the undersurface of the turntable 2b, so that the detection part 25b of the turntable 2b can be detected. The laser sensor 8 including the light emitting element 81 and the light receiving element 82 is the same as that of the first embodiment. The laser sensor 8 may be provided in the interior of the vacuum chamber 1 in a manner similar to the first embodiment. In this modification, the laser sensor 8 is disposed in the base part 14 of the vacuum chamber 1, as illustrated in FIGS. 17 and 18.

At this time, an entrance window 17b is formed in the position at which the laser sensor 8 is projected in parallel with the rotary shaft of the turntable 2b to the base part 14 of the vacuum chamber 1. The laser beam emitted from the light emitting element 81 of the laser sensor 8 enters into the undersurface of the turntable 2b, and the entrance window 17b is for enabling the laser beam reflected on the undersurface of the turntable 2b to enter into the light receiving element 82 of the laser sensor 8.

Provided that the laser sensor 8 is disposed in the interior of the vacuum chamber 1, the entrance window 17b may be omitted in a manner similar to the first embodiment.

The detection of a rotation position of the turntable 2b using the laser sensor 8 and the detection part 25b in this modification is carried out in a manner similar to that of the first embodiment. For example, if the diameter of the turntable 2b is equal to 960 mm and a scribed line having a depth of 2 mm, a width of 1 mm in the rotational direction and a length of 5 mm in the radial direction is formed in the circumference of the undersurface of the turntable 2b, the rotation position detection and correction can be carried out with the precision of ±0.3 mm. Therefore, if the detection part 25b is formed in the undersurface of the turntable 2b, the same effect as the first embodiment is acquired.

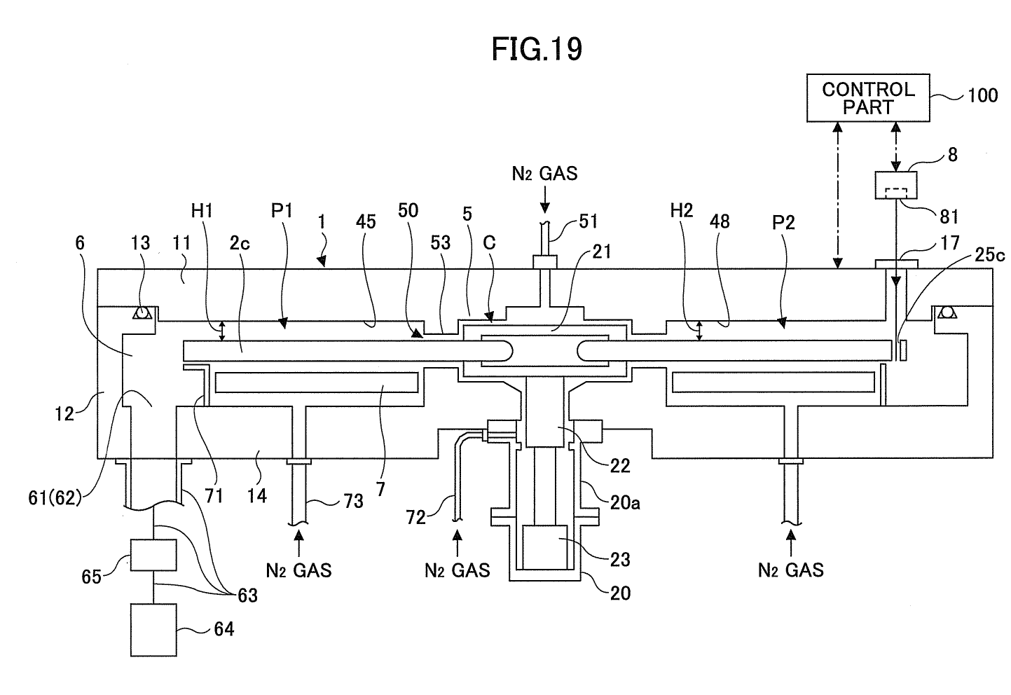

Next, with reference to FIGS. 19 through 21B, the film deposition apparatus of a third modification of the first embodiment of the invention will be described.

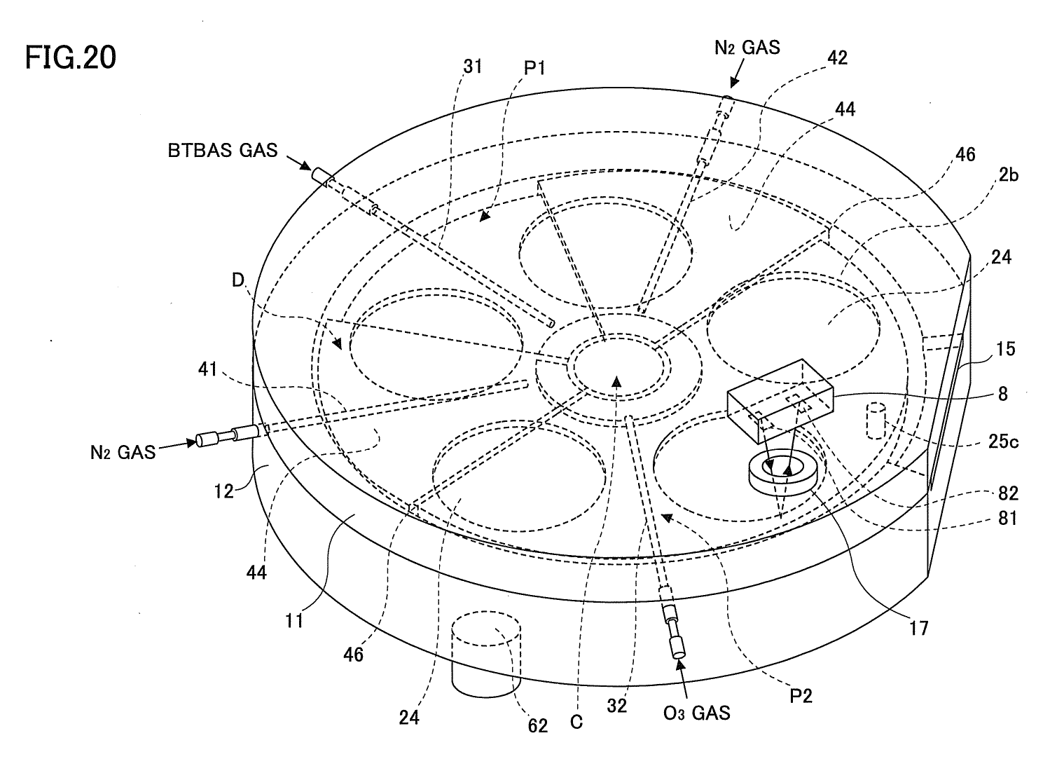

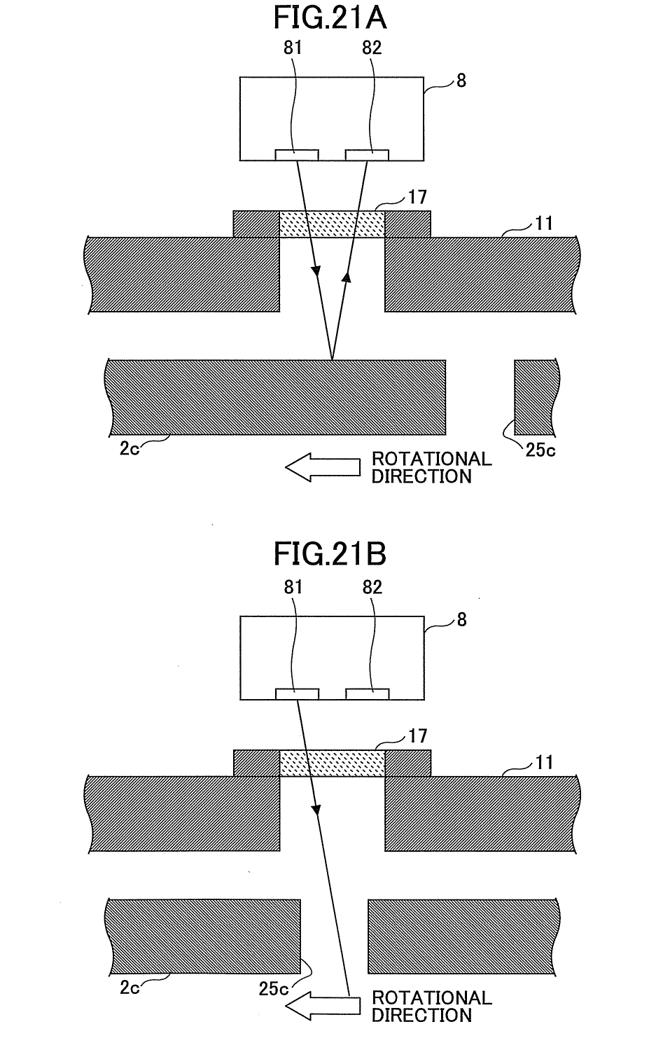

FIG. 19 is a cross-sectional view illustrating the composition of the film deposition apparatus of this modification. FIG. 20 is a perspective view illustrating the arrangement between a position detecting unit and a detection part in the film deposition apparatus of this modification. FIGS. 21A and 21B are diagrams for explaining operation of a position detecting unit in the film deposition apparatus of this modification. FIG. 21A illustrates the state where the detection part is not detected, and FIG. 21B illustrates the state where the detection part is detected.

The film deposition apparatus of this modification is different from the film deposition apparatus of the first embodiment in that the detection part is a through hole.

Referring to FIGS. 19 through 21B, a detection part 25c in this modification is a through hole, which is different from the detection part in the first embodiment, which is a scribed line formed in the radial direction of the turntable. The detection part 25c is formed in the circumference of the upper surface of the turntable 2c as illustrated in FIGS. 19 and 20. The detection part 25c is a through hole which penetrates the upper surface and the undersurface and has a cylindrical form. Because the detection part 25c is the through hole provided in the circumference of the upper surface of the turntable 2c, the cross section of the detection part 25c perpendicular to the radial direction of the turntable 2c is rectangular as illustrated in FIGS. 21A and 21B.

As illustrated in FIG. 19, similar to the first embodiment, the laser sensor 8 is disposed above the top plate 11 of the vacuum chamber 1 and the entrance window 17 is formed in the position at which the laser sensor 8 is projected in parallel with the rotary shaft of the turntable 2c to the top plate 11.

The detection of a rotation position of the turntable 2c using the laser sensor 8 and the detection part 25c in the film deposition apparatus of this modification will be described with reference to FIGS. 21A and 21B.

As illustrated in FIG. 21A, similar to the first embodiment, a relative position and a relative angle between the laser sensor 8 and the entrance window 17 are adjusted so that, when the laser beam from the laser sensor 8 enters into the place where the detection part 25c is not provided, almost all the reflected light may be reflected to the light receiving element 82. The light receiving amount of the light receiving element 82 at this time is set to E3.

On the other hand, as illustrated in FIG. 21B, when the turntable 2c is rotated and the detection part 25c (the through hole) is moved to the position where the laser beam from the laser sensor 8 enters into the detection part 25c, the laser beam is no longer reflected, and the quantity of light entering into the light receiving element 82 of the laser sensor 8 decreases. The light receiving amount of the light receiving element 82 at this time is set to E4. That is, the condition of the light receiving amount is set to E4<E3.

Accordingly, if a difference of the light receiving amount (E4−E3) is detected, it can be determined whether the detection part 25c formed in the circumference of the upper surface of the turntable 2c has passed through the position beneath the laser sensor 8 and the entrance window 17. If a rotation position of the turntable 2c when the passage of the detection part 25c is detected by the laser sensor 8 is used as the reference position, the rotation position of the turntable 2c can be corrected with good accuracy. Specifically, if the diameter of the turntable 2c is equal to 960 mm and the diameter of the through hole formed in the circumference of the upper surface of the turntable 2c is equal to 2 mm, the rotation position detection and correction can be carried out with the precision of ±0.3 mm. Therefore, if the through hole is provided in the circumference of the upper surface of the turntable 2c as the detection part 25c, the same effect as the first embodiment is acquired.

If a difference of the light receiving amount is detectable, it is not necessary that the detection part 25c has to be a through hole penetrating the surface of the turntable 2c. For example, a hole that does not penetrate the surface of the turntable 2c and has a diameter of 2 mm and a depth of 1 to 2 mm may be used as the detection part 25c.

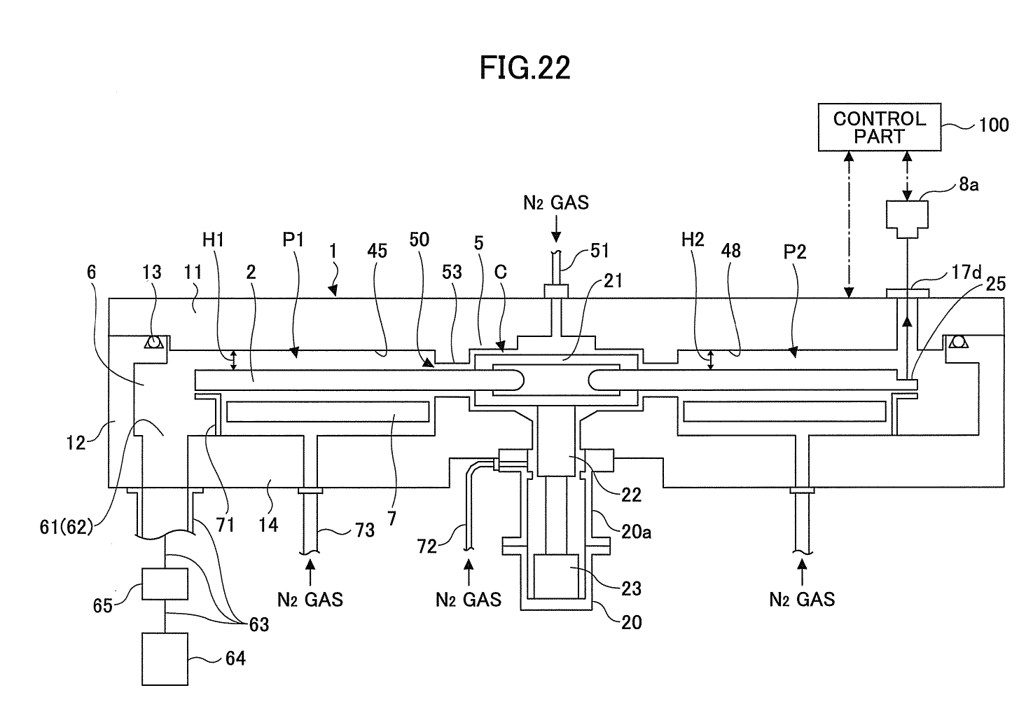

Next, with reference to FIG. 22, the film deposition apparatus of a fourth modification of the first embodiment of the invention will be described. FIG. 22 is a cross-sectional view illustrating the composition of the film deposition apparatus of this modification.

The film deposition apparatus of this modification is different from the film deposition apparatus of the first embodiment in that a position detecting unit is a camera.

Referring to FIG. 22, it is different from a position detecting unit being a laser sensor in the first embodiment, and a position detecting unit is a camera 8a in this modification. The detection part 25 which is a scribed line formed in the radial direction on the circumference of the upper surface of the turntable 2 is the same as that of the first embodiment.

However, unlike the first embodiment, the camera 8a is used as a position detecting unit. The camera in this modification may be a commonly used camera, such as a CCD (charge coupled device) camera or a CMOS (complementary metal oxide semiconductor) camera.

As illustrated in FIG. 22, the camera 8a is disposed above the circumference of the upper surface of the turntable 2 so that the detection part 25 of the turntable 2 can be observed. In the top plate 11 of the vacuum chamber 1, an observation window 17d is formed at the position where the detection part 25 of the turntable 2 can be observed by the camera 8a.

The detection of a rotation position of the turntable 2 using the camera 8a and the detection part 25 in the film deposition apparatus of this modification will be described.

For example, when the detection part 25 passes through the observation position of the camera a, the light receiving amount of the camera 8a changes. By detecting a difference of the light receiving amount, a rotation position of the turntable 2 can be detected. A captured image of the portion of the upper surface of the turntable 2 in which the detection part 25 is formed and a captured image of the portion of the upper surface of the turntables 2 other than the detection part 25 are recorded beforehand, and by comparing the captured image of the camera when the turntable 2 is rotated with the previously recorded images, the rotation position of the turntable 2 is detectable.

If an image of the detection part 25 can be recognized by the camera 8a, the composition of the detection part 25 is not limited. A detection part 25 with a configuration or color different from the other portion of the turntable 2 may be used.

Specifically, when a CCD camera of 1 million pixels is used, the rotation position detection and correction can be carried out with the precision of ±0.1 mm by forming a scribed line, having a depth of 2 mm, a width of 1 mm in the rotational direction and a length of 5 mm in the shaft direction, in the circumference of the upper surface of the turntable 2.

As described above, by using the camera as the position detecting unit, the level of precision of the rotation position detection can be improved further from that of the first embodiment.

Next, with reference to FIGS. 13 and 23-27C, the film deposition apparatus of a fifth modification of the first embodiment of the invention will be described.

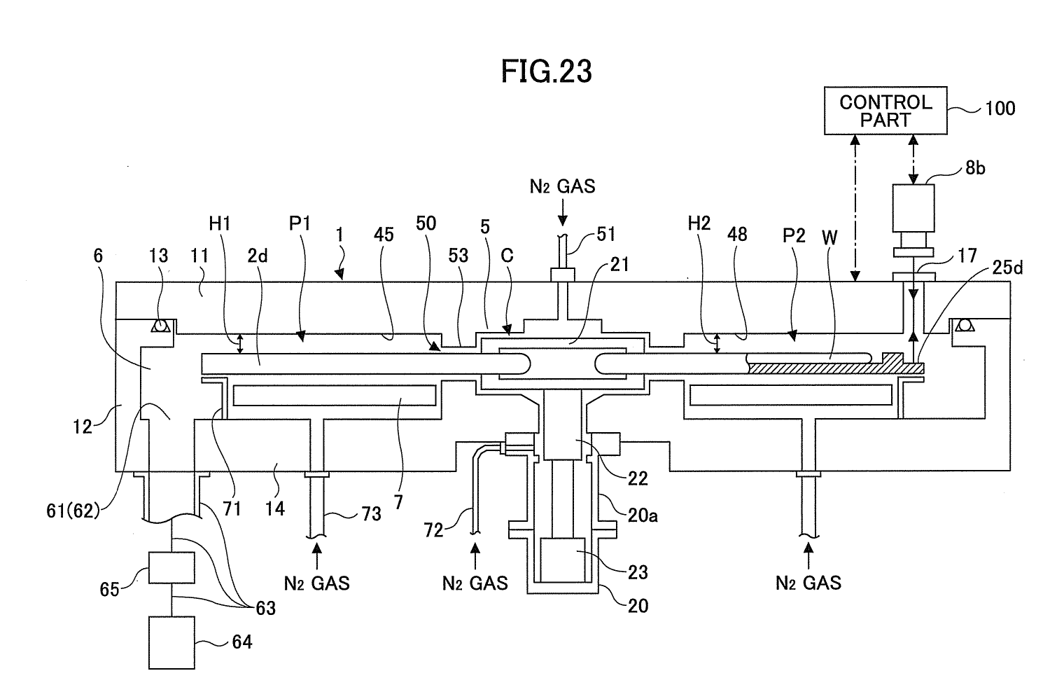

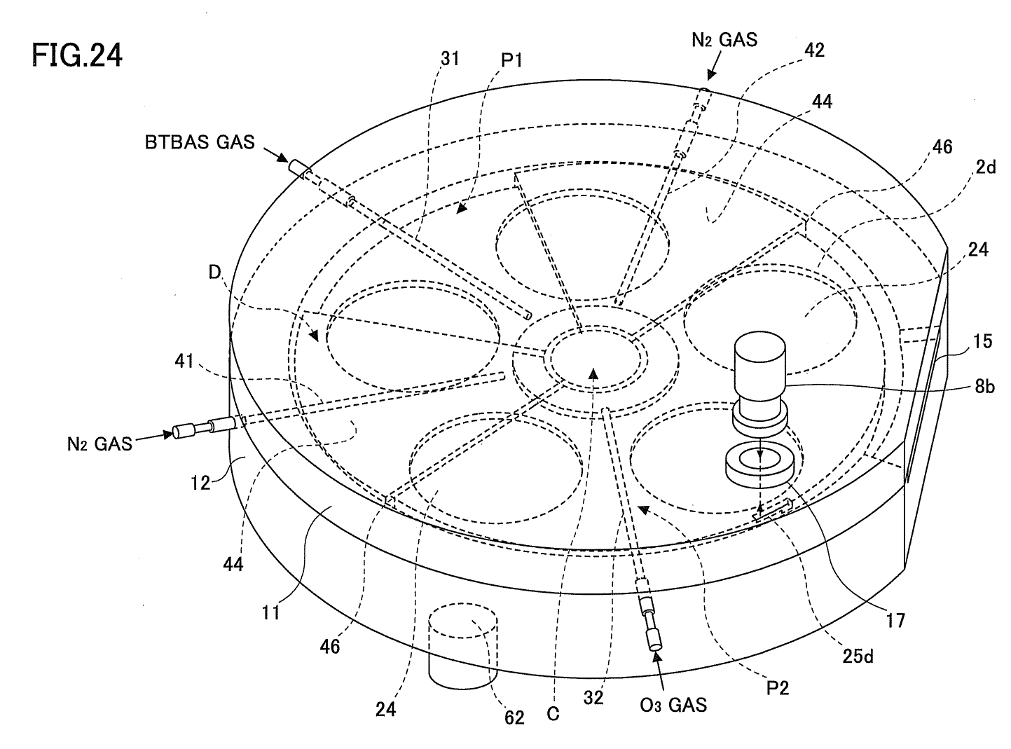

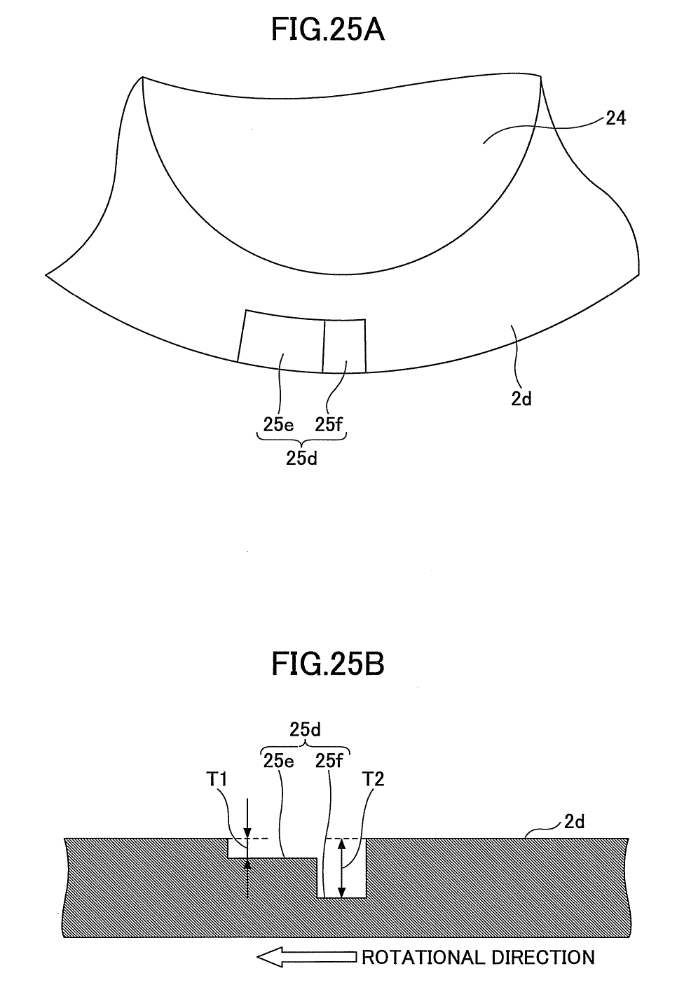

Referring to FIGS. 23 through 25B, the film deposition apparatus of this modification will be described. FIG. 23 is a cross-sectional view illustrating the composition of the film deposition apparatus of this modification. FIG. 24 is a diagram for explaining the film deposition apparatus of this modification, and is a perspective view for explaining the relation of arrangement between a position detecting unit and a detection part. FIGS. 25A and 25B are enlarged views near the detection part of the turntable of the film deposition apparatus of this modification. FIG. 25A is a plan view of the turntable, and FIG. 25B is a cross-sectional view of the turntable taken in the rotational direction of the turntable.

The film deposition apparatus of this modification differs from the film deposition apparatus of the first embodiment in that the laser sensor as the position detecting unit detects the detection part according to a change of a distance between the laser sensor and the surface of the turntable.

In the first embodiment, the light receiving amount after the laser beam from the light emitting element of the laser sensor is reflected by the turntable and enters into the light receiving element of the laser sensor is measured and the detection part is detected according to a change of the light receiving amount. This modification is different from the first embodiment. As illustrated in FIGS. 23 and 24, in this modification, a distance between the laser sensor 8b and the surface of the turntable 2d is measured, and the detection part 25d is detected according to a change of the distance.

The composition other than the position detecting unit and the detection part of the film deposition apparatus of this modification is the same as that of the film deposition apparatus of the first embodiment. Namely, as illustrated in FIGS. 23 and 24, in the film deposition apparatus of this modification, other than the laser sensor 8b and the turntable 2d, the vacuum chamber 1, the first reactive gas supplying portion 31, the second reactive gas supplying portion 32, and the first separation gas supplying portions 41, 42 are the same as those corresponding elements in the first embodiment, and a description thereof will be omitted.

In the film deposition apparatus of this modification, the turntable 2d and the laser sensor 8b differ from those in the first embodiment. Similar to the first embodiment, the turntable 2d has a center of rotation at the center of the vacuum chamber 1 and includes the case bodies 20 and 20a, the core part 21, the rotary shaft 22, the drive part 23, and the recesses 24.

The turntable 2d includes the detection part 25d which is different from that of the first embodiment, and the detection part 25d is provided in the circumference of the upper surface of the turntable 2d. The detection part 25d is the portion for measuring a distance between the laser sensor 8b and the turntable 2d, which will be described later.

The detection part 25d is not a scribed line as in the first embodiment, but it includes first and second step parts 25e and 25f which have mutually different depths from the surface of the turntable 2d as illustrated in FIGS. 25A and 25B. In this modification, the first and second step parts 25e and 25f are concavities having flat bottoms with predetermined depths T1 and T2, from the upper surface of the turntable 2d, respectively, as illustrated in FIGS. 25A and 25B.

The first and second step parts 25e and 25f are arranged in the rotational direction of the turntable 2d to be in contact with each other. If the front end of the second step part 25f is arranged to come in contact with the back end of the first step part 25e in the rotational direction of the turntable 2d, the first and second step parts 25e and 25f may be arranged so that the depth T2 of the second step part 25f from the upper surface of the turntable 2d is larger than the depth T1 of the first step part 25e from the upper surface of the turntable 2d, namely, to meet the condition T2>T1.

Although the values of the depths T1 and T2 are not limited, the values of the depths T1 and T2 may be set to about 3 mm and about 6 mm, respectively.

The first and second step parts 25e and 25f may be disposed at mutually adjacent front and back positions in the rotational direction of the turntable 2d. Alternatively, the first and second step parts 25e and 25f may be formed into projections having mutually different heights T1 and T2 from the upper surface of the turntable 2d. Moreover, regardless of whether the first and second step parts 25e and 25f are formed into concavities or projections, the relationship of the depths T1 and T2 may be set to meet the condition T2<T1.

As illustrated in FIGS. 23 and 24, the laser sensor 8b is provided above the circumference of the upper surface of the turntable 2d so that the detection part 25d of the turntable 2d can be detected, similar to that of the first embodiment. Similar to the first embodiment, the laser sensor 8b is provided above the top plate 11 of the vacuum chamber 1, as illustrated in FIGS. 23 and 24, and the entrance window 17 is formed in the position at which the laser sensor 8b is projected in parallel to the rotary shaft of the turntable 2d to the top plate 11 of the vacuum chamber 1. This modification is not limited to the laser sensor 8b disposed in the exterior of the vacuum chamber 1. Alternatively, the laser sensor 8b may be disposed in the interior of the vacuum chamber 1.

Although the laser sensor 8b contains the light emitting element which emits a laser beam (which is not illustrated) and the light receiving element which receives the laser beam (which is not illustrated), it is different from that of the first embodiment and has a function which measures a distance between the laser sensor and the device being measured. The method of measuring a distance between the laser sensor 8b and the device being measured is not limited. For example, a measuring method which measures a distance by measuring a phase difference between the incident light and the reflected light may be used. In addition, any measuring device may be used as the laser sensor 8b if the device is able to measure a distance.

Next, with reference to FIGS. 13, 26 to 27C, the film deposition method using the film deposition apparatus of this modification will be described.

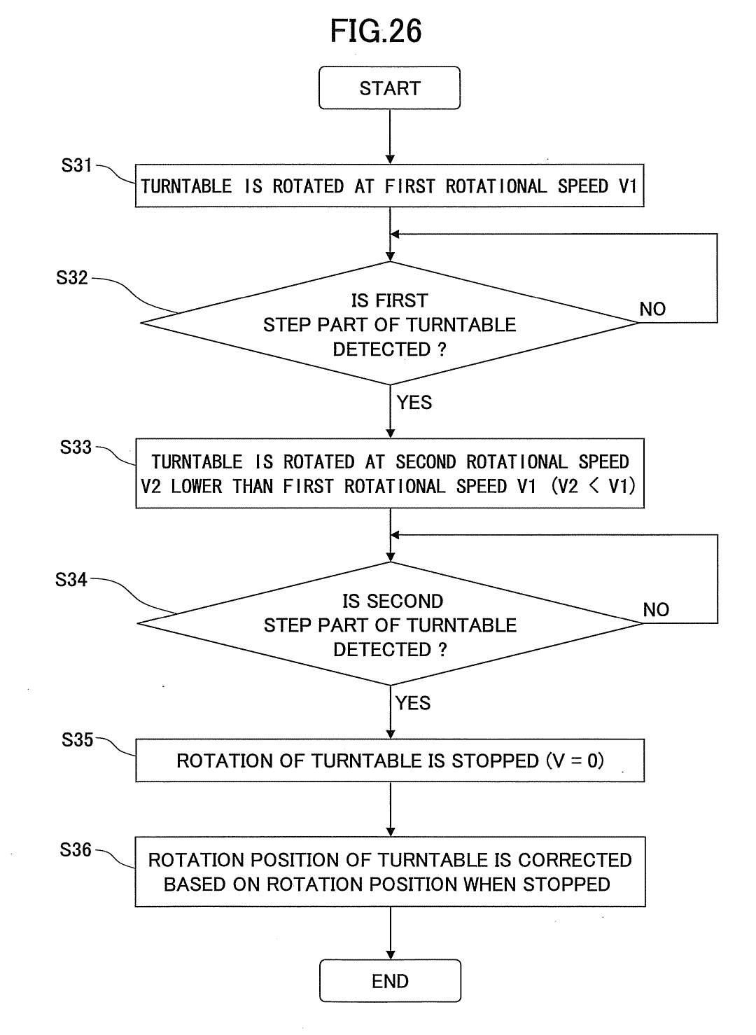

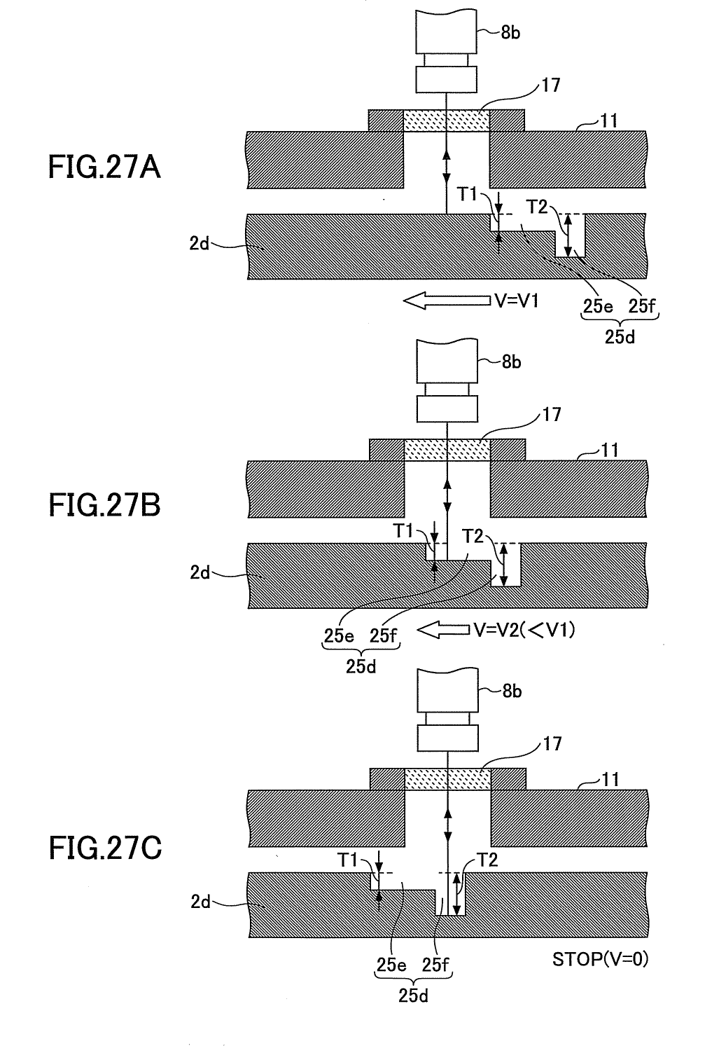

FIG. 26 is a flowchart for explaining the procedure of the position compensation step by the film deposition apparatus of this modification. FIGS. 27A through 27C are cross-sectional views illustrating the state of the laser sensor and the turntable in the position compensation step by the film deposition apparatus of this modification.

The procedure of the film deposition method using the film deposition apparatus of this modification may be formed in the same manner as the film deposition method illustrated in FIG. 13 by the film deposition apparatus of the first embodiment, except the position compensation step among the steps of the film deposition method using the film deposition apparatus of this modification. Specifically, among the steps S11 to S21 in the procedure of FIG. 13, steps S12-S19 and S21 may be performed in the same manner as in the first embodiment.

Step S12 is an installation step which places the substrate on the turntable 2d. Step S13 is a rotation step which rotates the turntable 2d. Steps S14 to S17 constitute a film deposition step which heats the turntable 2d from the bottom, supplies the first reactive gas and the second reactive gas from the first reactive gas supplying portion 31 and the second reactive gas supplying portion 32, supplies the heated first separation gas from the first separation gas supplying portion 41 or 42, moves the substrate while the turntable 2d is rotated, and repeats supply of the first reactive gas to the surface of the substrate, stop of the supply of the first reactive gas, supply of the second reactive gas to the surface of the substrate, and stop of the supply of the second reactive gas so that a thin film is deposited on the substrate.

Steps S18 and S19 constitute a film deposition stop step which stops the supply of the first reactive gas from the first reactive gas supplying portion 31, stops the supply of the second reactive gas from the second reactive gas supplying portion 32, stops heating of the substrate, stops the supply of each separation gas, and stops rotation of the turntable 2d.

Step S21 is a conveyance step which takes out the substrate from the vacuum chamber using the conveyance arm.

The position compensation step of this modification differs from the first and second position compensation steps which are the steps S11 and S20 of FIG. 13 in the first embodiment. That is, the position compensation step of this modification include steps S31 to S36 as illustrated in FIG. 26.

The position compensation step of this modification roughly determines a rotation position using the first step part 25e when the turntable 2d is rotated at high speed, and when the turntable 2d is rotated at low speed, a rotation position is determined precisely using the second step part 25f.

Upon start of the procedure of FIG. 26, step S31 is performed. Step S31 is a step which rotates the turntable 2d at a predetermined rotational speed V. Suppose that the rotational speed V of the turntable 2d in step S31 is the first rotational speed V1. The rotational speed V1 is not limited to a specific value. For example, the value of the rotational speed V1 may be set to about 1 rpm. For example, when the value of V1 is set to about 1 rpm, the length of the first step part 25e in the rotational direction may be set to about 30 mm.

Next, step S32 is performed. Step S32 is a step which determines whether the first step part 25e of the turntable 2d is detected by the laser sensor 8b. Specifically, a distance between the laser sensor 8b and the surface of the turntable 2d is measured by the laser sensor 8b, and it is determined whether the measured distance is changed from the predetermined distance value corresponding to the upper surface of the turntable 2d to be larger than the threshold that is set up beforehand corresponding to the predetermined step depth T1.

If the first step part 25e of the turntable 2d is not detected as a result of the determination, the measurement of a distance between the laser sensor 8b and the surface of the turntable 2d by the laser sensor 8b and the determination are performed again.

FIG. 27A illustrates the state where the turntable 2d is rotated at the rotational speed V=V1, the incident light from the laser sensor 8b has entered into the upper surface of the turntable 2d which is located in front of the first step part 25e, and it is not yet determined that the first step part 25e of the turntable 2d is detected as a result of the determination of step S32.

When it is determined as a result of the determination of step S32 that the first step part 25e of the turntable 2d is detected, the control is transferred to step S33. Step S33 is a step which decreases the rotational speed of the turntable 2d from the first rotational speed V1. If it is assumed that the rotational speed after slowing down is the second rotational speed V2, step S33 is a step which rotates the turntable 2d at a second rotational speed V2 lower than the first rotational speed V1. That is, the rotational speed of the turntable 2d is set to V2<V1. The value of V2 is equal to about 0.1 rpm, although it is not limited. If the value of V2 is equal to about 0.1 rpm, the length of the second step part 25f in the rotational direction may be set to about 10 mm, for example.

Next, step S34 is performed. Step S34 is a step which determines whether the second step part 25f of the turntable 2d is detected by the laser sensor 8b. Specifically, a distance between the laser sensor 8b and the surface of the turntable 2d is measured by the laser sensor 8b, and it is determined whether the measured distance is changed from the predetermined distance value corresponding to the upper surface of the turntable 2d to be larger than the threshold which is beforehand set up corresponding to the depth T2. Alternatively, it may be determined whether the measured distance is changed from the distance value when the first step part 25e is detected to be larger than the threshold which is beforehand set up corresponding to the depth (T2−T1).

If the second step part 25f of the turntable 2d is not detected as a result of a determination, the measurement of a distance between the laser sensor 8b and the surface of the turntable 2d by the laser sensor 8b and the determination are performed again.

FIG. 27B illustrates the state where the turntable 2d is rotated at the rotational speed V=V2, the incident light from the laser sensor 8b has entered into the first step part 25e in front of the second step part 25f, and it is not determined as a result of the determination of step S34 that the second step part 25f of the turntable 2d is detected.

When it is determined as a result of the determination of step S34 that the second step part 25f of the turntable 2d is detected, the control is transferred to step S35. Step S35 is a step which stops the rotation of the turntable 2d. The rotational speed V of the turntable 2d at this time is set to V=0.

FIG. 27C illustrates the state where the rotation of the turntable 2d is stopped (V 0) and the incident light from the laser sensor 8b has entered into the second step part 25f.

Subsequently, step S36 is performed. Step S36 is a step which performs position compensation of the turntable 2d on the basis of the rotation position obtained when the rotation of the turntable 2d is stopped.

By performing steps S31-S35, the repeatability of the rotation position of the turntable 2d is good and the rotation of the turntable 2d is stopped in the predetermined position. The rotation angle of the turntable 2d can be corrected with sufficient repeatability by setting the angular position at this time to 0 degrees.

If the position compensation of step S36 can be performed simultaneously when it is determined as a result of the determination of step S34 that the second step part 25f of the turntable 2d is detected, it is not necessary to stop the rotation of the turntable 2d in step S35.

According to the film deposition apparatus of this modification, the rotation angle of the turntable is monitored from the exterior and it is possible to perform positioning of the turntable regardless of the state in the vacuum chamber. After the rotation position of the turntable when the turntable is rotated at high speed (V=V1) is roughly detected using the first step part, the rotation position of the turntable when the turntable is rotated at low speed (V=V2<V1) can be accurately detected using the second step part. Therefore, the time for performing the position compensation step can be shortened, and it is possible to perform positioning of the turntable with good accuracy.

The first and second step parts (which constitute the detection part) may be provided in the side circumference of the turntable similar to the first modification of the first embodiment. In this case, the laser sensor may be disposed in the outside of the side circumference of the container main part of the vacuum chamber. In the side circumference of the container main part of the vacuum chamber, the entrance window may be formed in the position at which the laser sensor is projected to the center of rotation of the turntable. The position of the entrance window may be the same as the position in the first modification of the first embodiment of FIGS. 15 and 16.

The first and second step parts (which constitute the detection part) may be provided in the undersurface of the turntable similar to the second modification of the first embodiment. In this case, the laser sensor may be disposed below the base part of the vacuum chamber. The entrance window may be formed in the base part of the vacuum chamber in the position at which the laser sensor is projected in parallel with the rotary shaft of the turntable. The position of the entrance window may be the same as the position in the second modification of the first embodiment of FIGS. 17 and 18.

The kicker and the photosensor which detect a rotation position of the rotary shaft of the turntable which will be described later in the sixth modification of the first embodiment may be provided in addition to the first and second step parts which are formed in this modification. At this time, the kicker and the photosensor may be formed to detect beforehand a rotation position of the rotary shaft of the turntable before the first step part is detected by the laser sensor. By using the kicker and the photosensor additionally, the time needed for the position compensation step can be further reduced.

Next, with reference to FIGS. 13 and 28-32C, the film deposition apparatus of the sixth modification of the first embodiment of the invention will be described.

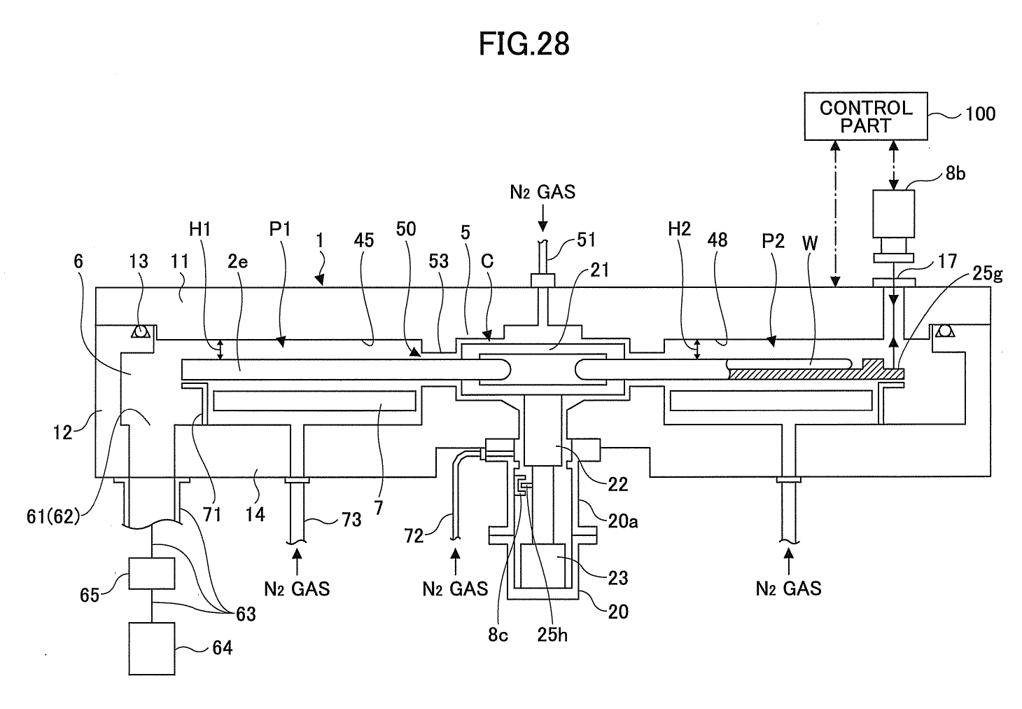

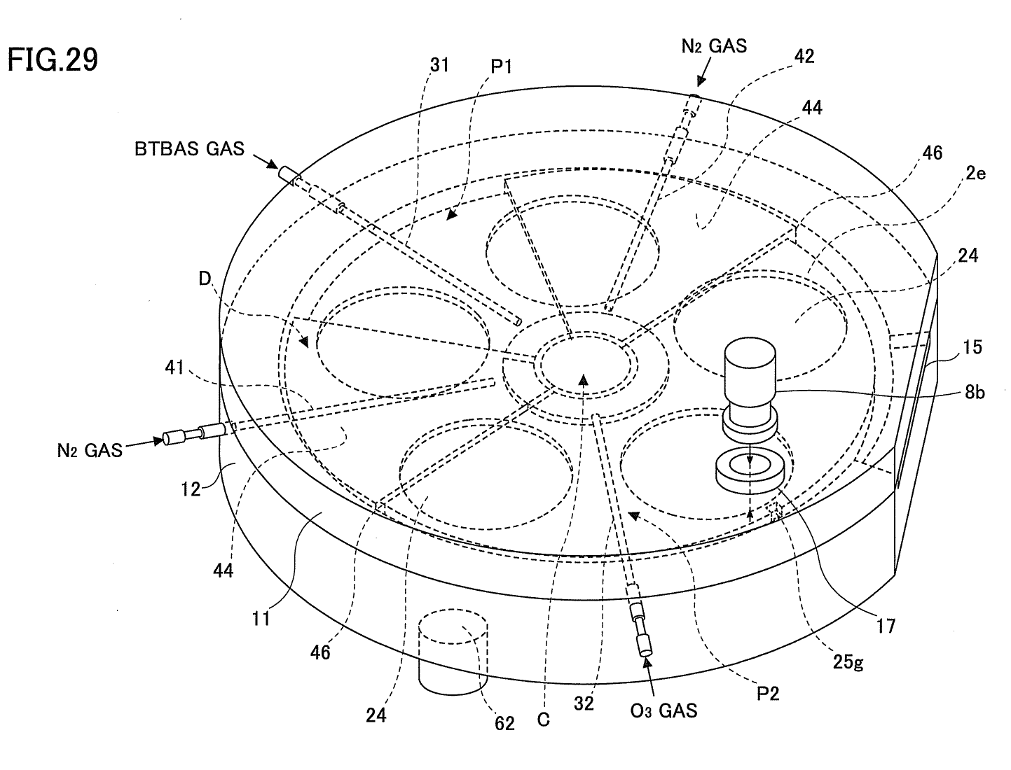

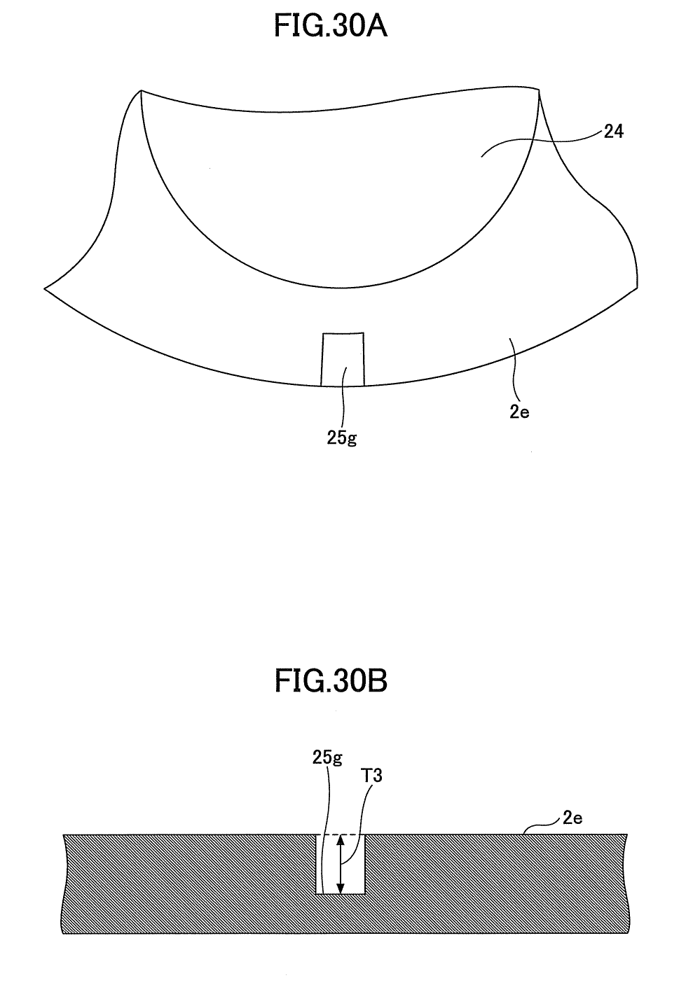

Referring to FIGS. 28 through 30B, the film deposition apparatus of this modification will be described. FIG. 28 is a cross-sectional view illustrating the composition of the film deposition apparatus of this modification. FIG. 29 is a perspective view illustrating the arrangement of a position detecting unit and a detection part in the film deposition apparatus of this modification. FIGS. 30A and 30B are enlarged views of the turntable of the film deposition apparatus of this modification near the detection part. FIG. 30A is a plan view of the turntable and FIG. 30B is a cross-sectional view in the rotational direction of the turntable.

The film deposition apparatus of this modification is different from the film deposition apparatus of the fifth modification of the first embodiment in that the kicker is disposed in the rotary shaft of the turntable and the photosensor is disposed in the vacuum chamber corresponding to the kicker, in addition to the detection part provided in the circumference of the turntable and the position detecting unit provided corresponding to the detection part.

As illustrated in FIG. 28, in this modification, a step part 25g which constitutes one of the two detection parts is formed in the circumference of the turntable 2e, a kicker 25h which constitutes the other of the two detection parts is formed in the rotary shaft 22 of the turntable 2e, and a photosensor 8c is disposed in the vacuum chamber 1 corresponding to the kicker 25h.

As illustrated in FIGS. 28 and 29, the composition of the film deposition apparatus of this modification, other than the detection part and the position detecting unit, is the same as that of the film deposition apparatus of the fifth modification of the first embodiment. On the other hand, the composition of the detection part and the position detecting unit in the film deposition apparatus of this modification differs from that of the fifth modification of the first embodiment.

The turntable 2e has a center of rotation at the center of the vacuum chamber 1 and includes case bodies 20 and 20a, a core part 21, a rotary shaft 22, a drive part 23, and a recess 24, which are the same as those of the fifth modification of the first embodiment.

Apart from the fifth modification of the first embodiment, the detection part in this modification is arranged so that only one step part 25g is formed in the circumference of the turntable 2e. Instead of the other step part provided in the circumference of the turntable in the fifth modification of the first embodiment, the kicker 25h in this modification is formed in the rotary shaft 22 of the turntable 2e, and the photosensor 8c is formed corresponding to the kicker 25h as illustrated in FIG. 28.

The step part 25g is the portion for measuring the distance between the laser sensor 8b and the turntable 2e as in the fifth modification of the first embodiment. Therefore, the step part 25g is a concavity having a flat bottom surface and a predetermined depth T3 from the upper surface of the turntable 2e, as illustrated in FIGS. 30A and 30B.

As illustrated in FIGS. 28 and 29, the laser sensor 8b is disposed at the position above the circumference of the upper surface of the turntable 2e, so that the detection part 25e of the turntable 2e can be detected by the laser sensor 8b, which is the same as that of the fifth modification of the first embodiment. The laser sensor 8b has a function to measure a distance between the laser sensor 8b and the object being measured, which is the same as that of the fifth modification of the first embodiment.

On the other hand, the kicker 25h and the photosensor 8c in this modification are disposed as follows. A pair of an LED 81a which emits a laser beam parallel to the rotary shaft 22 and a photodiode 82a which receives the laser beam parallel to the rotary shaft 22 are formed in the inner wall of the container main part 12 of the vacuum chamber 1 which inner wall is distant from the rotary shaft 22 attached under the turntable 2e. The LED 81a and the photodiode 82a constitute the photosensor 8c. The kicker 25h is disposed on the side circumference of the rotary shaft 22 so that, while the rotary shaft 22 is rotated one revolution, the kicker 25h intercepts at a time the light emitted from the LED 81a which is received by the photodiode 82a. The kicker 25h is further arranged so that the step part 25g is detected by the laser sensor 8b after the kicker 25h in the rotational direction of the turntable 2e is detected by the photosensor 8c.

The LED 81a, the photodiode 82a, and the kicker 25h are equivalent to the light emitting element, the light receiving element, and the shade part in the claims.

Next, with reference to FIGS. 13 and 31-32C, the film deposition method using the film deposition apparatus of this modification will be explained.

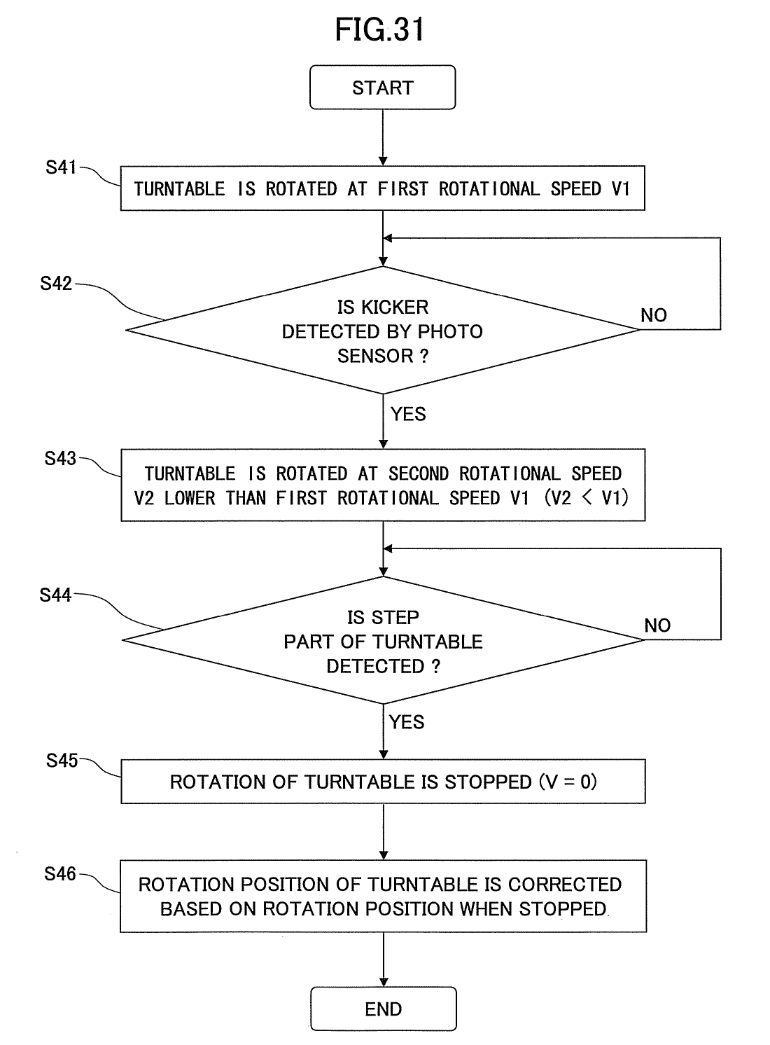

FIG. 31 is a flowchart for explaining the procedure of the position compensation step by the film deposition apparatus of this modification.

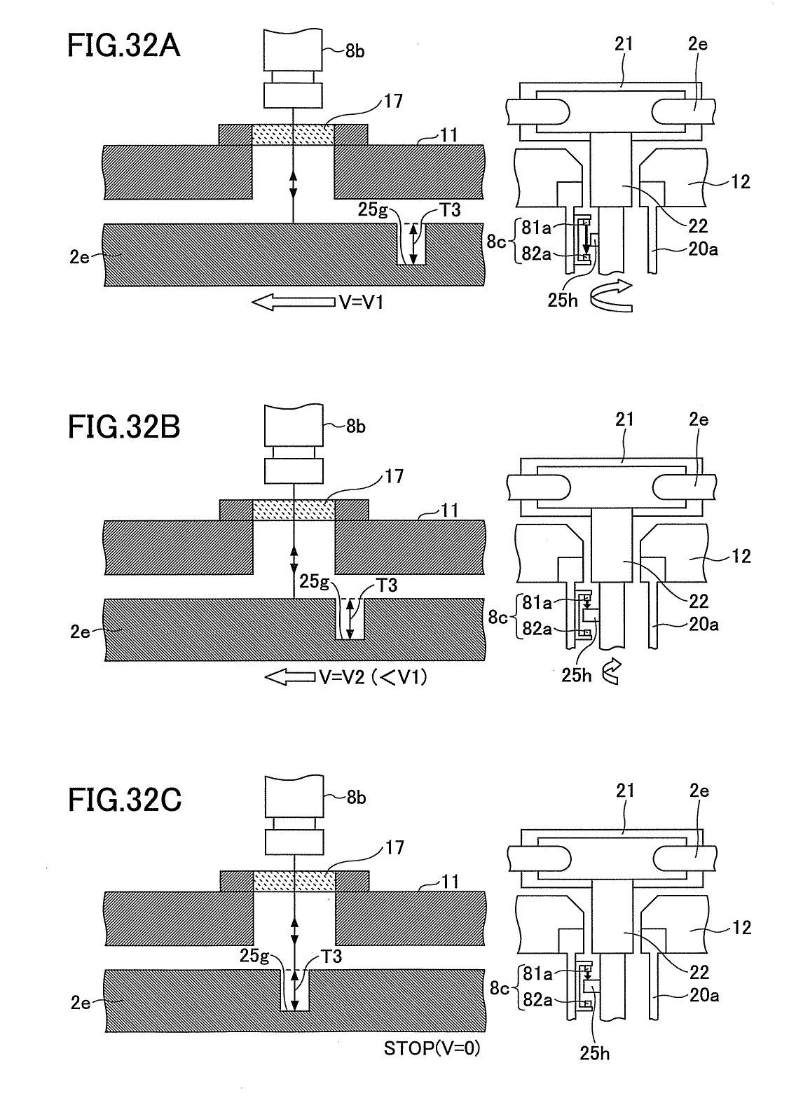

FIGS. 32A-32C illustrate the state of the position detecting unit and the detection part in the position compensation step by the film deposition apparatus of this modification. In FIGS. 32A-32C, the left-hand side diagram illustrates the state of the laser sensor 8b and the turntable 2e, and the right-hand side diagram illustrates the state of the kicker 25h and the photosensor 8c. The procedure of this modification is the same as that of the film deposition method of FIG. 13 performed by the film deposition apparatus of the first embodiment, other than the position compensation step among the steps of the film deposition method using the film deposition apparatus of this modification.

On the other hand, the first and second position compensation steps which are step S11 and step S20 of FIG. 13 of the first embodiment differ from the position compensation step of this modification. That is, the position compensation step of this modification includes steps S41 to S46 as illustrated in FIG. 31.

The position compensation step of this modification roughly determines a rotation position using the kicker 25h and the photosensor 8c when the turntable 2e is rotated at high speed. Next, when the turntable 2e is rotated at low speed, a rotation position is precisely determined using the step part 25g and the laser sensor 8b.

Upon start, step S41 is performed. Step S41 is a step which rotates the turntable 2e at a predetermined rotational speed V. Suppose that the rotational speed V of the turntable 2e in step S41 is the first rotational speed V1. The value of V1, although it is not limited, may be set to about 1 rpm, for example.

Next, step S42 is performed. Step S42 is a step which determines whether the kicker 25h was detected by the photosensor 8c. Specifically, the light receiving amount of photodiode 82a of the photosensor 8c is measured. The value of the light receiving amount of the photosensor 8c in the state where between the LED 81a and the photodiode 82a is not interrupted by the kicker 25h. It is determined whether the light receiving amount is changing to exceed the threshold determined beforehand corresponding to the state where between the LED 81a and the photodiode 82a is interrupted by the kicker 25h.

If the kicker 25h is not detected by the photosensor 8c as a result of a determination, measurement and determination of photodiode 82a of the photosensor 8c of the light receiving amount are repeated again.

FIG. 32A illustrates the state where the turntable 2e is rotated at the rotational speed V=V1, the incident light from the laser sensor 8b has entered into the upper surface of the turntable 2e of this side which is the step part 25g, and the kicker 25h has not interrupted between the LED 81a and the photodiode 82a of the photosensor 8c, and in the determination of step S42, the kicker 25h is not yet detected by the photosensor 8c.

When it is determined that the kicker 25h is detected by the photosensor 8c as a result of the determination of step S42, the control is transferred to step S43. Step S43 is a step which decreases the rotational speed of the turntable 2e from the first rotational speed V1 to the second rotational speed V2 (<V1).

Next, step S44 is performed. Step S44 is a step which determines whether the step part 25g of the turntable 2e is detected by the laser sensor 8b. Specifically, a distance between the surface of the laser sensor 8b and the turntable 2e is measured by the laser sensor 8b. It is determined whether the measured distance is changed from the predetermined value corresponding to the upper surface of the turntable 2e to be larger than the threshold which is determined beforehand corresponding to the depth T3.

If the step part 25g of the turntable 2e is not detected as a result of the determination, measurement and determination of the distance between the laser sensor 8b and the surface of the turntable 2e by the laser sensor 8b are performed again.

FIG. 32B illustrates the state where the turntable 2e is rotated at the rotational speed V=V2, the incident light from the laser sensor 8b has entered into the upper surface of the turntable 2e which is located in front of the step part 25g, the kicker 25h has interrupted between the LED 81a and the photodiode 82a of the photosensor 8c, and in the determination of step S44, the step part 25g of the turntable 2e is not yet detected.

When it is determined that the step part 25g of the turntable 2e is detected as a result of the determination of step S44, the control is transferred to step S45. Step S45 is a step which stops the turntable Se. The rotational speed V of the turntable 2e is set to V=0.

FIG. 32C illustrates the state where the turntable 2e has stopped (V=0), the incident light from the laser sensor 8b has entered into the step part 25g, and the kicker 25h has interrupted between the LED 81a and the photodiode 82a of the photosensor 8c.

Next, step S46 is performed. Step S46 is a step which performs position compensation of the turntable 2e on the basis of the rotation position when the turntable 2e is stopped. By performing steps S41-S45, the turntable 2e is stopped in the predetermined position with good repeatability. By setting the angular position where the turntable 2e is stopped to 0 degrees, the rotation angle of the turntable 2e can be corrected with sufficient repeatability.

Provided that the position compensation of step S46 can be performed simultaneously when it is determined that the step part 25g of the turntable 2e is detected as a result of the determination of step S44, it is not necessary to stop rotation of the turntable 2e in step S45.

According to the film deposition apparatus of this modification, after the rotation position of the turntable is roughly determined using the kicker and the photosensor provided in the rotary shaft of the turntable when it is rotated at high speed (V=V1), the rotation position of the turntable can be precisely determined using the step part and the laser sensor when the turntable is rotated at low speed (V=V2<V1). Therefore, it is possible to shorten the time for the position compensation step and perform the positioning precisely.

The step part which is the detection part may be provided in the side circumference or the undersurface of the turntable as in the fifth modification of the first embodiment. In this case, the laser sensor may be disposed outside or on the base part of the side circumference of the container main part of the vacuum chamber. The entrance window may be provided in the side circumference or the base part of the container main part of the vacuum chamber.

In this modification, the kicker and the photosensor are formed in the case bodies 20 and 20a which communicate with the container main part 12 of the vacuum chamber 1. However, the case bodies 20 and 20a which accommodate the lower part side of the rotary shaft 22 may not be arranged to communicate with the container main part 12 of the vacuum chamber 1 airtightly. The kicker and the photosensor may be formed in the case bodies 20 and 20a which do not communicate with the container main part 12 of the vacuum chamber 1 airtightly.

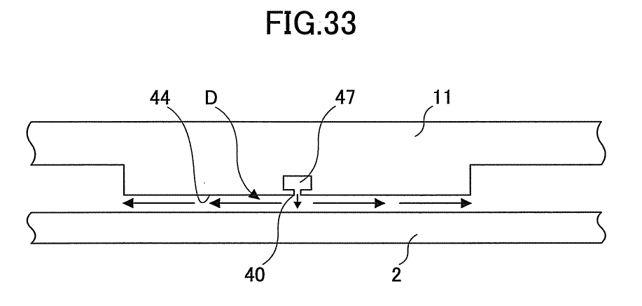

Next, with reference to FIG. 33, the film deposition apparatus of a seventh modification of the first embodiment of the invention will be described.

FIG. 33 is a cross-sectional view illustrating another example of the configuration of the top plate in the third undersurface portion in the film deposition apparatus of this modification.

The film deposition apparatus of this modification is different from the film deposition apparatus of the first embodiment in that the conduction chamber 47 of the first separation gas is arranged in the interior of the top plate 11 in third space D in the radial direction of the turntable 2.

In the first embodiment, the third undersurface portion is disposed on the both sides of the first separation gas supplying portion and the slot is formed in the portion corresponding to the first separation gas supplying portion. In this modification, the chamber 47 of the first separation gas is formed in the interior of top plate 11 of the vacuum chamber 1 in the third space D in the radial direction of the turntable 2 and plural gas discharge holes 40 are perforated on the bottom of the chamber 47 in the length direction. Therefore, it is not necessary to newly provide the first separation gas supplying portion other than the conduction chamber 47, and the same effect as the first embodiment can be acquired, and the number of component parts can be reduced.

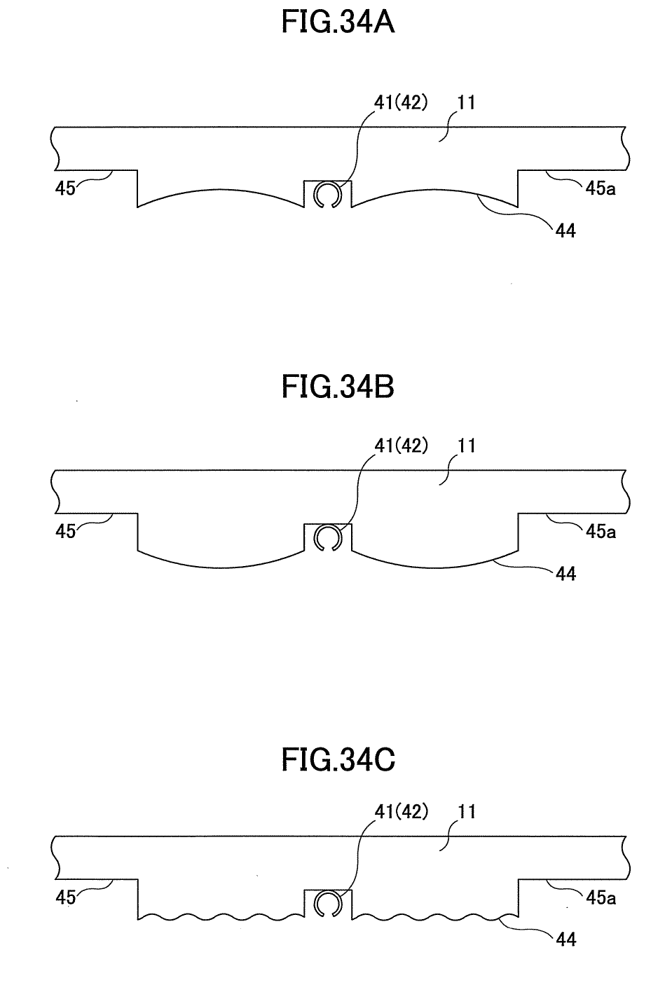

Next, with reference to FIGS. 34A through 34C, the film deposition apparatus of the eighth modification of the first embodiment of the invention will be described.

FIGS. 34A to 34C are cross-sectional views illustrating examples of the configuration of the undersurface of the top plate in the third undersurface portion in the film deposition apparatus of this modification.

The film deposition apparatus of this modification is different from the film deposition apparatus of the first embodiment in that the third undersurface portion in third space D is a curved surface.

Referring to FIGS. 34A through 34C, different from the first embodiment in which the third undersurface portion on the both sides of the first separation gas supply is a plane, the third undersurface portion 44 in this modification on the both sides of the first separation gas supplying portion 41 (42) is a curved surface.

The third undersurface portion 44 is not limited to the plane configuration as in the first embodiment, if it can separate the first reactive gas and the second reactive gas. As illustrated in FIG. 34A, the third undersurface portion 44 may be formed into a concave surface. As illustrated in FIG. 34B, the third undersurface portion 44 may be formed into a convex surface. As illustrated in FIG. 34C, the third undersurface portion 44 may be formed into a wave-like configuration.

For example, as illustrated in FIG. 34A, if it is formed into a concave surface, the height of the third undersurface portion 44 from the turntable 2 at the ends adjacent to the first undersurface portion 45 and the second undersurface portion 45a can be lowered. For this reason, infiltration of the first reactive gas and the second reactive gas to the third undersurface portion 44 can be prevented more efficiently. As illustrated in FIG. 34B, if it is formed into a convex surface, the height of the third undersurface portion 44 corresponding to the convex peak from the turntable 2 can be lowered. For this reason, infiltration of the first reactive gas and the second reactive gas to the third undersurface portion 44 can be prevented more efficiently. As illustrated in FIG. 34C, if it is formed into a wave-like configuration, two or more convex peaks as illustrated in FIG. 34B can be provided. For this reason, infiltration of the first reactive gas and the second reactive gas to the third undersurface portion 44 can be prevented more efficiently.

In this modification, the third undersurface portion 44 is formed in the undersurface of the top plate 11. Alternatively, the undersurface of another component than the top plate 11 may be formed into the configuration which is the same as in the third undersurface portion 44, and this component may be attached to the top plate 11.

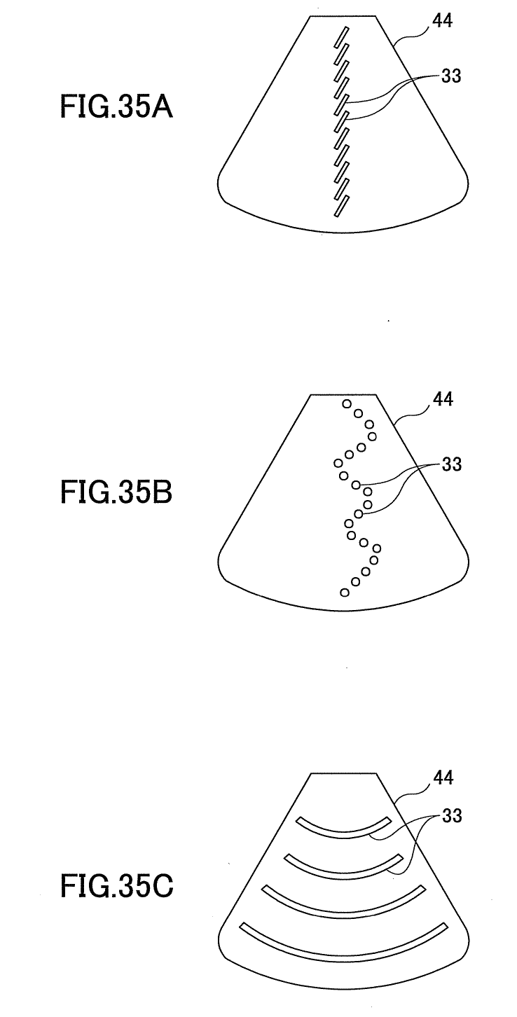

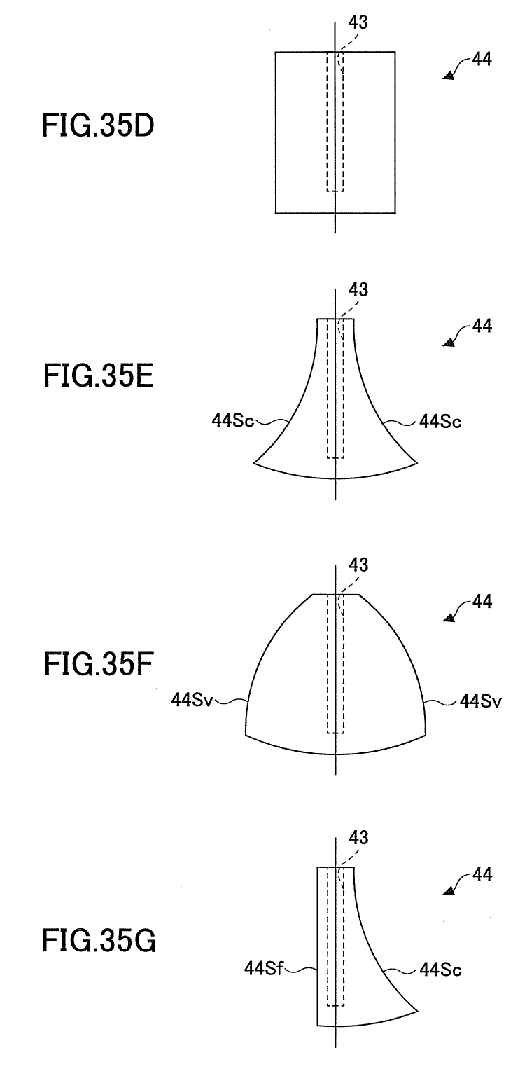

Next, with reference to FIGS. 35A through 35G, the film deposition apparatus of a ninth modification of the first embodiment of the invention will be described.

FIGS. 35A through 35C are bottom views illustrating examples of the configuration of gas discharge holes of the first reactive gas supplying portion in the film deposition apparatus of this modification. FIGS. 35D through 35G are bottom views illustrating examples of the configuration of the third undersurface portion in the film deposition apparatus of this modification. In FIGS. 35A through 35C, the arrangement of the third undersurface portion 44 and discharge holes 33 is illustrated.

Referring to FIGS. 35A through 35C, the film deposition apparatus of this modification is different from the film deposition apparatus of the first embodiment which requires the discharge holes formed in the first separation gas supplying portion which are arranged in a straight line from the circumference of the turntable 2 to the center of rotation.

The arrangement of the discharge holes 33 is not limited to that of the first embodiment if the first separation gas can be uniformly supplied to the substrate. The arrangement of the discharge hole 33 may be modified as follows.

In the composition illustrated in FIG. 35A, the discharge holes 33 are plural slits which have a rectangular form, are suitably slanted to the radial direction of the turntable 2, and are arrayed at predetermined intervals in the radial direction of the turntable 2. In the composition illustrated in FIG. 35B, the discharge holes 33 are plural discharge holes which have a circular form and are arrayed in a serpentine or zigzag formation. In the composition illustrated in FIG. 35C, the discharge holes 33 are plural slits which have a circular form and are arranged to be coaxial to the center of rotation of the turntable 2.

The third undersurface portion 44 may be constituted so that the portion is hollow and the first separation gas may be introduced into the hollow portion. In this case, two or more discharge holes 33 may be arranged as illustrated in FIGS. 35A through 35C.

In this modification, the upper surface of the third undersurface portion 44 has a sector form. As illustrated in FIG. 35D, the upper surface of the third undersurface portion 44 may be formed to have a rectangular or square configuration. As illustrated in FIG. 35E, the upper surface of the third undersurface portion 44 may be formed into a generally sector-form configuration which has concavely curved sides 44Sc. As illustrated in FIG. 35F, the upper surface of the third undersurface portion 44 may be formed into a generally sector-form configuration which has convexly curved sides 44Sv. As illustrated in FIG. 35G, the upper surface of the third undersurface portion 44 may be formed so that the upstream portion of the third undersurface portion 44 in the rotational direction of the turntable 2 (FIG. 1) has a concavely curved side 44Sc and the downstream portion of the third undersurface portion 44 in the rotational direction of the turntable 2 (FIG. 1) has a straight side 44Sf. In FIGS. 35D-35G, the dotted line indicates the slot 43 formed in the third undersurface portion 44. In this case, the first separation gas supplying portion 41 or 42 (FIG. 2) accommodated in the slot 43 extends from the central part of the vacuum chamber 1 (for example, the projecting portion 53 (FIG. 1)).

By arranging the discharge holes 33 in this manner, the first separation gas is supplied to the third undersurface portion 44 more uniformly and infiltration of the first reactive gas and the second reactive gas to the third undersurface portion 44 can be prevented more efficiently.

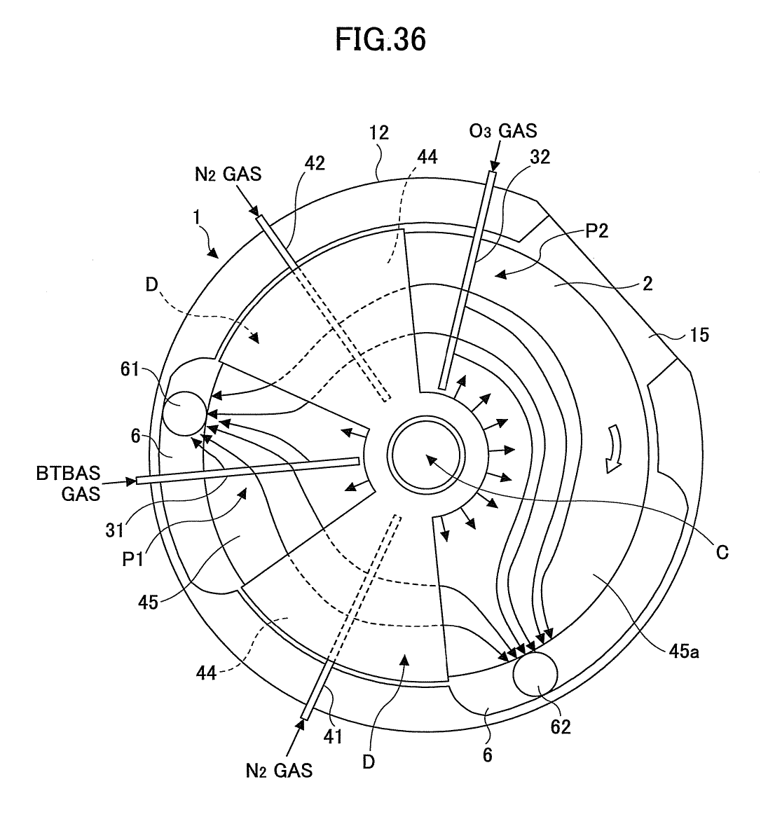

Next, with reference to FIG. 36, the film deposition apparatus of a tenth modification of the first embodiment of the invention will be described.

FIG. 36 is a diagram illustrating the composition of the film deposition apparatus of this modification. FIG. 36 is a plan view of the film deposition apparatus of this modification in the state where the top plate 11 of the vacuum chamber 1 is separated.

The film deposition apparatus of this modification is different from the film deposition apparatus of the first embodiment in that the second reactive gas supplying portion 34 is disposed upstream of the conveyance port 15 in the rotational direction of the turntable 2, as illustrated in FIG. 36.

In the film deposition apparatus of this modification having such a layout, the first reactive gas and the second reactive gas can be separated more efficiently, infiltration of the first separation gas to the first undersurface portion 45 and the second undersurface portion 45a can be prevented, and the first reactive gas and the second reactive gas can be supplied to the wafer in the first undersurface portion 45 and the second undersurface portion 45a more efficiently.

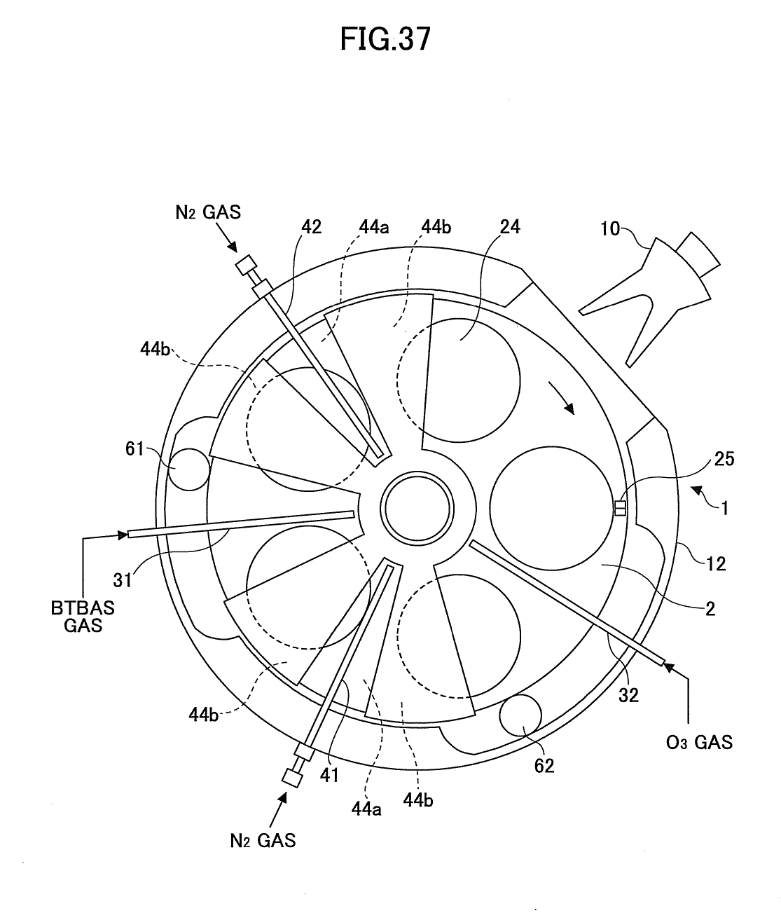

Next, with reference to FIG. 37, the film deposition apparatus of an eleventh modification of the first embodiment of the invention will be described.

FIG. 37 is a diagram illustrating the composition of the film deposition apparatus of this modification. FIG. 37 illustrates the film deposition apparatus of this modification in which the top plate 11 of the vacuum chamber 1 is cut away horizontally at the position that is lower than the first undersurface portion 45 and the second undersurface portion 45a and higher than the first separation gas supplying portion 41 or 42.

The film deposition apparatus of this modification is different from the film deposition apparatus of the first embodiment in that the third undersurface portion is divided into two parts in the circumferential direction and the first separation gas supplying portion is provided between the two parts.

As illustrated in FIG. 37, the third undersurface portion in this modification includes a third undersurface portion 44a that is disposed at a height from the turntable 2 larger than the third height H3 and includes the first separation gas supplying portion 41 or 42, and a third undersurface portion 44b that adjoins the third undersurface portion 44a and is disposed at the third height H3 from the turntable 2.

By providing the third undersurface portions 44a and 44b, the first reactive gas and the second reactive gas can be separated more efficiently, infiltration of the first separation gas to the first undersurface portion 45 and the second undersurface portion 45a can be prevented, and the first reactive gas and the second reactive gas can be supplied to the wafer in the first undersurface portion 45 and the second undersurface portion 45a more efficiently.

The distance between the third undersurface portion 44b and the first separation gas supplying portion 41 or 42, and the configuration and dimensions of the third undersurface portion 44b can be designed optimally by taking into consideration the discharge flow rates of the first reactive gas, the second reactive gas, the first separation gas, etc.

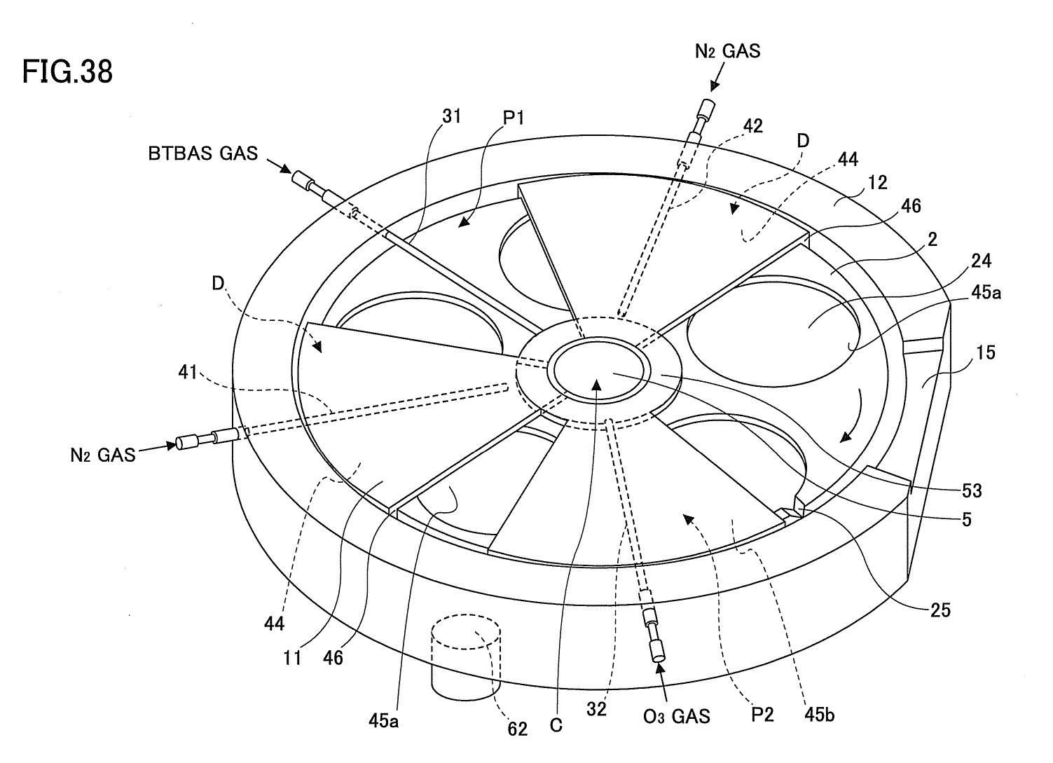

Next, with reference to FIG. 38, the film deposition apparatus of a twelfth modification of the first embodiment of the invention will be described.

FIG. 38 is a perspective view illustrating the composition of the film deposition apparatus of this modification.

The film deposition apparatus of this modification is different from the film deposition apparatus of the first embodiment in that the second undersurface portion is replaced with a sixth undersurface portion and a seventh undersurface portion which are provided in this modification.

As illustrated in FIG. 38, the second undersurface portion in this modification is replaced with the following: a sixth undersurface portion 45b that is disposed at a height from the turntable 2 smaller than the second height H2 and includes the second reactive gas supplying portion 32; and a seventh undersurface portion 45a that adjoins the sixth undersurface portion 45b and is disposed at the second height H2 from the turntable 2.

Therefore, the sixth undersurface portion 45b is the same as the third undersurface portion 44 except that the second reactive gas supplying portion 32 is used instead of the first separation gas supplying portion 41 or 42.

By providing the sixth undersurface portion 45b, the first reactive gas and the second reactive gas can be separated more efficiently, infiltration of the first separation gas and the first reactive gas to the sixth undersurface portion 45b can be prevented, and the second reactive gas can be more efficiently supplied to the wafer in the sixth undersurface portion 45b.

The sixth undersurface portion 45b may be configured to be similar to the hollow third undersurface portion 44 as illustrated in FIGS. 35A through 35C.

In this modification, the second undersurface portion is replaced by the sixth undersurface portion and the seventh undersurface portion. Alternatively, the first undersurface portion may be replaced by the following: a fourth undersurface portion that is disposed at a height from the turntable smaller than the first height H1 and includes the first reactive gas supplying portion; and a fifth undersurface portion that adjoins the fourth undersurface portion and is disposed at the first height H1 from the turntable.

By providing the fourth undersurface portion, the first reactive gas and the second reactive gas can be separated more efficiently, infiltration of the first separation gas and the first reactive gas to the fourth undersurface portion can be prevented, and the first reactive gas can be more efficiently supplied to the wafer in the fourth undersurface portion.

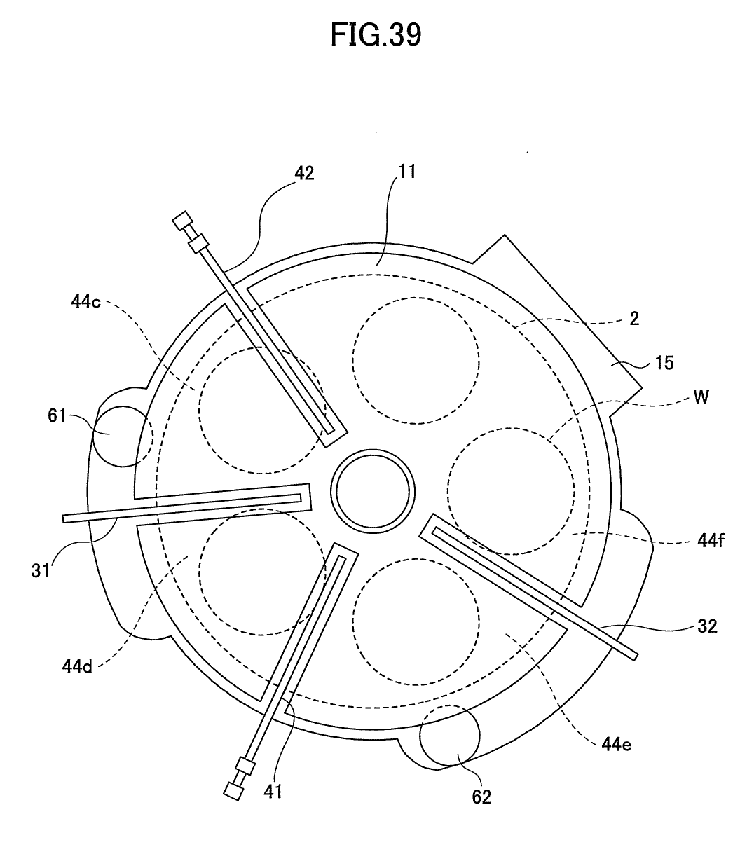

Next, with reference to FIG. 39, the film deposition apparatus of a thirteenth modification of the first embodiment of the invention will be described.

FIG. 39 is a diagram illustrating the composition of the film deposition apparatus of this modification. FIG. 39 is a plan view of the film deposition apparatus of this modification in the state where the top plate of the vacuum chamber is separated.

The film deposition apparatus of this modification is different from the film deposition apparatus of the first embodiment in that low ceiling surfaces are provided on both sides of each of the first reactive gas supplying portion and the second reactive gas supplying portion.

As illustrated in FIG. 39, in this modification, third undersurface portions 44c-44f that are low ceiling surfaces similar to the third undersurface portion are disposed on both sides of each of the first reactive gas supplying portion 31 and the second reactive gas supplying portion 32, and these third undersurface portions 44c-44f are formed to be continuous.

As illustrated in FIG. 39, the third undersurface portion is provided in the whole area surface which faces the turntable 2 except the areas in which the first separation gas supplying portion 41 (42), the first reactive gas supplying portion 31, and the second reactive gas supplying portion 32 are formed.

In this case, the first separation gas is spread on the both sides of the first separation gas supplying portion 41 (42), the first reactive gas and the second reactive gas are spread on the both sides of each of the first reactive gas supplying portion 31 and the second reactive gas supplying portion 32, and these gases join in the narrow space between the third undersurface portions 44c-44f and the turntable 2. However, these gases are exhausted from the exhaust port 61 (62) located between the first (second) reactive gas supplying portion 31 (32) and the first separation gas supplying portion 42 (41). Thus, in this modification, the same effect as the first embodiment is acquired.

Alternatively, the third undersurface portions 44c-44f may be formed by combining the hollow undersurface portions as illustrated in any of FIGS. 35A through 35C. In such alternative modification, the first reactive gas, the second reactive gas and the separation gas may be discharged from the discharge holes 33 of the corresponding hollow third undersurface portion 44c-44f without using the first reactive gas supplying portion 31, the second reactive gas supplying portion 32 and the first separation gas supplying portion 41 or 42.

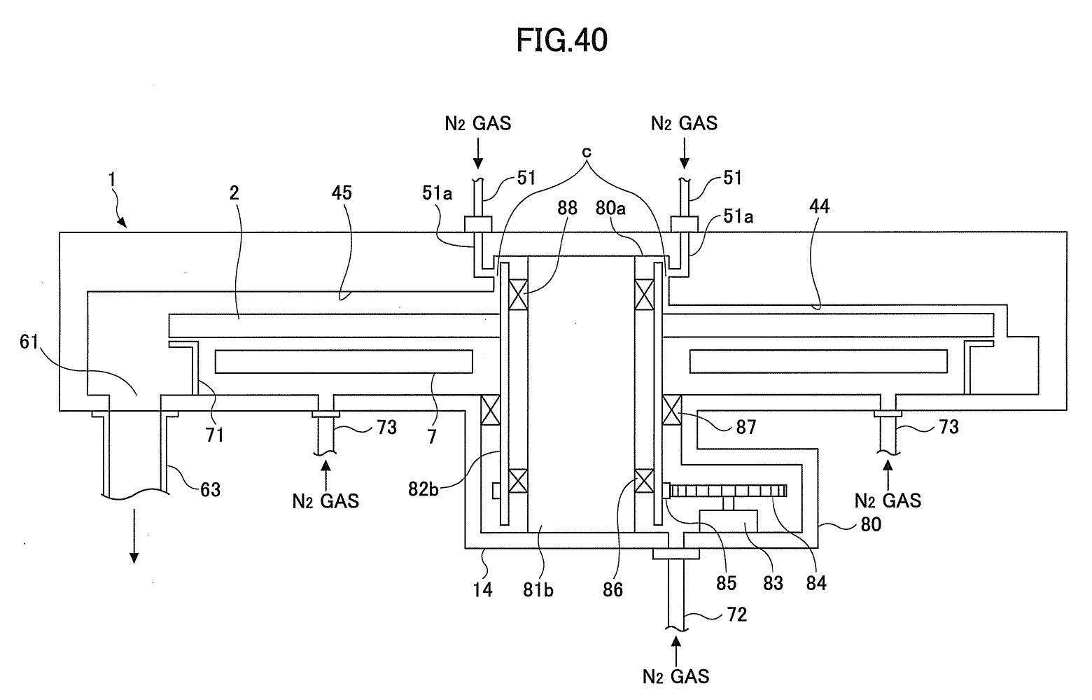

Next, with reference to FIG. 40, the film deposition apparatus of a fourteenth modification of the first embodiment of the invention will be described.

FIG. 40 is a cross-sectional view illustrating the composition of the film deposition apparatus of this modification.

The film deposition apparatus of this modification is different from the film deposition apparatus of the first embodiment in that a support is interposed between the base part of the vacuum chamber and the top plate in the core of the vacuum chamber to prevent mixture of the reactive gases.

As illustrated in FIG. 40, in this modification, a recess 80a is formed in the upper surface of the central region of the vacuum chamber 1, and a support 81b is disposed in the core of the vacuum chamber 1 between the bottom of the accommodation space 80 and the upper surface of the recess 80a.

As illustrated in FIG. 40, the base part 14 of the center region of the vacuum chamber 1 is projected downward to form the accommodation space 80 of the drive part. The recess 80a is formed in the upper surface of the center region of the vacuum chamber 1, and the support 81b is interposed between the bottom of the accommodation space 80 and the upper surface of the recess 80a in the core of the vacuum chamber 1 in order to prevent the BTBAS gas from the first reactive gas supplying portion 31 and the O₃ gas from the second reactive gas supplying portion 32 from being mixed together in the core of the vacuum chamber 1.

As the drive mechanism which rotates the turntable 2, the rotation sleeve 82b is arranged to surround the support 81b, and the circular turntable 2 is arranged along the rotation sleeve 82b. The drive gear parts 84 and 85 which are driven by the motor 83 are arranged in the accommodation space 80, and these drive gear parts 84 and 85 rotate the rotation sleeve 82b. In FIG. 40, reference numerals 86, 87 and 88 denote bearings.

The third separation gas supplying portion 72 that supplies the third separation gas is connected to the bottom of the accommodation space 80, and the second separation gas supplying portion 51 that supplies the second separation gas is connected at one end to the space between the side of the recess 80a and the top end of the rotation sleeve 82b, and connected at the other end to the upper part of the vacuum chamber 1.

In the composition of FIG. 40, the opening 51a for supplying the second separation gas to the space between the side of the recess 80a and the top end of the rotation sleeve 82b is disposed on both right and left sides. In order to prevent the BTBAS gas and the O₃ gas from being mixed in the area in the vicinity of the rotation sleeve 82b, it is preferred to design the number of openings 51a of the second separation gas supplying portion 51 to be the optimum.

In the modification of FIG. 40, the space between the side of the recess 80a and the top end of the rotation sleeve 82b, when viewed from the side of the turntable 2, is equivalent to the separation gas discharge hole, and the separation gas discharge hole, the rotation sleeve 82b and the support 81b constitute the core area C located in the core of the vacuum chamber 1.

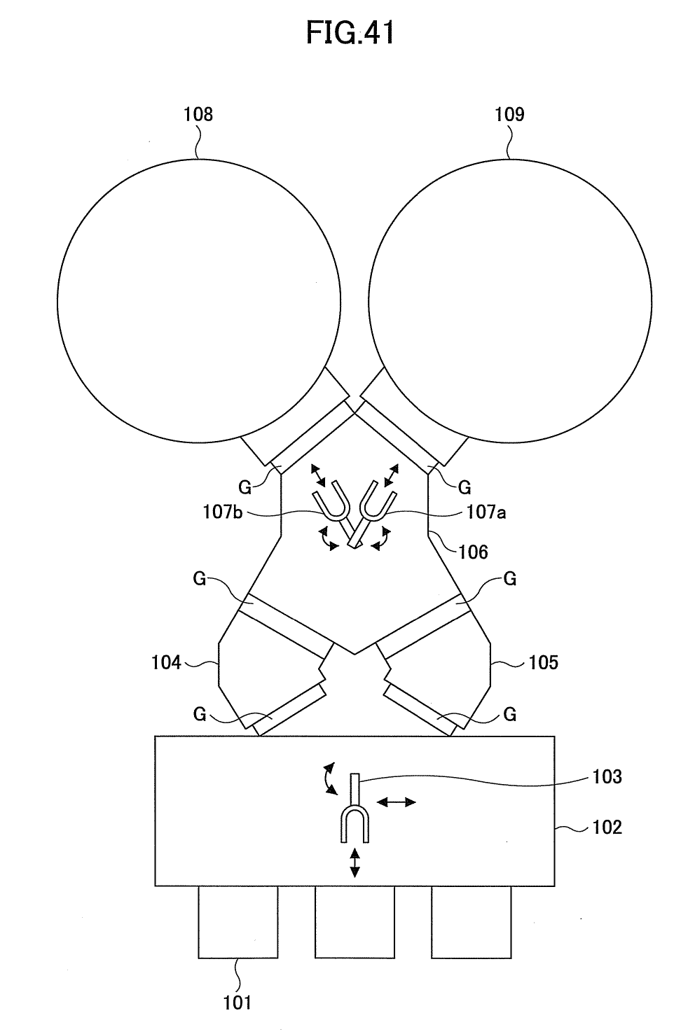

Next, with reference to FIG. 41, a substrate processing apparatus of a second embodiment of the invention will be described. FIG. 41 is a plan view illustrating the composition of the substrate processing apparatus of this embodiment.

As illustrated in FIG. 41, the substrate processing apparatus of this embodiment includes a conveyance container 101, an atmosphere conveyance chamber 102, a conveyance arm 103, load lock chambers 104 and 105 (which constitute a reserve vacuum chamber in the claims), a vacuum conveyance chamber 106, a conveyance arm 107, and film deposition apparatuses 108 and 109.

The conveyance container 101 is a hermetically sealed conveyance container (called FOUP) which stores 25 wafers, for example. The atmosphere conveyance chamber 102 is an air conveyance chamber in which the conveyance arm 103 is arranged.

Each of the load lock chambers 104 and 105 is arranged to switch the internal atmosphere of the chamber between an air atmosphere and a vacuum atmosphere.

The vacuum conveyance chamber 106 is a vacuum conveyance chamber in which the two conveyance arms 107 are arranged.

Each of the film deposition apparatuses 108 and 109 is constituted by the film deposition apparatus of the first embodiment of the invention.

A conveyance container 101 is conveyed from the outside to the conveyance port provided with the mounting base (which is not illustrated), and installed therein. After the conveyance container 101 is installed, the lid of the air conveyance chamber 102 is opened by the opening/closing mechanism (which is not illustrated), and a wafer is taken out from the inside of the conveyance container 101 by the conveyance arm 103. The wafer taken out from the inside of the conveyance container 101 is carried in the load lock chamber 104 or 105.

Subsequently, the internal atmosphere of the load lock chamber 104 or 105 is switched to vacuum atmosphere from air atmosphere.

Subsequently, the wafer is taken out from the load lock chamber 104 or 105 by the conveyance arm 107, and conveyed to the film deposition apparatus 108 or 109. Then, in the film deposition apparatus 108 or 109, the film deposition processing is performed by performing the above-described film deposition method.

In this embodiment, it is possible by starting the first embodiment of the invention, for example, having a film deposition apparatus for five-sheet processing two pieces two or more to carry out film deposition processing of ALD or MLD by a high throughput.

In this embodiment, because the film deposition apparatuses 108 and 109 of the first embodiment of the invention are used, in each film deposition apparatus, by having a position detecting unit for detecting the detection part and detection part which were provided in the circumference of the turntable, the rotation position of the turntable can be detected and corrected with sufficient accuracy of position, and carrying-in appearance of a substrate can be certainly performed between the exteriors of a vacuum chamber.

As described in the foregoing, the film deposition apparatus and method of the invention can carry out a proper film deposition without jeopardizing high production throughput, by performing plural cycles of alternately supplying plural reactive gases to the substrate to form plural layers of the reaction products of the reactive gases on the substrate without allowing the plural reactive gases to be mixed on the wafer. The film deposition apparatus and method of the invention can carry out an accurate detection and correction of a rotation position of the turntable, rotated at high speed, with sufficient accuracy of rotation position. The film deposition apparatus and method of the invention can certainly carry out a conveyance of the substrate from the interior to the exterior of the vacuum chamber.

The present invention is not limited to the above-described embodiments, and variations and modifications may be made without departing from the scope of the present invention.

What is claimed is:

1. A film deposition apparatus which deposits a thin film on a substrate by performing a cycle of alternately supplying at least two kinds of source gases, including a first reactive gas and a second reactive gas, to produce a layer of a reaction product in a vacuum chamber, comprising:
a turntable that is rotatably arranged in the vacuum chamber and includes a substrate mounting part on which the substrate is mounted;
first and second reactive gas supplying portions that are arranged to extend from mutually different circumferential positions of the turntable to a center of rotation of the turntable to respectively supply the first reactive gas and the second reactive gas;
a first separation gas supplying portion that is arranged to extend from a circumferential position of the turntable between the first reactive gas supplying portion and the second reactive gas supplying portion to the center of rotation to supply a first separation gas that separates the first reactive gas and the second reactive gas;
a first undersurface area in an undersurface of a top plate of the vacuum chamber which area is arranged at a first height from the turntable to include the first reactive gas supplying portion;
a first space that is arranged between the first undersurface area and the turntable;
a second undersurface area in an undersurface of the top plate which area is arranged at a position apart from the first undersurface area and at a second height from the turntable to include the second reactive gas supplying portion;
a second space that is arranged between the second undersurface area and the turntable;
a third undersurface area in an undersurface of the top plate which area is arranged at a third height from the turntable to include the first separation gas supplying portion, the third height smaller than the first height and the second height, and the third undersurface area extending on both sides of the first separation gas supplying portion along a rotational direction of the turntable;
a third space that is arranged between the third undersurface area and the turntable, the third space having the third height from the turntable and allowing the first separation gas supplied from the first separation gas supplying portion to flow into the first space and the second space;
a position detecting unit that detects a rotation position of the turntable;
a detection part that is arranged at a circumferential position of the turntable and detected by the position detecting unit;
a core area in an undersurface of the top plate, the core area including a second separation gas supplying portion arranged on a side of the substrate mounting part around the center of rotation of the turntable to supply a second separation gas which separates the first reactive gas and the second reactive gas; and
an exhaust port that is arranged to exhaust the first reactive gas and the second reactive gas together with both the first separation gas discharged to both sides of the third space and the second separation gas discharged from the core area.

2. The film deposition apparatus according to claim 1, wherein the position detecting unit is a laser sensor.

3. The film deposition apparatus according to claim 2, wherein the laser sensor detects the detection part in accordance with a change of a distance between the laser sensor and a surface of the turntable.

4. The film deposition apparatus according to claim 3, wherein the detection part is arranged on the surface of the turntable and includes a first step part and a second step part, the first and second step parts having mutually different depths from the surface of the turntable, and
wherein the second step part is arranged adjacent to the first step part in the rotational direction of the turntable.

5. The film deposition apparatus according to claim 3, wherein the position detecting unit comprises:
a photosensor which includes a light emitting element and a light receiving element and detects a rotation position of a rotary shaft of the turntable; and
a shade part which is arranged on a circumferential side face of the rotary shaft and detected by the photosensor when the shade part located between the light emitting element and the light receiving element prevents light emitted by the light emitting element from entering the light receiving element.

6. The film deposition apparatus according to claim 5, wherein the detection part is arranged on the surface of the turntable to include a step part having a depth from the surface of the turntable.

7. The film deposition apparatus according to claim 1, wherein the detection part is a scribed line which is formed in a circumferential portion of an upper surface of the turntable and extends in a radial direction of the turntable.

8. The film deposition apparatus according to claim 1, further comprising a third separation gas supplying portion that is arranged beneath the center of rotation of the turntable to supply a third separation gas that separates the first reactive gas and the second reactive gas.

9. The film deposition apparatus according to claim 1, further comprising a fourth separation gas supplying portion that is arranged between a bottom of the vacuum chamber and the turntable to supply a fourth separation gas that separates the first reactive gas and the second reactive gas.

10. The film deposition apparatus according to claim 1, wherein a fourth undersurface area and a fifth undersurface are substituted for the first undersurface area, wherein
the fourth undersurface area is arranged at a height, lower than the first height, from the turntable to include the first reactive gas supplying portion; and
the fifth undersurface area is adjacent to the fourth undersurface area and arranged at the first height from the turntable.

11. The film deposition apparatus according to claim 1, wherein a sixth undersurface area and a seventh undersurface area are substituted for the second undersurface area, wherein
the sixth undersurface area is arranged at a height, lower than the second height, from the turntable to include the second reactive gas supplying portion; and
the seventh undersurface area is adjacent to the sixth undersurface area and arranged at the second height from the turntable.

12. The film deposition apparatus according to claim 1, wherein a surface of the substrate placed on the substrate mounting part is flush with an upper surface of the turntable or at a height lower than the upper surface of the turntable.

13. The film deposition apparatus according to claim 1, wherein gas inlet ports for introducing gases to the first reactive gas supplying portion, the second reactive gas supplying portion, and the first separation gas supplying portion respectively are arranged on either a side of the center of rotation of the turntable or a side of the circumference of the turntable.

14. The film deposition apparatus according to claim 1, wherein discharge holes are arranged in the first separation gas supplying portion along a line extending from the center of rotation of the turntable to the circumference of the turntable.

15. The film deposition apparatus according to claim 14, wherein the third undersurface area is divided into two areas by the discharge holes of the first separation gas supplying portion included in the third undersurface area, a width of each of the two areas along a circular line in the rotational direction of the turntable through which a center of the substrate placed in the substrate mounting part passes is equal to 50 mm or larger.

16. The film deposition apparatus according to claim 1, wherein the undersurface of the top plate including the third undersurface area is formed into a plane or a curved surface.

17. The film deposition apparatus according to claim 1, further comprising a first exhaust port and a second exhaust port which are respectively arranged at circumferential positions of a bottom of the vacuum chamber adjacent to the first space and the second space.

18. A substrate processing apparatus comprising:
the film deposition apparatus according to claim 1;
a vacuum conveyance chamber connected to the film deposition apparatus in an airtight manner and including a substrate conveying part arranged inside the vacuum conveyance chamber; and
a reserve vacuum chamber connected to the vacuum conveyance chamber in an airtight manner and arranged to switch an internal atmosphere of the reserve vacuum chamber between an air atmosphere and a vacuum atmosphere.

19. A film deposition method which deposits a thin film on a substrate by performing a cycle of alternately supplying at least two kinds of source gases, including a first reactive gas and a second reactive gas, to produce a layer of a reaction product in a vacuum chamber, wherein a height of an area, to which a first separation gas that separates the first reactive gas and the second reactive gas is supplied, between an upper surface of a turntable and a top plate of the turntable on which the substrate is placed is lower than a height of an area, to which the first reactive gas and the second reaction gas are supplied, between the turntable upper surface and the top plate, and wherein the first separation gas is supplied to a narrow space arranged between the turntable upper surface and the top plate, a second separation gas that separates the first reactive gas and the second reactive gas is supplied to a core area in an undersurface of the top plate around a center of rotation of the turntable, and the first reactive gas and the second reactive gas which are separated from each other are exhausted together with the first separation gas and the second separation gas, the film deposition method comprising:
correcting a rotation position of the turntable;
placing the substrate on the turntable the rotation position of which is corrected;
rotating the turntable on which the substrate is placed;
depositing a thin film on a surface of the substrate by repeating a cycle of heating the turntable from a bottom of the turntable, supplying the first reactive gas and the second reactive gas respectively from a first reactive gas supplying portion and a second reactive gas supplying portion, which are arranged at mutually different circumferential positions of the turntable, supplying the first separation gas from a first separation gas supplying portion arranged between the first reactive gas supplying portion and the second reactive gas supplying portion, moving the substrate while the turntable is rotated, supplying the first reactive gas to the surface of the substrate, stopping the supply of the first reactive gas, supplying the second reactive gas to the surface of the substrate, and stopping the supply of the second reactive gas; and
taking out the substrate from the turntable the rotation position of which is corrected.

20. A computer-readable storage medium storing a program which, when executed by a computer, causes the computer to perform the film deposition method according to claim 19.
